(19) United States
(12) Patent Application Publication
(10) Pub. No.: US 2024/0381644 A1
(43) Pub. Date: Nov. 14, 2024

(54) THREE-DIMENSIONAL MEMORY DEVICE INCLUDING COAXIAL DOUBLE CONTACT VIA STRUCTURES AND METHODS FOR FORMING THE SAME

(71) Applicant: SANDISK TECHNOLOGIES LLC, ADDISON, TX (US)

(72) Inventor: Ryo MIZUTSU, Yokkaichi (JP)

(21) Appl. No.: 18/779,508

(22) Filed: Jul. 22, 2024

Related U.S. Application Data
(63) Continuation-in-part of application No. 18/662,077, filed on May 13, 2024.
Application No. 18/662,077 is a continuation-in-part of application No. 17/351,789, filed on Jun. 18, 2021, now Pat. No. 12,046,285.

(51) Int. Cl. H10B 43/27; H01L 23/00; H01L 25/00; H01L 25/065; H01L 25/18; H10B 80/00

(52) U.S. Cl. CPC H10B 43/27; H01L 24/08; H01L 24/80; H01L 25/0657; H01L 25/18; H01L 25/50; H10B 80/00; H01L 2224/08145; H01L 2224/80006; H01L 2224/80895; H01L 2224/80896; H01L 2924/1431; H01L 2924/14511

(57) ABSTRACT

A device structure includes an alternating stack of insulating layers and electrically conductive layers, a stepped dielectric material portion overlying and laterally contacting the alternating stack in the staircase region, and memory opening fill structures extending through the alternating stack. The electrically conductive layers include first electrically conductive layers and second electrically conductive layers overlying the first electrically conductive layers. Coaxial double contact via structures vertically extend through the stepped dielectric material portion. Each of the coaxial double contact via structures includes a respective inner layer contact via structure contacting a respective one of the first electrically conductive layers, and a respective outer layer contact via structure that laterally surrounds the respective inner layer contact via structure and contacts a respective one of the second electrically conductive layers.

### RELATED APPLICATIONS

The present application is a continuation-in-part application of U.S. application Ser. No. 18/662,077 filed on May 13, 2024, which is a CIP application of U.S. patent application Ser. No. 17/351,789 filed on Jun. 18, 2021, the contents of which are incorporated herein by reference in their entirety.

### FIELD

The present disclosure relates generally to the field of semiconductor devices, and particularly to a three-dimensional memory device including coaxial double contact via structures and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a device structure comprises: an alternating stack of insulating layers and electrically conductive layers, wherein the electrically conductive layers comprise first electrically conductive layers and second electrically conductive layers that overlie the first electrically conductive layers, wherein lateral extents of the second electrically conductive layers vary along a vertical direction in a staircase region; a stepped dielectric material portion overlying and laterally contacting the alternating stack in the staircase region; memory openings vertically extending through the alternating stack; memory opening fill structures located in the memory openings, wherein each of the memory opening fill structures comprises a respective vertical stack of memory elements and vertical semiconductor channel; and coaxial double contact via structures vertically extending through the stepped dielectric material portion, wherein each of the coaxial double contact via structures comprises: a respective inner layer contact via structure contacting a respective one of the first electrically conductive layers; and a respective outer layer contact via structure that laterally surrounds the respective inner layer contact via structure and contacts a respective one of the second electrically conductive layers.

According to another aspect of the present disclosure, a method of forming a device structure comprises: forming a combination of an alternating stack of insulating layers and electrically conductive layers, a stepped dielectric material portion overlying stepped surfaces of the alternating stack, and a memory stack structure vertically extending through the alternating stack, wherein the electrically conductive layers comprise first electrically conductive layers and second electrically conductive layers that overlie the first electrically conductive layers, and wherein the memory stack structure comprises a vertical stack of memory elements and a vertical semiconductor channel; and forming coaxial double contact via structures through the stepped dielectric material portion and a respective subset of the electrically conductive layers, wherein each of the coaxial double contact via structures comprises: a respective inner layer contact via structure contacting a respective one of the first electrically conductive layers; and a respective outer layer contact via structure that laterally surrounds the respective inner layer contact via structure and contacts a respective one of the second electrically conductive layers.

According to an aspect of the present disclosure, a device structure comprises: an alternating stack of insulating layers and electrically conductive layers, wherein the electrically conductive layers comprise a vertically neighboring pair of a first-type electrically conductive layer and a second-type electrically conductive layer that overlies the first-type electrically conductive layer; a dielectric material portion overlying the alternating stack; memory openings vertically extending through the alternating stack; memory opening fill structures located in the memory openings, wherein each of the memory opening fill structures comprises a respective vertical stack of memory elements and a vertical semiconductor channel; and a coaxial double contact via structure vertically extending through the dielectric material portion and comprising: an inner layer contact via structure contacting the first-type electrically conductive layer; at least one insulating spacer layer comprising a respective tubular insulating portion that laterally surrounds the inner layer contact via structure; and an outer layer contact via structure comprising a tubular conductive portion that laterally surrounds the at least one insulating spacer layer and contacting the second-type electrically conductive layer.

According to another aspect of the present disclosure, a method of forming a device structure comprises: forming a combination of an alternating stack of insulating layers and electrically conductive layers, wherein the electrically conductive layers comprise a vertically neighboring pair of a first-type electrically conductive layer and a second-type electrically conductive layer that overlies the first-type electrically conductive layer; forming a dielectric material portion over the alternating stack; forming a memory opening through the alternating stack; forming a memory opening fill structure comprising a vertical stack of memory elements and a vertical semiconductor channel in the memory opening; and forming a coaxial double contact via structure comprising a combination of an outer layer contact via structure, at least one insulating spacer layer, and an inner layer contact via structure through the stepped dielectric material portion and on the first-type electrically conductive layer and the second-type electrically conductive layer such that the inner layer contact via structure contacts the first-type electrically conductive layer, the at least one insulating spacer layer laterally surrounds the inner layer contact via structure, and the outer layer contact via structure laterally surrounds the at least one insulating spacer layer and contacts the second-type electrically conductive layer.

### BRIEF DESCRIPTION OF THE DRAWINGS

FIG. 1 is a schematic vertical cross-sectional view of a first exemplary structure after formation of an alternating stack of insulating layers and sacrificial material layers over a carrier substrate according to an embodiment of the present disclosure.

FIG. 2 is a schematic vertical cross-sectional view of the first exemplary structure after formation of stepped surfaces and a stepped dielectric material portion according to an embodiment of the present disclosure.

FIG. 3A is a schematic vertical cross-sectional view of the first exemplary structure after formation of memory openings and support openings according to an embodiment of the present disclosure. FIG. 3B is a top-down view of the first exemplary structure of FIG. 3A. The hinged vertical cross-sectional plane A-A′ is the cut plane of the vertical cross-sectional view of FIG. 3A.

FIG. 4 is a schematic vertical cross-sectional view of the first exemplary structure after formation of sacrificial opening fill structures according to an embodiment of the present disclosure.

FIG. 5 is a vertical cross-sectional view of the first exemplary structure after formation of support pillar structures according to an embodiment of the present disclosure.

FIG. 6 is a schematic vertical cross-sectional view of the first exemplary structure after removal of sacrificial memory opening fill structures according to an embodiment of the present disclosure.

FIGS. 7A-7F are sequential vertical cross-sectional views of a memory opening during formation of a memory opening fill structure according to an embodiments of the present disclosure.

FIG. 8A is a schematic vertical cross-sectional view of the first exemplary structure after formation of memory opening fill structures according to an embodiment of the present disclosure. FIG. 8B is a top-down view of the first exemplary structure of FIG. 8A. The vertical plane A-A is the cut plane of the vertical cross-sectional view of FIG. 8A.

FIG. 9A is a vertical cross-sectional view of the first exemplary structure after formation of a contact-level dielectric layer and lateral isolation trenches according to an embodiment of the present disclosure. FIG. 9B is a top-down view of the first exemplary structure of FIG. 9A. The vertical plane A-A is the cut plane of the vertical cross-sectional view of FIG. 9A.

FIG. 10 is a vertical cross-sectional view of the first exemplary structure after formation of laterally-extending cavities according to an embodiment of the present disclosure.

FIG. 11A is a schematic vertical cross-sectional view of the first exemplary structure after formation of electrically conductive layers according to an embodiment of the present disclosure. FIG. 11B is a magnified view of a region of the first exemplary structure of FIG. 11A.

FIG. 12A is a vertical cross-sectional view of the first exemplary structure after formation of lateral isolation trench fill structures and drain-select-level isolation structures according to an embodiment of the present disclosure. FIG. 12B is a top-down view of the first exemplary structure of FIG. 12A. The vertical plane A-A is the cut plane of the vertical cross-sectional view of FIG. 12A.

FIG. 13A is a vertical cross-sectional view of the first exemplary structure after formation of layer contact cavities and drain contact cavities to the embodiment of the present disclosure. FIG. 13B is a top-down view of the first exemplary structure of FIG. 13A. The hinged vertical cross-sectional plane A-A′ in FIG. 13B is the cut plane of the vertical cross-sectional view of FIG. 13A. FIG. 13C is a vertical cross-sectional view of a region of the first exemplary structure along the vertical plane C-C′ of FIG. 13B.

FIGS. 14A-14I are sequential vertical cross-sectional views of a region around a layer contact via cavity during formation of a coaxial double contact via structure according to a first embodiment of the present disclosure.

FIG. 15A is a vertical cross-sectional view of the first exemplary structure after formation of drain contact via structures and coaxial double contact via structures according to an embodiment of the present disclosure. FIG. 15B is a top-down view of the first exemplary structure of FIG. 15A. The vertical plane A-A is the cut plane of the vertical cross-sectional view of FIG. 15A. FIG. 15C is a vertical cross-sectional view of a region of the first exemplary structure along the vertical plane C-C′ of FIG. 15B.

FIG. 16A is a vertical cross-sectional view of the first exemplary structure after formation of a memory die according to an embodiment of the present disclosure. FIG. 16B is a magnified view of a region of the first exemplary structure of FIG. 16A around a coaxial double contact via structure.

FIG. 17 is a vertical cross-sectional view of a logic die according to an embodiment of the present disclosure.

FIG. 18 is a vertical cross-sectional view of the first exemplary structure after attaching the logic die to the memory die according to an embodiment of the present disclosure.

FIG. 19 is a vertical cross-sectional view of the first exemplary structure after removal of a carrier substrate according to an embodiment of the present disclosure.

FIG. 20A is a vertical cross-sectional view of the first exemplary structure after formation of a source layer and backside contact structures according to an embodiment of the present disclosure. FIG. 20B is a magnified view of a region of the first exemplary structure of FIG. 20A around a coaxial double contact via structure.

FIGS. 21A-21E are sequential vertical cross-sectional views of a region around a layer contact via cavity during formation of a coaxial double contact via structure and overlying upper-level metal interconnect structures in a second embodiment of the first exemplary structure.

FIGS. 22A-22I are sequential vertical cross-sectional views of a region around a layer contact via cavity during formation of a coaxial double contact via structure and overlying upper-level metal interconnect structures in a third embodiment of the first exemplary structure.

FIG. 23A is a vertical cross-sectional view of a second exemplary structure after formation of an alternating stack of insulating layers and sacrificial material layers, patterning of the alternating stack, formation of a stepped dielectric material portion, and formation of memory openings according to an embodiment of the present disclosure. FIG. 23B is a top-down view of the second exemplary structure of FIG. 23A. The hinged vertical plane A-A′ is the cut plane of the vertical cross-sectional view of FIG. 23A.

FIG. 24A is a vertical cross-sectional view of the second exemplary structure after formation of memory opening fill structures in the memory openings according to an embodiment of the present disclosure. FIG. 24B is a top-down view of the second exemplary structure of FIG. 24A. The hinged vertical plane A-A′ is the cut plane of the vertical cross-sectional view of FIG. 24A.

FIG. 25A is a vertical cross-sectional view of the second exemplary structure after formation of lateral isolation trenches according to an embodiment of the present disclosure. FIG. 25B is a top-down view of the second exemplary structure of FIG. 25A. The hinged vertical plane A-A′ is the cut plane of the vertical cross-sectional view of FIG. 25A.

FIG. 26 is a vertical cross-sectional view of the second exemplary structure after formation of lateral recesses according to an embodiment of the present disclosure.

FIG. 27A is a vertical cross-sectional view of the second exemplary structure after formation of electrically conductive layers according to an embodiment of the present disclosure. FIG. 27B is a magnified view of a region of the second exemplary structure of FIG. 27A around a memory opening fill structure.

FIG. 28A is a vertical cross-sectional view of the second exemplary structure after formation of lateral isolation trench fill structures and drain-select-level isolation structures according to an embodiment of the present disclosure. FIG. 28B is a top-down view of the second exemplary structure of FIG. 28A. The hinged vertical plane A-A′ is the cut plane of the vertical cross-sectional view of FIG. 28A.

FIG. 29A is a vertical cross-sectional view of the second exemplary structure after formation of drain contact via cavities according to an embodiment of the present disclosure.

FIG. 29B is a top-down view of the second exemplary structure of FIG. 29A. The hinged vertical plane A-A′ is the cut plane of the vertical cross-sectional view of FIG. 29A.

FIG. 30A is a vertical cross-sectional view of the second exemplary structure after formation of layer contact via cavities according to an embodiment of the present disclosure.

FIG. 30B is a top-down view of the second exemplary structure of FIG. 30A. The hinged vertical plane A-A′ is the cut plane of the vertical cross-sectional view of FIG. 30A.

FIG. 31A is a vertical ross-sectional view of the second exemplary structure after formation of at least one outer metallic material layer according to an embodiment of the present disclosure. FIG. 31B is a magnified view of a region of the second exemplary structure of FIG. 31A around a layer contact via cavity.

FIG. 32A is a vertical ross-sectional view of the second exemplary structure after formation of an outer insulating spacer material layer according to an embodiment of the present disclosure. FIG. 32B is a magnified view of a region of the second exemplary structure of FIG. 32A around a layer contact via cavity.

FIG. 33A is a vertical ross-sectional view of the second exemplary structure after formation of sacrificial via fill structures according to an embodiment of the present disclosure. FIG. 33B is a magnified view of a region of the second exemplary structure of FIG. 33A around a layer contact via cavity.

FIG. 34A is a vertical ross-sectional view of the second exemplary structure after formation of a patterned etch mask layer according to an embodiment of the present disclosure. FIG. 34B is a magnified view of a region of the second exemplary structure of FIG. 34A around a layer contact via cavity.

FIG. 35A is a vertical ross-sectional view of the second exemplary structure after removal of the sacrificial via fill structures according to an embodiment of the present disclosure. FIG. 35B is a magnified view of a region of the second exemplary structure of FIG. 35A around a layer contact via cavity.

FIG. 36A is a vertical ross-sectional view of the second exemplary structure after a first anisotropic etch process that vertically extends voids in the layer contact via cavities according to an embodiment of the present disclosure. FIG. 36B is a magnified view of a region of the second exemplary structure of FIG. 36A around a layer contact via cavity.

FIG. 37A is a vertical ross-sectional view of the second exemplary structure after anisotropic deposition of a patterning film according to an embodiment of the present disclosure. FIG. 37B is a magnified view of a region of the second exemplary structure of FIG. 37A around a layer contact via cavity.

FIG. 38A is a vertical ross-sectional view of the second exemplary structure after a second anisotropic etch process that vertically extends voids in the layer contact via cavities according to an embodiment of the present disclosure. FIG. 38B is a magnified view of a region of the second exemplary structure of FIG. 38A around a layer contact via cavity.

FIG. 39A is a vertical ross-sectional view of the second exemplary structure after an isotropic etch process that isotropically etches physically exposed portions of the electrically conductive layers according to an embodiment of the present disclosure. FIG. 38B is a magnified view of a region of the second exemplary structure of FIG. 38A around a layer contact via cavity.

FIG. 40A is a vertical ross-sectional view of the second exemplary structure after formation of an inner insulating spacer material layer according to an embodiment of the present disclosure. FIG. 40B is a magnified view of a region of the second exemplary structure of FIG. 40A around a layer contact via cavity.

FIG. 41A is a vertical ross-sectional view of the second exemplary structure after performing an anisotropic etch process that etches horizontally-extending portions of the inner insulating spacer material layer according to an embodiment of the present disclosure.

FIG. 41B is a magnified view of a region of the second exemplary structure of FIG. 41A around a layer contact via cavity.

FIG. 42 is a vertical ross-sectional view of the second exemplary structure after formation of connection via cavities according to an embodiment of the present disclosure.

FIG. 43A is a vertical ross-sectional view of the second exemplary structure after deposition of at least one inner metallic material layer according to an embodiment of the present disclosure. FIG. 43B is a magnified view of a region of the second exemplary structure of FIG. 43A around a layer contact via cavity.

FIG. 44A is a vertical ross-sectional view of the second exemplary structure after patterning the at least one inner metallic material layer according to an embodiment of the present disclosure. FIG. 44B is a magnified view of a region of the second exemplary structure of FIG. 44A around a layer contact via cavity.

FIG. 45A is a vertical ross-sectional view of the second exemplary structure after applying and patterning a photoresist layer according to an embodiment of the present disclosure. FIG. 45B is a magnified view of a region of the second exemplary structure of FIG. 45A around a layer contact via cavity.

FIG. 46A is a vertical ross-sectional view of the second exemplary structure after patterning the inner layer contact via structures and the at least one inner metallic material layer according to an embodiment of the present disclosure. FIG. 46B is a magnified view of a region of the second exemplary structure of FIG. 46A around a layer contact via cavity.

FIG. 47 is a vertical cross-sectional view of the second exemplary structure after formation of a bonded assembly of a memory die and a logic die, a source layer, a backside dielectric layer, source contact pads, and backside contact pads according to an embodiment of the present disclosure.

### DETAILED DESCRIPTION

Embodiments of the present disclosure are directed to double wall contact via structures for a three-dimensional memory device and methods for manufacturing the same. Embodiments of the disclosure can be employed to form various structures including a three-dimensional memory structure, non-limiting examples of which include three-dimensional NAND memory devices.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

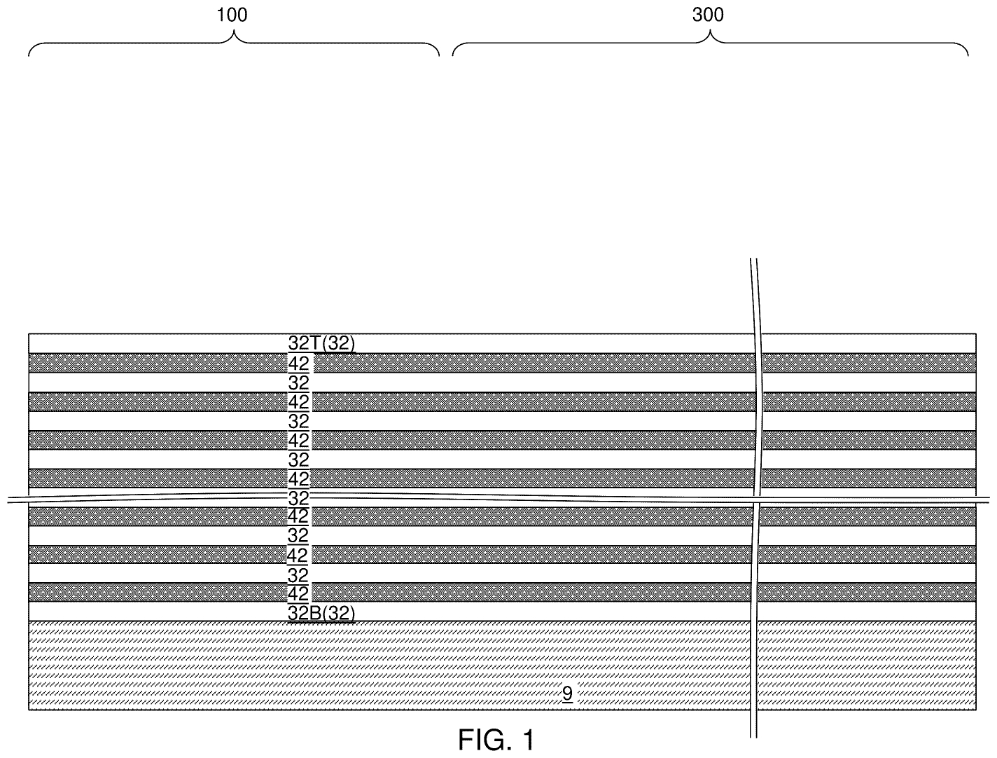

Referring to FIG. 1, a first exemplary structure according to an embodiment of the present disclosure is illustrated. The first exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective to the materials of insulating layers 32 and dielectric material portions to be subsequently formed.

An alternating stack of first material layers and second material layers can be formed over the carrier substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 (i.e., an insulating layer 32 that is most proximal to the carrier substrate 9) is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about one half of the thickness of other insulating layers 32.

The first exemplary structure comprises a memory array region 100 in which a three-dimensional array of memory elements is to be subsequently formed, and a contact region 300 in which layer contact via structures contacting word lines are to be subsequently formed.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

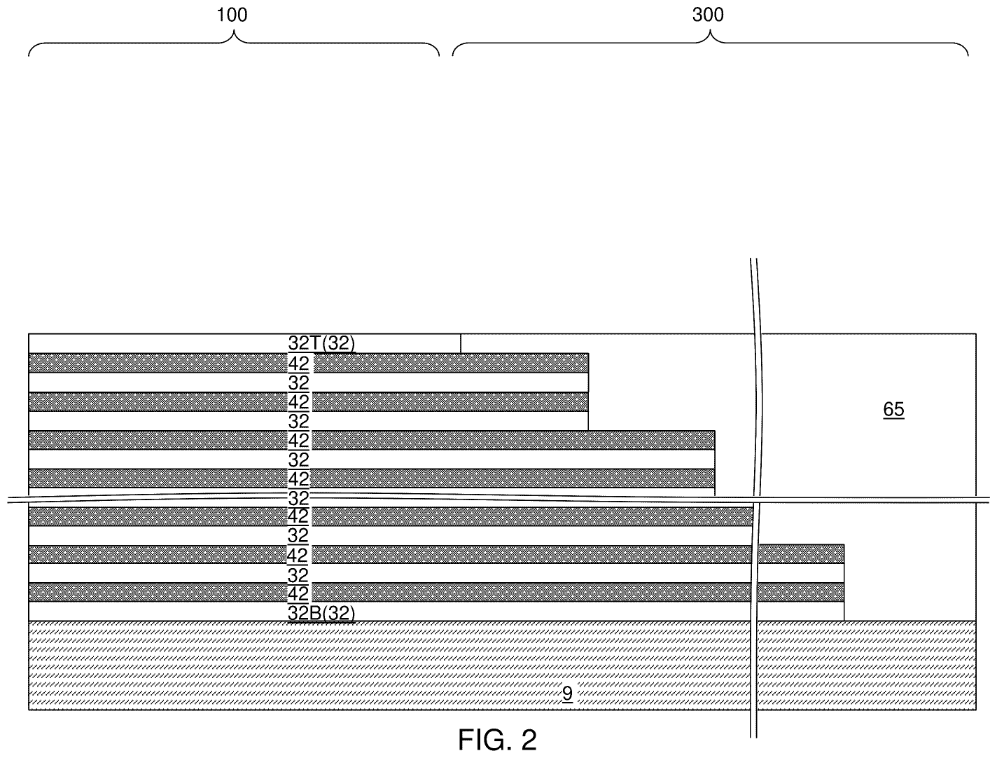

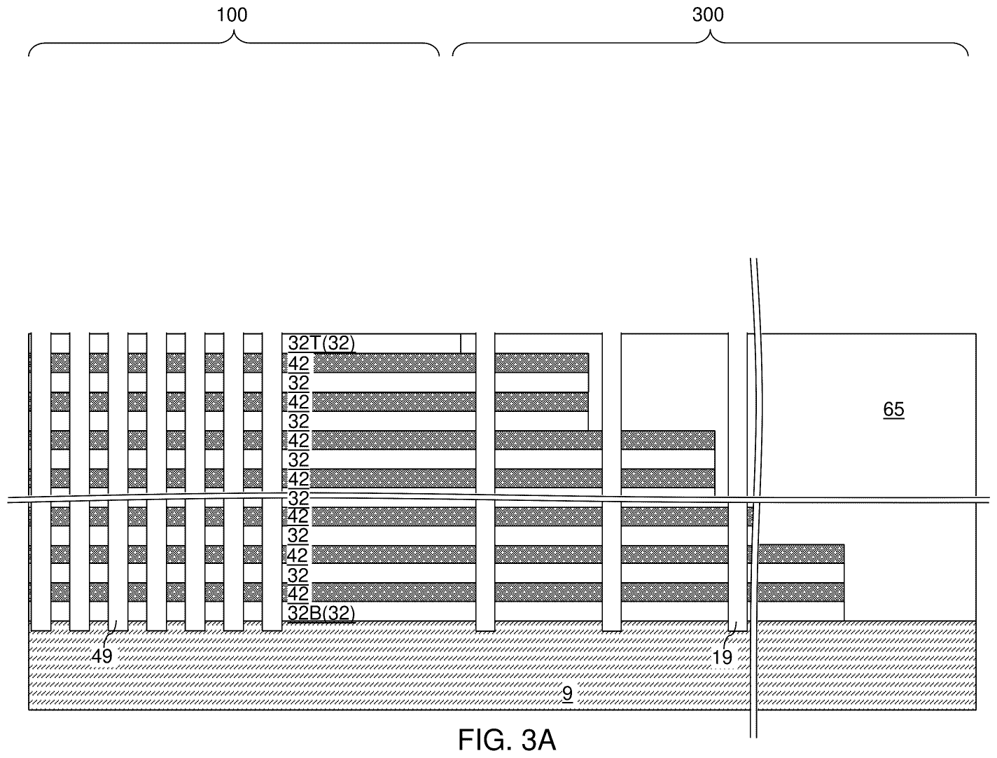

Referring to FIG. 2 stepped surfaces are formed in the contact region 300. As used herein, “stepped surfaces” refer to a set of surfaces that include at least two horizontally-extending surfaces and at least two vertically extending surfaces such that each horizontally-extending surface is adjoined to a first vertically extending surface that extends upward from a first edge of the horizontally-extending surface, and is adjoined to a second vertically extending surface that extends downward from a second edge of the horizontally-extending surface. A stepped cavity is formed within the volume from which portions of the alternating stack (32, 42) are removed through formation of the stepped surfaces. A “stepped cavity” refers to a cavity having stepped surfaces.

Each sacrificial material layer 42 other than a topmost sacrificial material layer 42 within the alternating stack (32, 42) laterally extends farther than any overlying sacrificial material layer 42 within the alternating stack (32, 42) in each staircase. Each contiguous set of stepped surfaces of the alternating stack (32, 42) within a respective staircase continuously extend from a bottommost layer within the alternating stack (32, 42) (such as the bottommost insulating layer 32B) to a topmost layer within the alternating stack (32, 42) (such as the topmost insulating layer 32T).

A stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the stepped dielectric material portion 65, the silicon oxide of the stepped dielectric material portion 65 may, or may not, be doped with dopants such as B, P, and/or F.

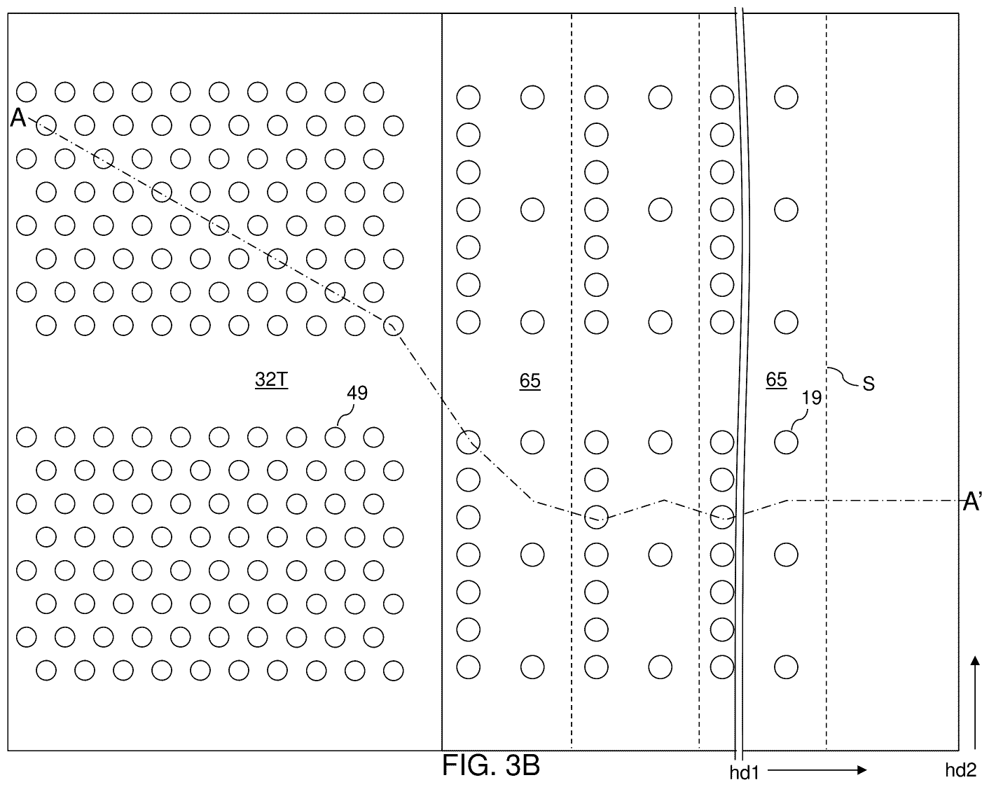

Referring to FIGS. 3A and 3B, an etch mask layer (such as a photoresist layer) can be formed over the alternating stack (32, 42), and can be lithographically patterned to form openings in the memory array region 100 and in the contact region 300. An anisotropic etch process can be performed to transfer the pattern of the openings in the etch mask layer through the stepped dielectric material portion 65 and the alternating stack (32, 42). Memory openings 49 are formed through the alternating stack (32, 42) in the memory array region 100. Support openings 19 can optionally be formed through the stepped dielectric material portion 65 and the alternating stack (32, 42) in the contact region 300.

Each of the memory openings 49 and the support openings 19 can vertically extend into the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser and greater diameters may be employed. The support openings 19 may have a diameter in a range from 60 nm to 400 nm, such as from 120 nm to 300 nm, although lesser and greater diameters may be employed.

Each cluster of memory openings 49 (which corresponds to an area of a memory block) may comprise a plurality of rows of memory openings 49. Each row of memory openings 49 may comprise a plurality of memory openings 49 that are arranged along the first horizontal direction hd1 (which may be a word line direction) with a uniform pitch. The rows of memory openings 49 may be laterally spaced from each other along the second horizontal direction hd2 (which may be a bit line direction), which may be perpendicular to the first horizontal direction hd1. In one embodiment, each cluster of memory openings 49 may be formed as a two-dimensional periodic array of memory openings 49.

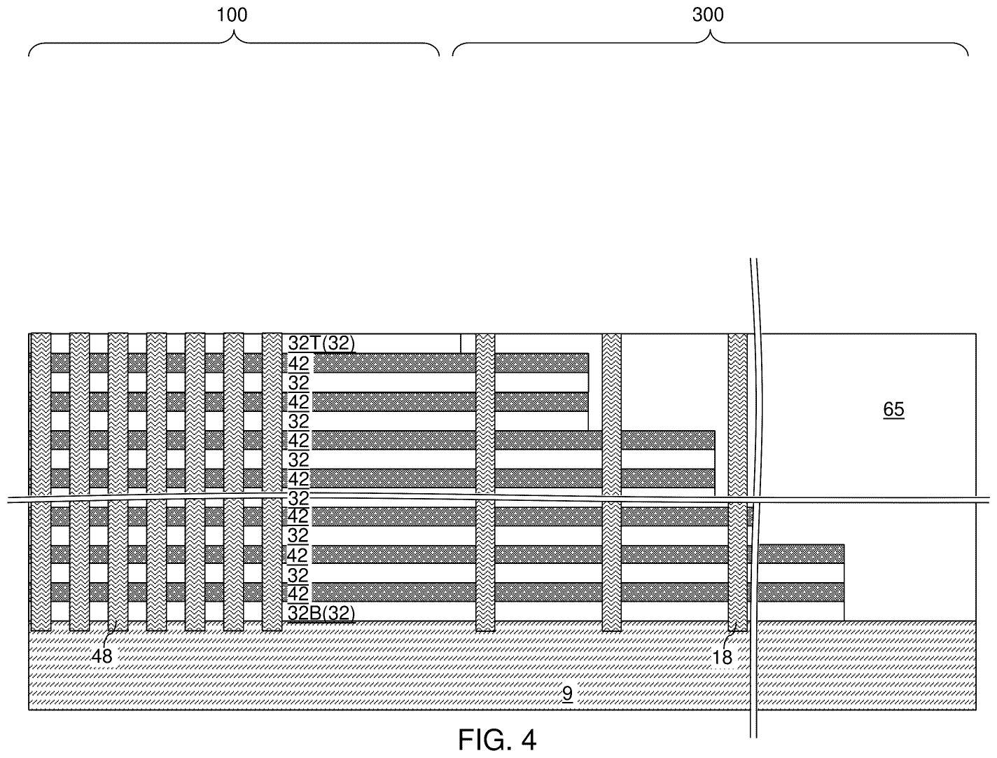

Referring to FIG. 4, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium), a polymer material, or a dielectric material (such as organosilicate glass or borosilicate glass). Excess portions of the sacrificial fill material may be removed from above the horizontal plane including the top surface of the topmost insulating layer 32T. Each remaining portion of the sacrificial fill material that fills a memory opening 49 constitutes a sacrificial memory opening fill structure 48. Each remaining portion of the sacrificial fill material that fills a support opening 19 constitutes a sacrificial support opening fill structure 18.

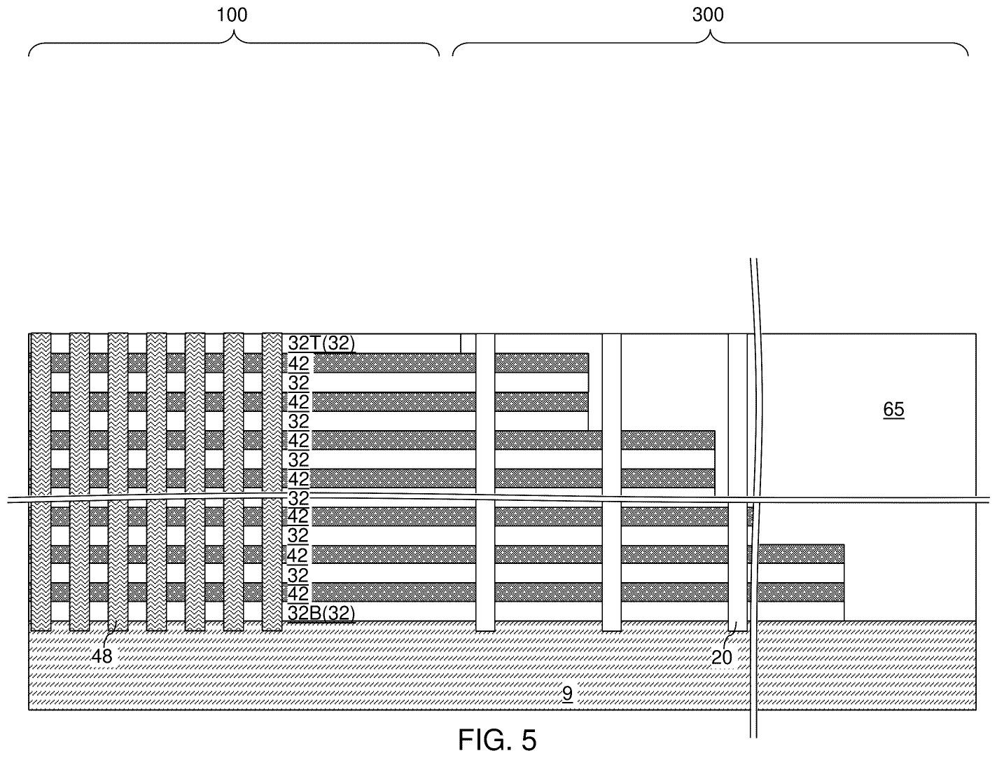

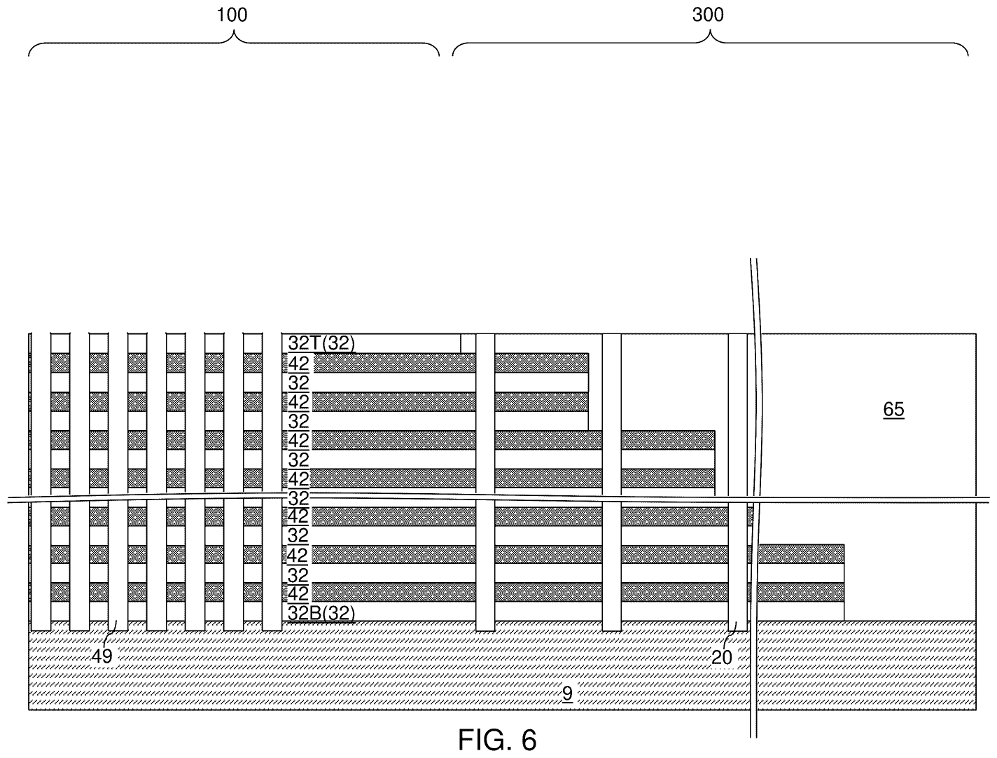

Referring to FIG. 5, a photoresist layer (not shown) can be applied over the first exemplary structure, and can be lithographically patterned to cover the sacrificial memory opening fill structures 48 in the memory array region 100 without covering the sacrificial support opening fill structures 18 in the contact region 300. The sacrificial support opening fill structures 18 are subsequently removed selective to the materials of the insulating layers 32, the sacrificial material layers 42, and the carrier substrate 9 by ashing or selective etching. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the stepped dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

Referring to FIG. 6, sacrificial memory opening fill structures 48 are subsequently removed selective to the materials of the insulating layers 32, the sacrificial material layers 42, and the carrier substrate 9. Voids are formed in the volumes of the memory openings 49 from which the sacrificial memory opening fill structures 48 are removed.

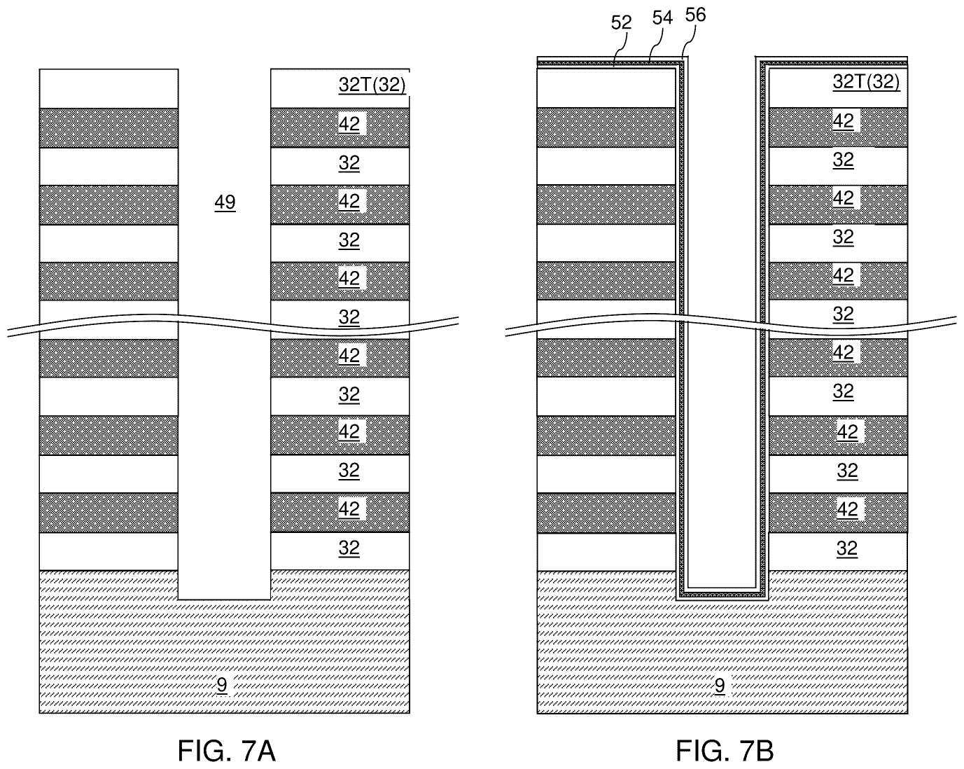

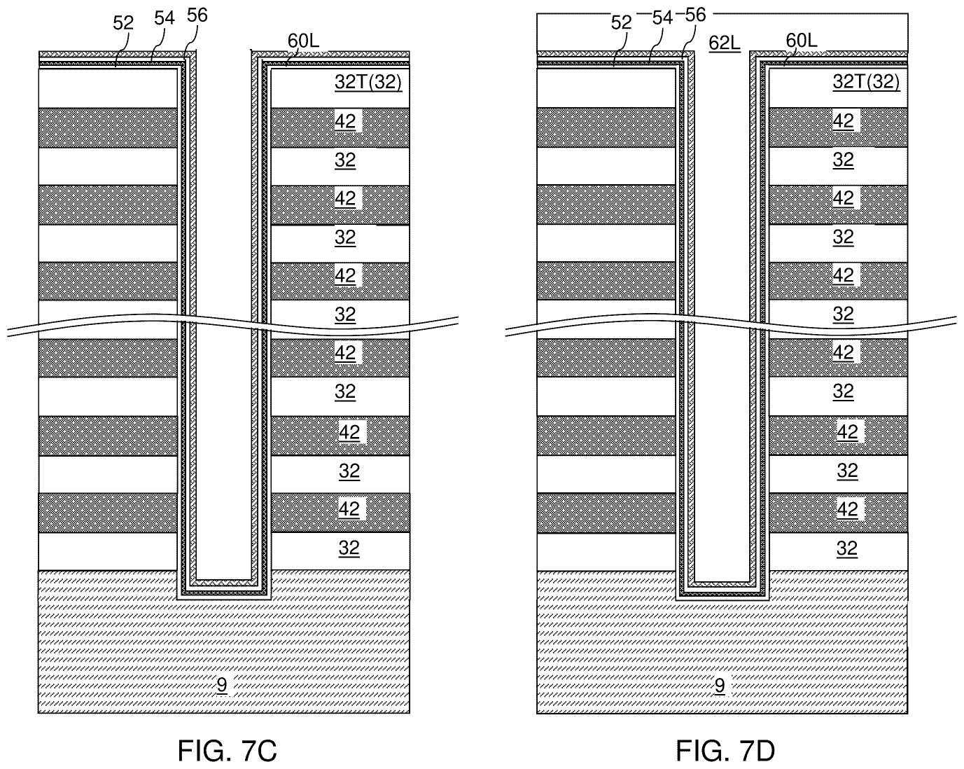

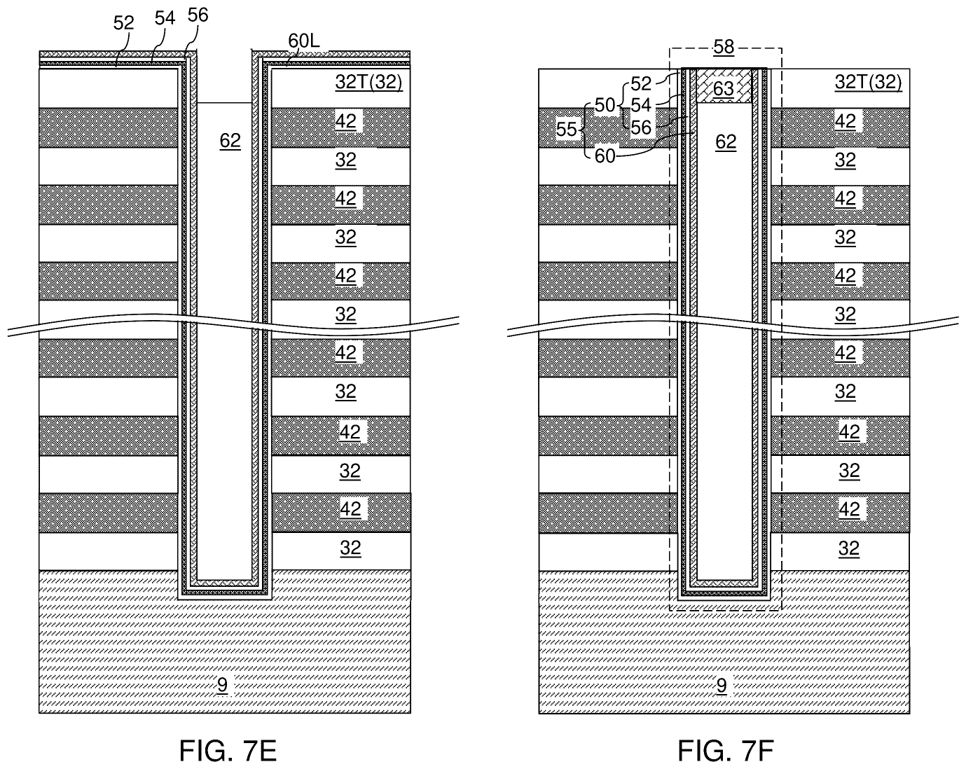

FIGS. 7A-7F are sequential vertical cross-sectional views of a memory opening 49 during formation of a memory opening fill structure 58 according to an embodiment of the present disclosure.

Referring to FIG. 7A, a memory opening 49 is illustrated after the processing steps of FIG. 6.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

Referring to FIG. 7C, a semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 7D, a dielectric core layer 62L comprising a dielectric fill material, such as silicon oxide, can be deposited in remaining volumes of the memory openings 49. The dielectric core layer 62L can be deposited employing a conformal deposition process, such as a chemical vapor deposition process.

Referring to FIG. 7E, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62.

Referring to FIG. 7F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings 19 at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extends predominantly along a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the drains extend along the specific direction.

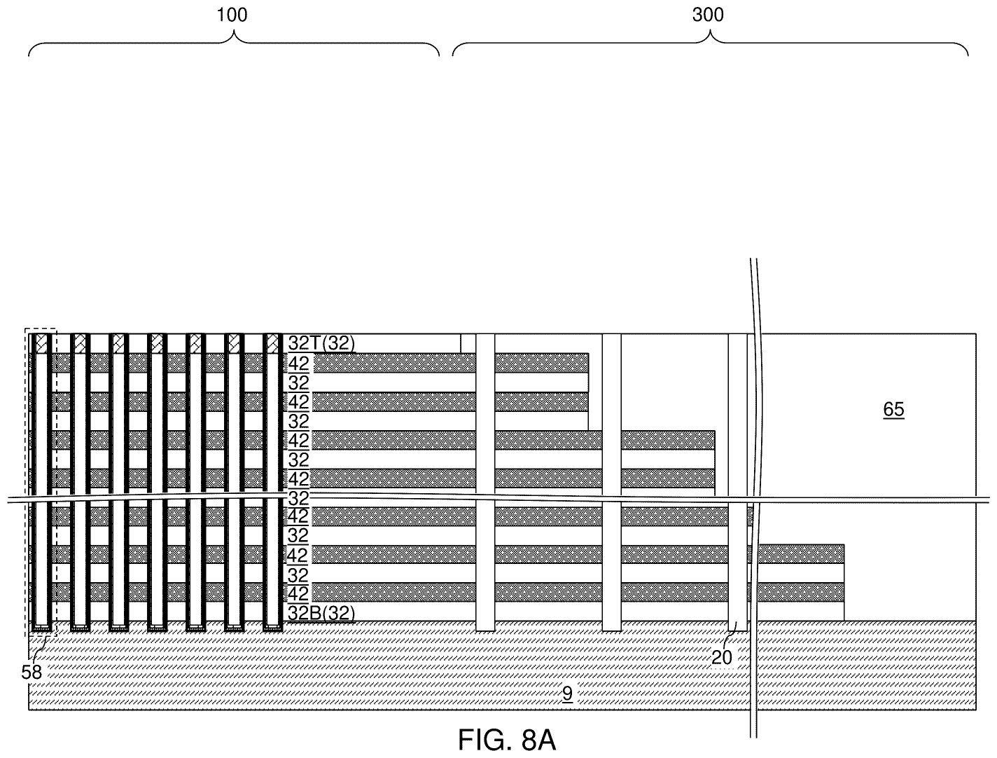

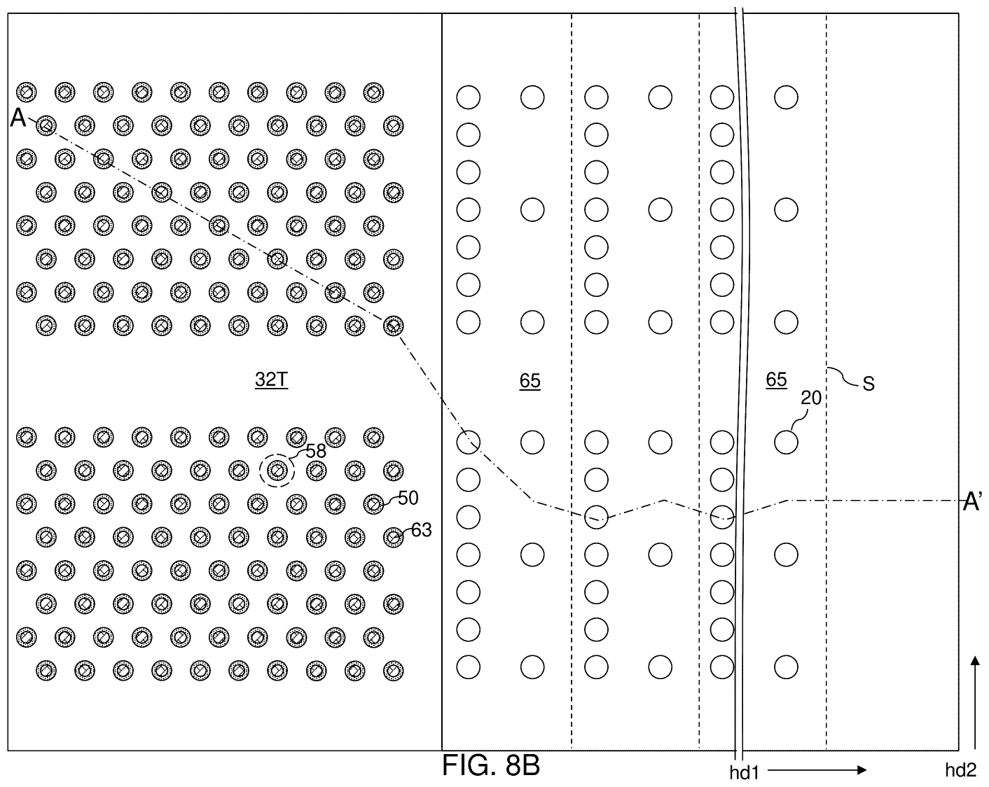

Referring to FIGS. 8A and 8B, the first exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

Thus, an alternating stack (32, 42) of insulating layers 32 and sacrificial material layers 42 is formed over a substrate (such as a carrier substrate 9). The spacer material layers are formed as or are subsequently replaced with electrically conductive layers. Memory openings 49 are formed through the alternating stack (32, 42). Memory opening fill structures 58 are formed in the memory openings 49. Each of the memory opening fill structures 58 comprises a respective memory film 50 and a respective vertical semiconductor channel 60 that is laterally surrounded by the respective memory film 50. The memory opening fill structures 58 are arranged in rows laterally extending along a first horizontal direction hd1, and the rows are laterally spaced apart from each other along a second horizontal direction hd2 that is perpendicular to the first horizontal direction hd1. Each of the memory opening fill structures 58 comprises a vertical stack of memory elements (which may comprise portions of a memory film 50 located at levels of the sacrificial material layers 42), and a respective drain region 63.

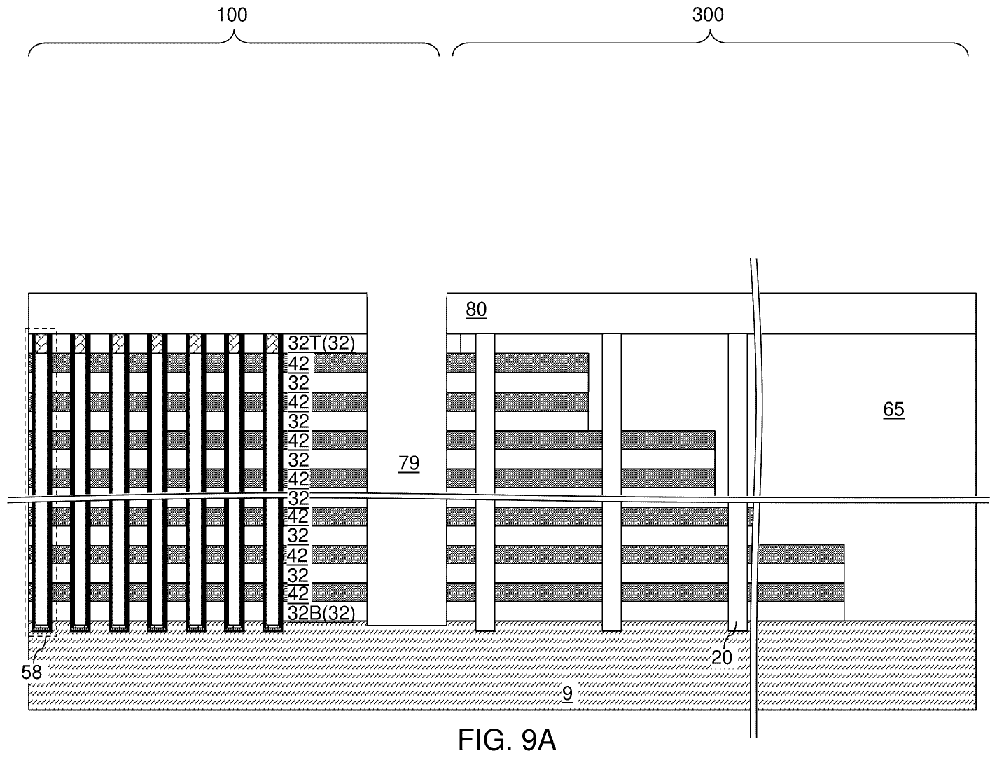

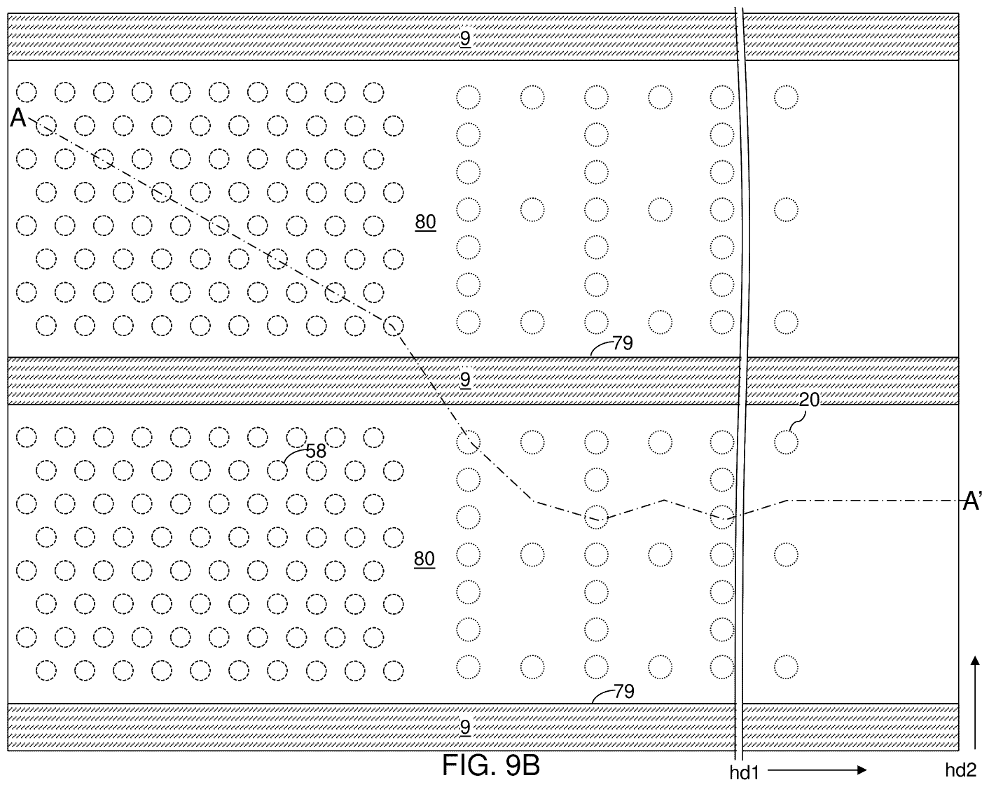

Referring to FIGS. 9A and 9B, a contact-level dielectric layer 80 can be formed over the alternating stack (32, 42), the memory opening fill structures 58, and the stepped dielectric material portion 65. The contact-level dielectric layer 80 comprises a dielectric material, such as undoped silicate glass (i.e., silicon oxide) or a doped silicate glass. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the stepped dielectric material portion 65, and to a top surface of the carrier substrate 9. Lateral isolation trenches 79 laterally extending along the first horizontal direction hd1 can be formed through the alternating stack (32, 42), the stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to the top surface of the carrier substrate 9. A surface of the carrier substrate 9 can be physically exposed underneath each lateral isolation trench 79. The photoresist layer can be subsequently removed, for example, by ashing.

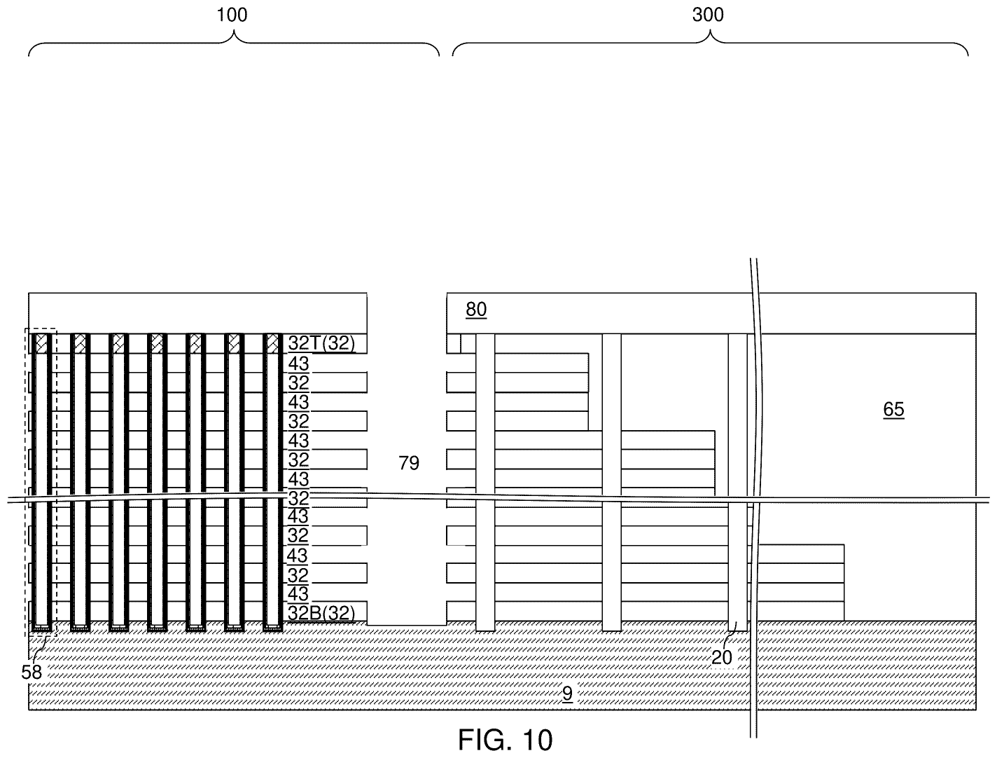

Referring to FIG. 10, an etchant that selectively etches the material of the sacrificial material layers 42 with respect to the material of the insulating layers 32 and the contact-level dielectric layer 80 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the contact-level dielectric layer 80, the stepped dielectric material portion 65, and the material of the outermost layer of the memory films 50. In one embodiment, the sacrificial material layers 42 can include silicon nitride, and the materials of the insulating layers 32 and the stepped dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, and various other materials employed in the art. The support pillar structure 20, the stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

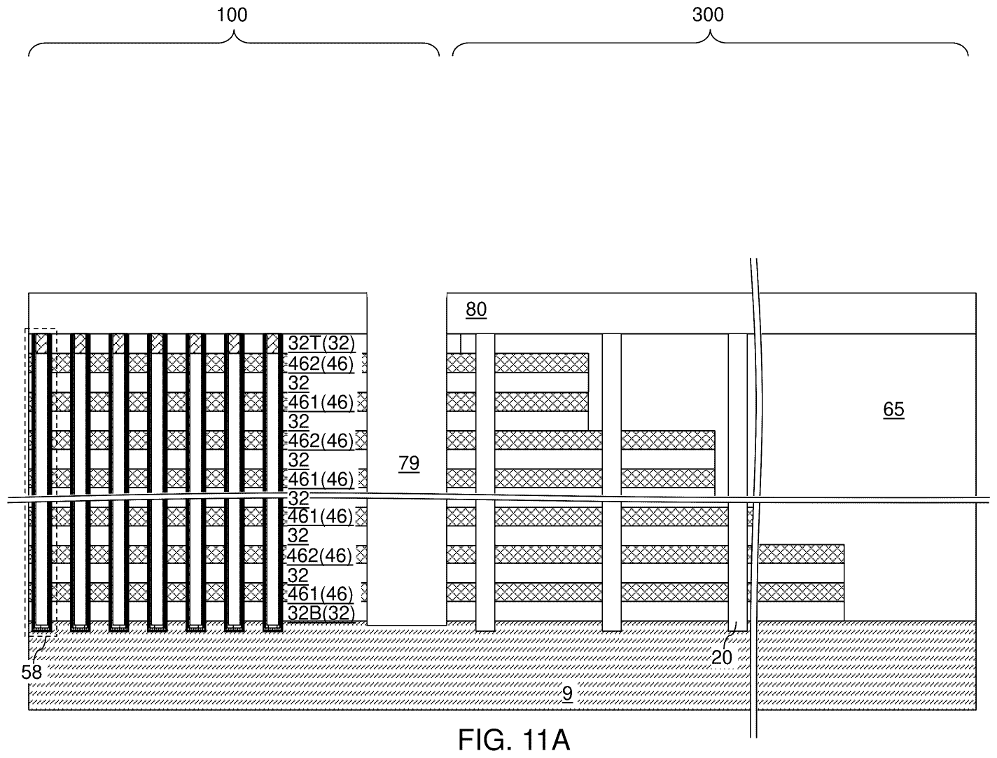

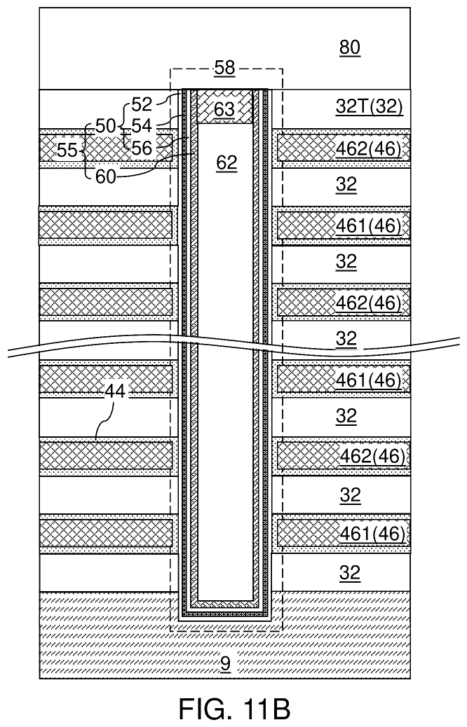

Referring to FIGS. 11A and 11B, an outer blocking dielectric layer 44 can be optionally formed. The outer blocking dielectric layer 44, if present, comprises a dielectric material that functions as a control gate dielectric for the control gates to be subsequently formed in the lateral recesses 43. In case the blocking dielectric layer 52 is present within each memory opening 49, the outer blocking dielectric layer 44 is optional. In case the blocking dielectric layer 52 is omitted, the outer blocking dielectric layer 44 is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of each lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

Each electrically conductive layer 46 may be embedded within a respective outer blocking dielectric layer 44, which may comprise a dielectric metal oxide material, such as aluminum oxide. Each outer blocking dielectric layer 44 may have a pair of horizontally-extending portions in contact with a respective one of the insulating layers 32, and a plurality of tubular portions laterally surrounding a respective one of the memory opening fill structures 58 and connecting the pair of horizontally-extending portions. The thickness of each outer blocking dielectric layer 44 may be in a range from 1 nm to 6 nm, although lesser and greater thicknesses may also be employed.

Generally, an assembly of an alternating stack (32, 46) and memory opening fill structures 58 can be formed. The alternating stack (32, 46) comprises a vertically alternating sequence of insulating layers 32 and electrically conductive layers 46. The memory opening fill structures 58 vertically extend through the alternating stack (32, 46). Each of the memory opening fill structures 58 comprises a respective vertical stack of memory elements (which may comprise portions of a memory material layer 54 located at levels of the electrically conductive layers 46), a respective vertical semiconductor channel 60, and a respective drain region 63. At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

In one embodiment, the electrically conductive layers 46 may comprise first-type electrically conductive layers 461 and second-type electrically conductive layers 462. The first-type electrically conductive layers 461 comprise a first subset of the electrically conductive layers 46, and the second-type electrically conductive layers 462 comprise a second subset of the electrically conductive layers 46. The first subset of the electrically conductive layers 46 (i.e., layers 461) comprises each electrically conductive layer 46 that does not have any top surface segment that contacts the stepped dielectric material portion 65 in case the outer blocking dielectric layers 44 are not present, or comprises each electrically conductive layer 46 that does not have any top surface segment that is vertically spaced from the stepped dielectric material portion 65 by a distance that equals the thickness of a horizontally-extending portion of an outer blocking dielectric layer 44. The second subset of the electrically conductive layers 46 (i.e., layers 462) comprises each electrically conductive layer 46 that has a top surface segment that contacts the stepped dielectric material portion 65 in case the outer blocking dielectric layers 44 are not present, or comprises each electrically conductive layer 46 that has a top surface segment that is vertically spaced from the stepped dielectric material portion 65 by a distance that equals the thickness of a horizontally-extending portion of a backside blocking dielectric layer 44.

Generally, for each pair of electrically conductive layers 46 having a same lateral extent in a plan view (and thus, having the same area in the plan view), the pair of electrically conductive layers 46 may comprise a first-type electrically conductive layer 461 and a second-type electrically conductive layer 462. In one embodiment, the electrically conductive layers 46 may comprise at least one vertically neighboring pair of a first-type electrically conductive layer 461 and a second-type electrically conductive layer 462 that overlies the first-type electrically conductive layer 461. In one embodiment, the electrically conductive layers 46 may comprise multiple vertically neighboring pairs of a first-type electrically conductive layer 461 and a second-type electrically conductive layer 462 that overlie the first-type electrically conductive layer 461. In this case, the first-type electrically conductive layer 461 underlies the second-type electrically conductive layer 462 in each vertically neighboring pair of the first-type electrically conductive layer 461 and the second-type electrically conductive layer 462.

In one embodiment, upon sequentially numbering all of the electrically conductive layers 46 with positive integers beginning with 1 from bottom to top, each odd-numbered electrically conductive layer 46 may be a first-type electrically conductive layer 461, and each even-numbered electrically conductive layer 46 may be a second-type electrically conductive layer 462.

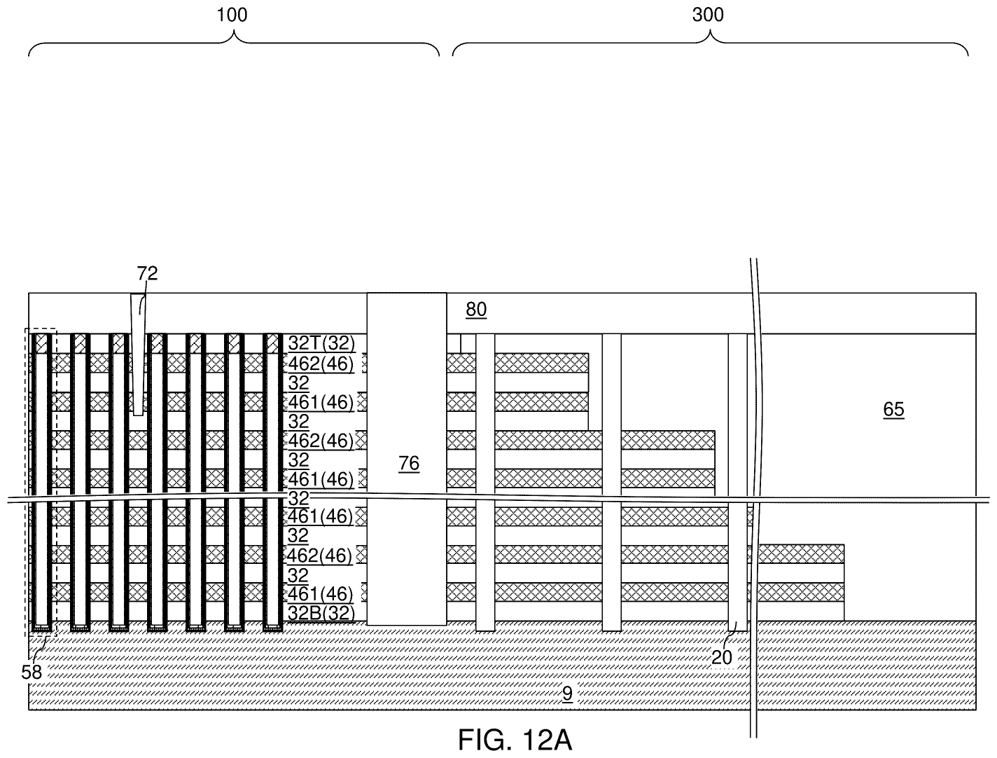

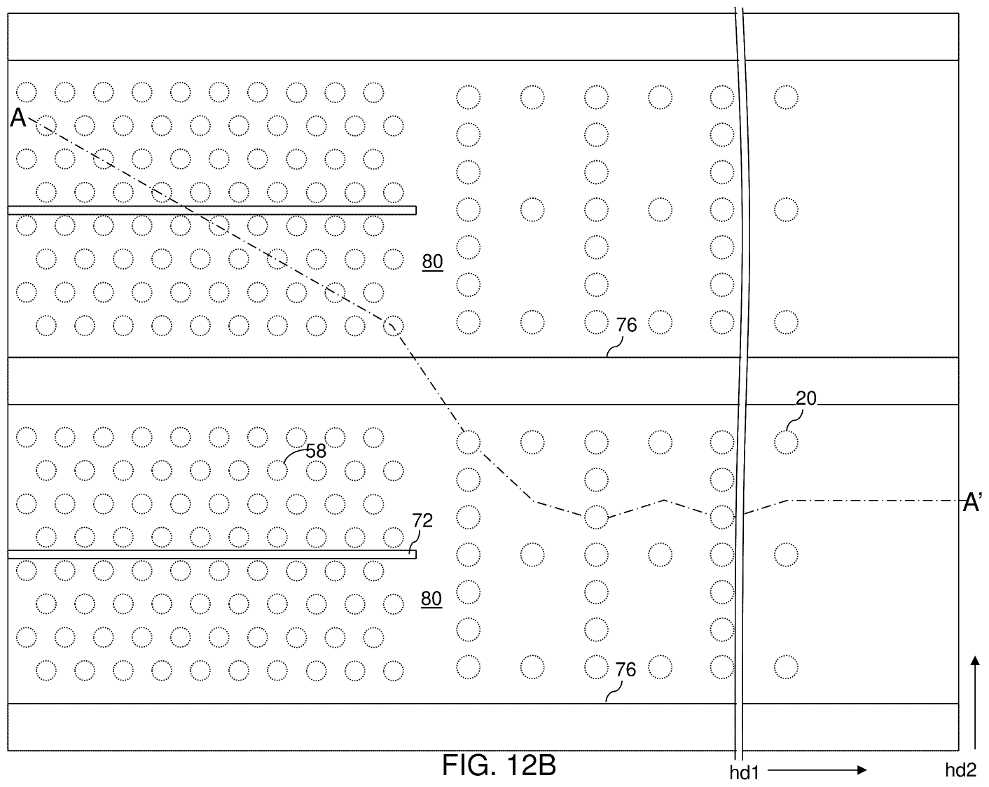

Referring to FIGS. 12A and 12B, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

An alternating stack (32, 46) of insulating layers 32 and electrically conductive layers 46 can be formed in a memory block area between each neighboring pair of lateral isolation trench fill structures 76. A first subset of the electrically conductive layers 46 can include at least one drain-select-level electrically conductive layer (i.e., at least one drain side select gate electrode) which is employed to activate or deactivate NAND strings (e.g., the memory opening fill structures 58 and adjacent portions of the electrically conductive layers 46) vertically extending through the alternating stack (32, 46). A second subset of the electrically conductive layers 46 that underlies the drain-select-level electrically conductive layers comprises word lines, which comprise control electrodes of the NAND strings. A subset of one or more bottommost electrically conductive layers 46 which underlies the word lines comprises source side select gate electrodes.

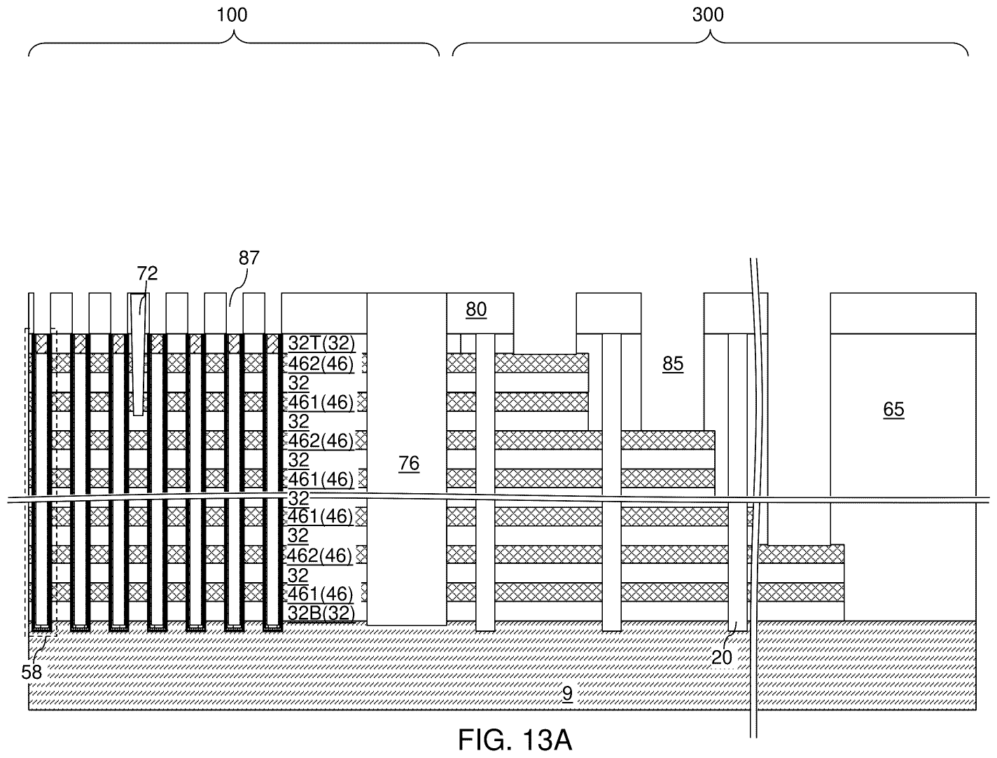

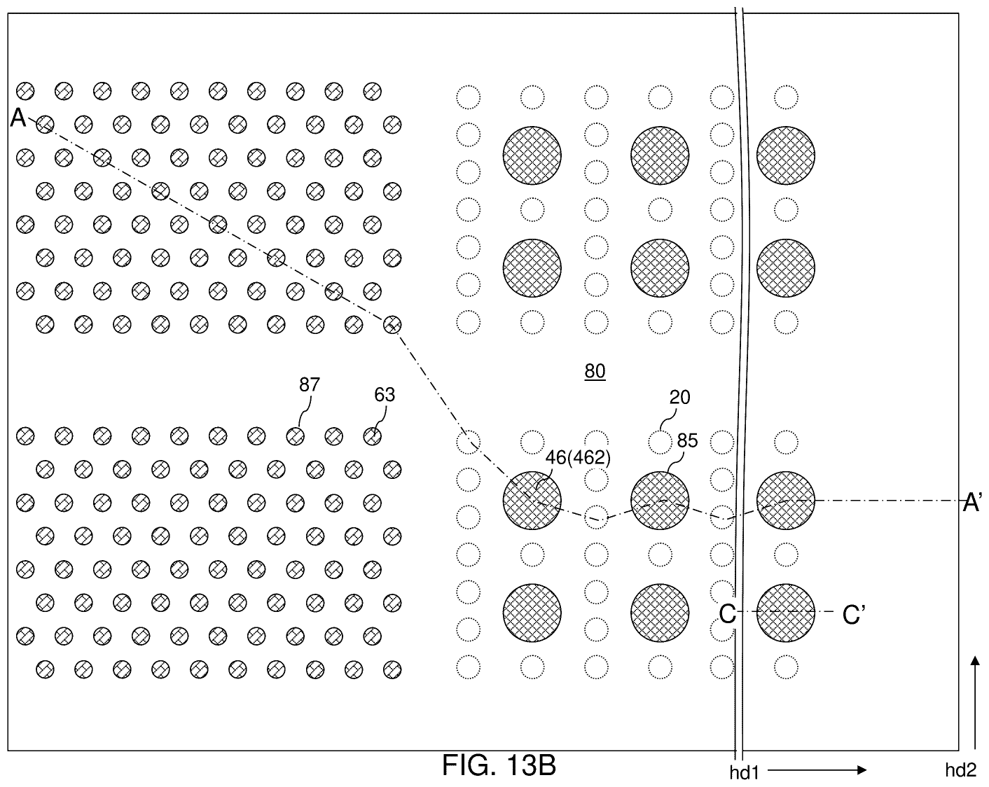

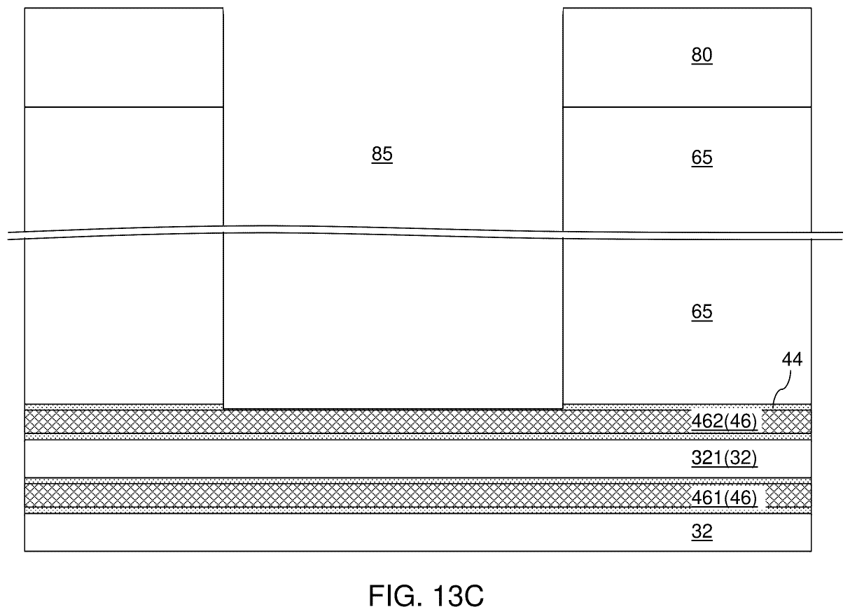

Referring to FIGS. 13A-13C, drain contact via cavities 87 and layer contact via cavities 85 can be formed by performing at least one combination of a photolithographic patterning process and an anisotropic etch process. In one embodiment, a first photoresist layer (not shown) can be performed over the contact-level dielectric layer 80, and can be lithographically patterned to form a pattern of openings having the same pattern as the arrays of memory opening fill structures 58. A first anisotropic etch process can be performed to transfer the pattern of the openings in the first photoresist layer through the contact-level dielectric layer 80. The first anisotropic etch process may etch the dielectric material of the contact-level dielectric layer 80 selective to the semiconductor material of the drain regions 63. The drain contact via cavities 87 are formed through the contact-level dielectric layer 80 such that a top surface of a drain region 63 is physically exposed underneath each drain contact via cavity 87. The first photoresist layer can be subsequently removed, for example, by ashing.

A second photoresist layer (not shown) can be applied over the contact-level dielectric layer 80, and can be lithographically patterned to form openings in areas of the horizontally-extending surface segments of a stepped bottom surface of the stepped dielectric material portion 65. A second anisotropic etch process can be performed to transfer the pattern of the openings in the second photoresist layer through the contact-level dielectric layer 80 and the stepped dielectric material portion 65. The second anisotropic etch process may have an etch chemistry that etches the materials of the contact-level dielectric layer 80 and the stepped dielectric material portion 65 selective to the material of the electrically conductive layers 46. The etch chemistry of the second anisotropic etch process may optionally also be selective to the material of the outer blocking dielectric layer 44. Layer contact via cavities 85 are formed in the volumes from which the materials of the contact-level dielectric layer 80 and the stepped dielectric material portion 65 are removed.

A layer contact via cavity 85 can be formed for each second-type electrically conductive layer 462. Thus, each second-type electrically conductive layer 462 may have a horizontally-extending surface segment that is physically exposed to a respective overlying layer contact via cavity 85. Each first-type electrically conductive layer 461 underlies a respective second-type electrically conductive layer 462, which is an overlying and neighboring electrically conductive layer 46. Thus, the first-type electrically conductive layers 461 are not physically exposed to any layer contact via cavity 85. The total number of the layer contact via cavities 85 may be the same as the total number of second-type electrically conductive layers 462. The total number of the first-type electrically conductive layers 461 may be the same as, or may be less than, the total number of the second-type electrically conductive layers 462. In one embodiment, the total number of the first-type electrically conductive layers 461 may be the same as the total number of the second-type electrically conductive layers 462. In one embodiment, the height of at least a subset of the vertically extending surface segments of the stepped bottom surface of the stepped dielectric material portion 65 may be twice the pitch of the periodicity along the vertical direction within the alternating stack (32, 46) (without consideration of the variations in the lateral extent of the layers within the alternating stack (32, 46)), i.e., twice the sum of the thickness of an insulating layer 32 and a spacing between a neighboring pair of insulating layers 32. The lateral dimension, such as a diameter, of each layer contact via cavity 85 may be in a range from 150 nm to 1,000 nm, such as from 300 nm to 600 nm, although lesser and greater dimensions may also be employed.

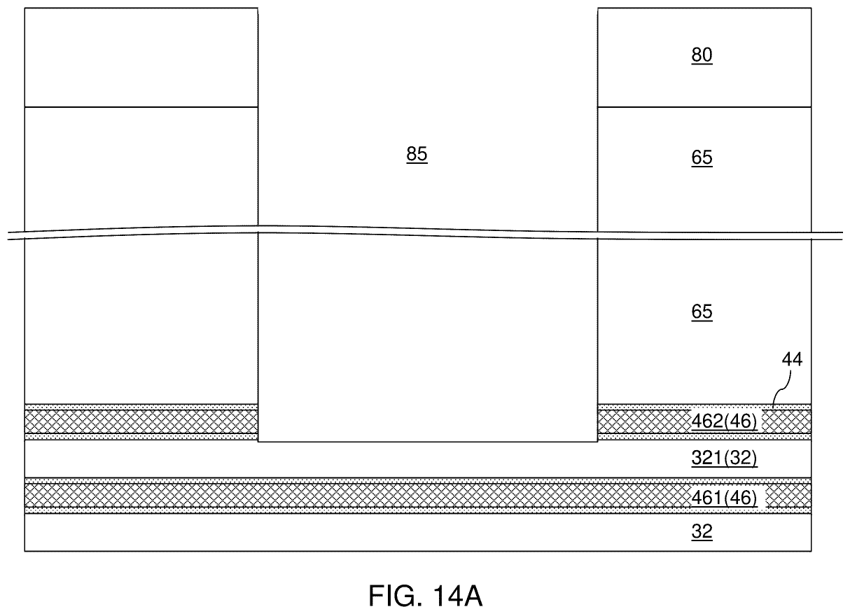

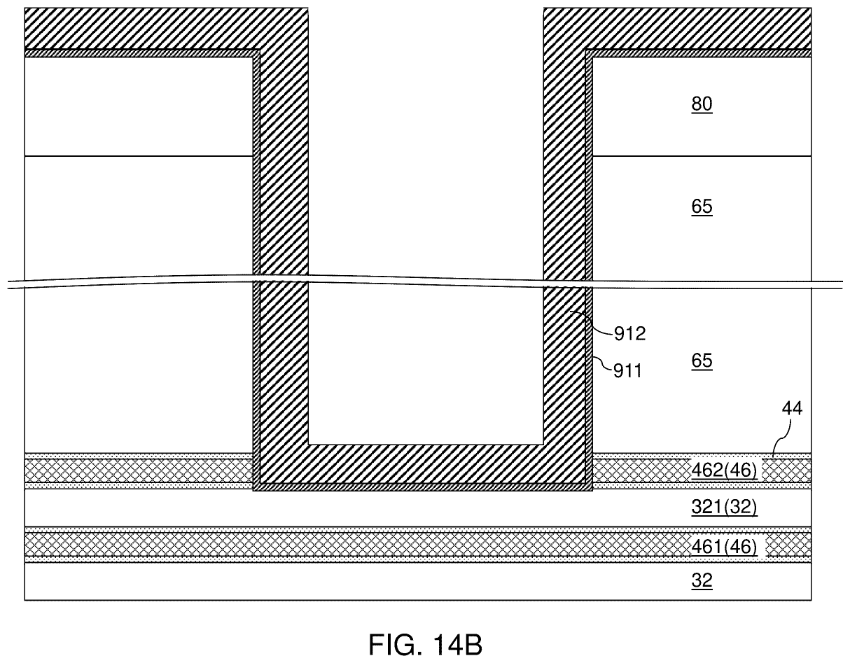

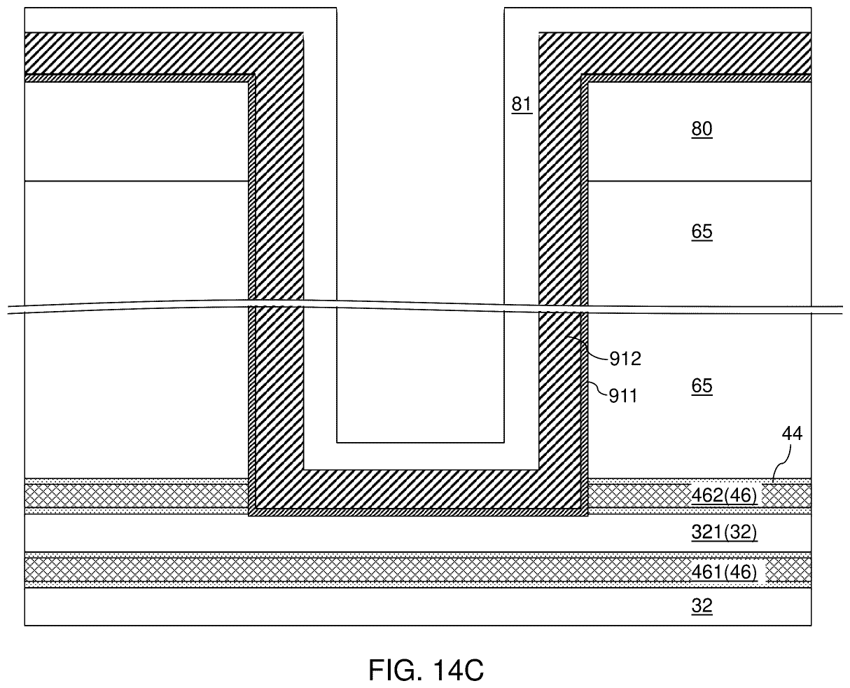

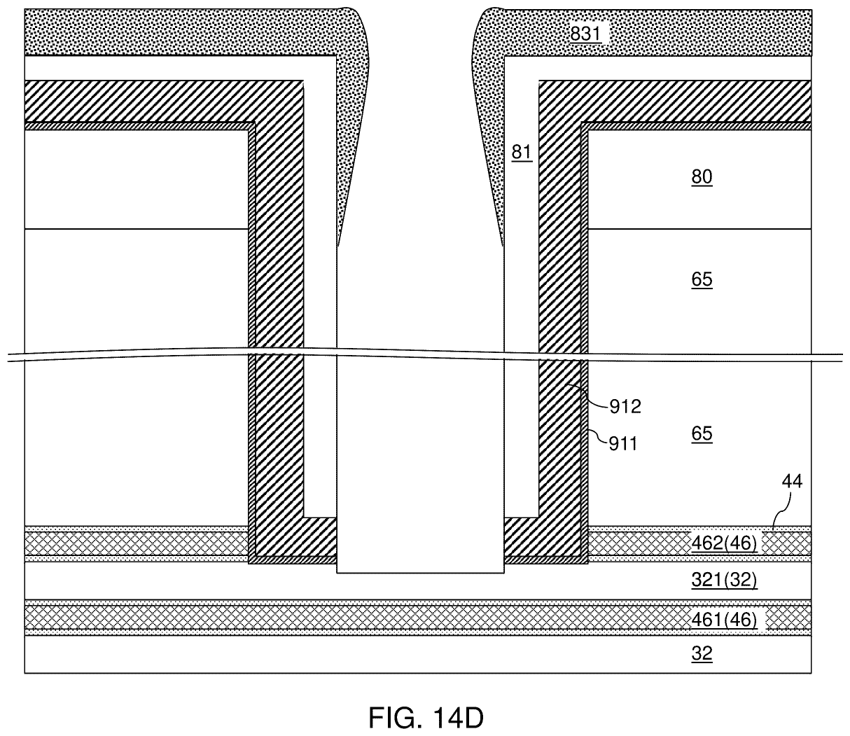

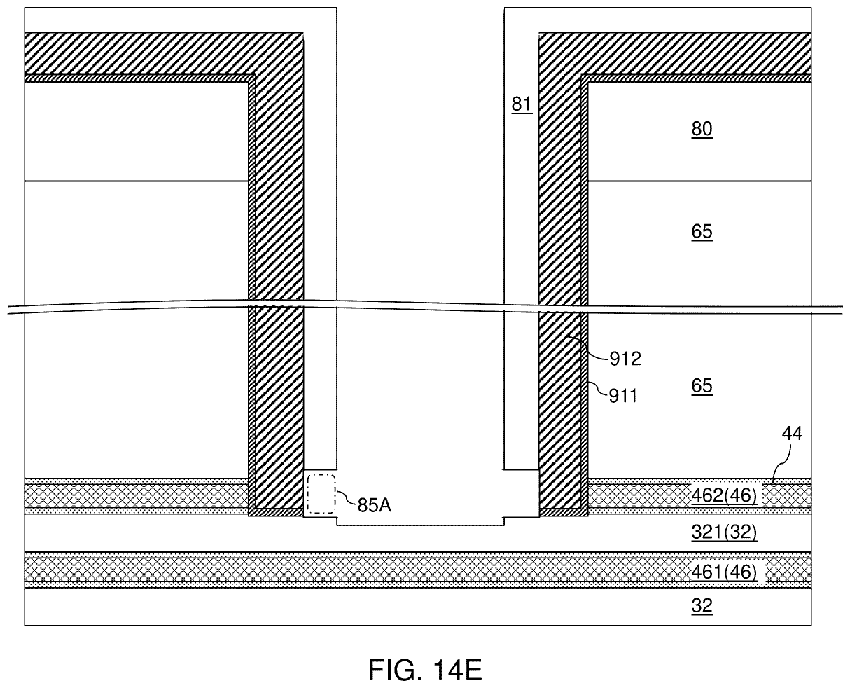

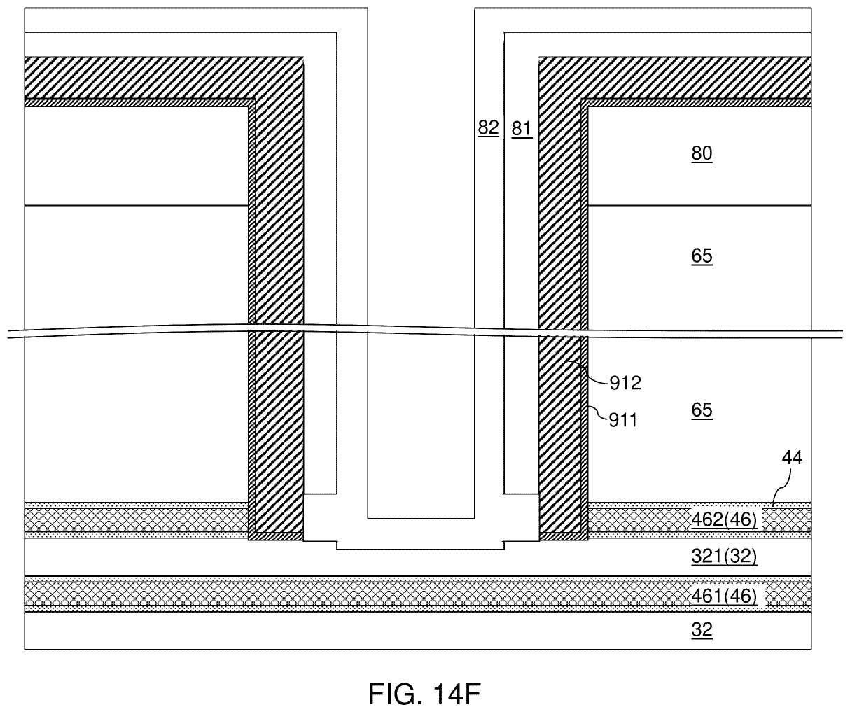

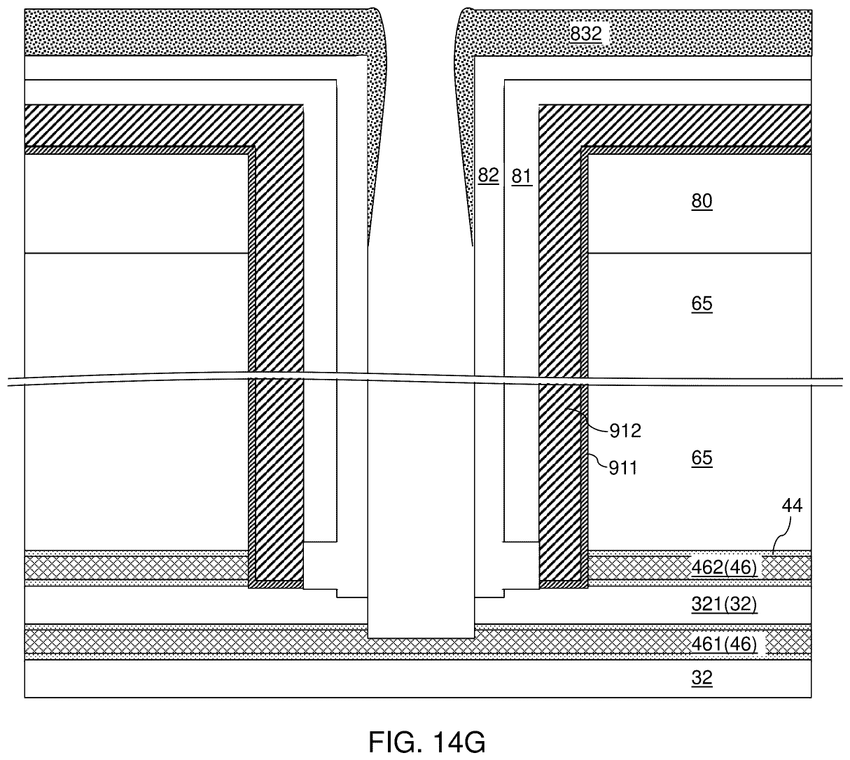

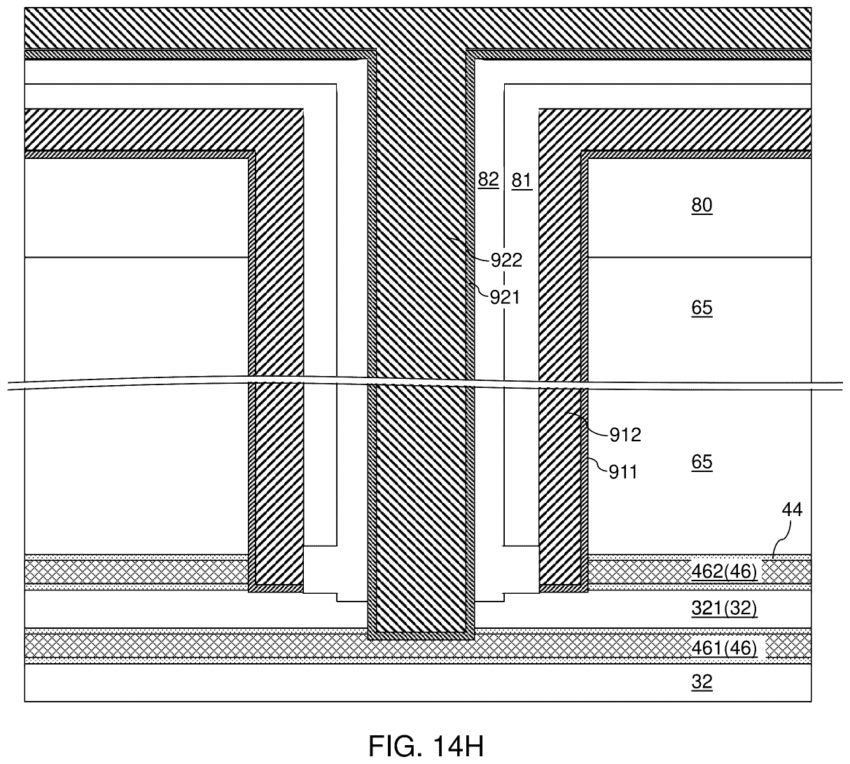

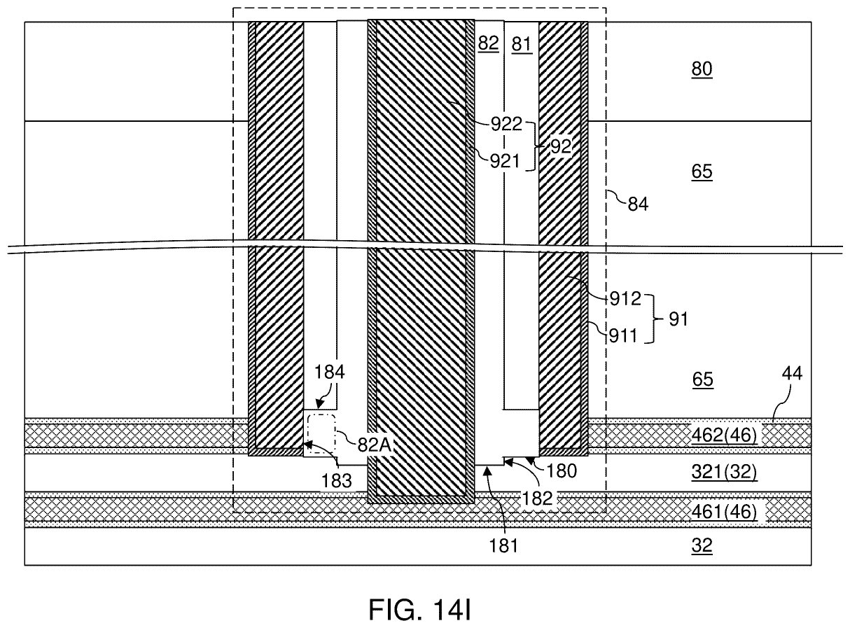

FIGS. 14A-14I are sequential vertical cross-sectional views of a region around a layer contact via cavity during formation of a coaxial double contact via structure 84 according to a first embodiment of the present disclosure.

Referring to FIG. 14A, the second anisotropic etch process can be continued with a change in the etch chemistry. Specifically, the second anisotropic etch process may comprise a terminal etch step that etches the material of the electrically conductive layers 46 selective to the material of the insulating layers 32. Each layer contact via cavity 85 can be vertically extended through a respective second-type electrically conductive layer 462, and a cylindrical surface of the respective second-type electrically conductive layer 462 can be physically exposed to the layer contact via cavity 85. In case outer blocking dielectric layers 44 are present, a horizontally-extending portion of the outer blocking dielectric layer 44 may be removed from underneath a bottom portion of a layer contact via cavity 85, which vertically extends through a second-type layer contact via cavity 85.

An insulating layer 32, which is herein referred to as a first insulating layer 321, is interposed between each neighboring pair of an underlying first-type electrically conductive layer 461 and an overlying second-type electrically conductive layer 462. A top surface segment of a first insulating layer 321 can be physically exposed underneath each layer contact via cavity 85. The second photoresist layer can be subsequently removed, for example, by ashing.

Referring to FIG. 14B, at least one outer metallic material layer (911, 912) can be deposited on the physically exposed surfaces around the layer contact via cavities 85 and over the contact-level dielectric layer 80. The at least one outer metallic material layer (911, 912) may comprise an optional outer metallic barrier liner 911 and an outer metal layer 912. The outer metallic barrier liner 911 may comprise a metallic barrier material such as TiN, TaN, WN, and/or MoN. The outer metallic barrier liner 911 may be deposited by physical vapor deposition or chemical vapor deposition. The thickness of the outer metallic barrier liner 911 may be in a range from 3 nm to 50 nm, although lesser and greater thicknesses may also be employed. The outer metallic barrier liner 911 can be formed directly on each physically exposed cylindrical surface of the second-type electrically conductive layers 462, and on each physically exposed top surface segment of the first insulating layers 321. The outer metallic barrier liner 911 may also be formed on physically exposed cylindrical surface segments of the outer blocking dielectric layers 44.

The outer metal layer 912 may comprise a metal such a W, Mo, Ti, Ta, Co, Ru, Cu, etc. The outer metal layer 912 may be deposited by physical vapor deposition, chemical vapor deposition, electroplating, or a combination thereof. The thickness of the outer metal layer 912 may be in a range from 5% to 25%, such as from 10% to 20%, of the lateral dimension of each layer contact via cavity 85 as formed at the processing steps of FIGS. 13A and 13B. For example, the thickness of the outer metal layer 912 may be in a range from 10 nm to 200 nm, although lesser and greater thicknesses may also be employed.

In one embodiment, the total thickness of the at least one outer metallic material layer (911, 912) may be greater than one half of the lateral dimension (such as the diameter) of each drain contact via cavity 87. In this case, the entire volume of each drain contact via cavity 87 can be filled with the at least one outer metallic material layer (911, 912).

Referring to FIG. 14C, an insulating spacer layer, which is herein referred to as an outer insulating spacer layer 81 can be formed by conformal deposition of an insulating material, which may comprise silicon oxide, silicon nitride, or another insulating material. The outer insulating spacer layer 81 comprises an outer insulating material, and is formed on each vertically-extending cylindrical inner sidewall of the at least one outer metallic material layer (911, 912) around the voids in the layer contact via cavities 85. The outer insulating spacer layer 81 can be deposited by a conformal deposition process such as a chemical vapor deposition process, and may have a thickness in a range from 2% to 10%, such as from 3% to 7%, of the lateral dimension of each layer contact via cavity 85 as formed at the processing steps of FIGS. 13A and 13B.

Referring to FIG. 14D, a first patterning film 831 may be optionally deposited over the horizontally-extending portion of the outer insulating spacer layer 81 that overlies the contact-level dielectric layer 80 by an anisotropic deposition process. For example, the first patterning film 831 may comprise a commercially available carbon-based etch mask material such as Advanced Patterning Film™ by Applied Materials, Inc®. Alternatively, the first patterning film 831 may be omitted, as will be described in more detail below with respect to the third embodiment. An anisotropic etch process can be performed to etch through horizontally-extending portions of the outer insulating spacer layer 81 and the at least one outer metallic material layer (911, 912) underneath the void in each layer contact via cavity 85. The anisotropic etch process vertically extends the voids located within the layer contact via cavities 85. The extended voids are laterally surrounded by a respective vertically-extending tubular portion of the outer insulating spacer layer 81. A bottom portion of the at least one outer metallic material layer (911, 912) is etched through by the anisotropic etch process from underneath each void within the layer contact via cavities 85. A surface portion of an underlying first insulating layer 321 may be collaterally recessed by the anisotropic etch process. In this case, a horizontally-extending recessed surface segment of a first insulating layer 321 may be vertically recessed relative to a topmost surface of the first insulating layer 321 underneath the void of each layer contact via cavity 85. The first patterning film 831 can be subsequently removed, for example, by ashing. Alternatively, if the first patterning film 831 is omitted, the horizontal portion of the outer insulating spacer layer 81 located above top surface of the outer metallic material layer (911, 912) and the top surface of the outer metallic material layer (911, 912) are also removed during the etching process.

Referring to FIG. 14E, at least one selective isotropic etch process can be performed to isotropically etch the metallic materials of the at least one outer metallic material layer (911, 912) selective to the insulating materials of the outer insulating spacer layer 81 and the insulating layers 32. For example, if the outer metallic barrier liner 911 comprises titanium nitride and if the outer metal layer 912 comprise tungsten, a first wet etch process employing a mixture of hydrogen peroxide and ammonium hydroxide may be employed to etch physically exposed portions of the outer metal layer 912, and a second wet etch process employing a mixture of hydrogen peroxide and sulfuric acid can be performed to etch physically exposed portions of the outer metallic barrier liner 911. The duration of each selective isotropic etch process can be selected such that the recessed surfaces of the at least one outer metallic material layer (911, 912) are approximately vertically coincident with an outer cylindrical sidewall of an overlying vertically-extending tubular portion of the outer insulating spacer layer 81.

Thus, physically exposed surfaces of the at least one outer metallic material layer (911, 912) can be laterally recessed selective to the insulating layers 32 and the outer insulating spacer layer 81 by performing a selective isotropic etch process. An annular cavity 85A is formed in each volume from which an annular portion of the at least one outer metallic material layer (911, 912) is removed. Thus, the annular cavity 85A can be formed underneath each vertically-extending tubular portion of the outer insulating spacer layer 81 in a volume from which materials of the at least one outer metallic material layer (911, 912) are etched away. A cylindrical surface segment of the outer metal layer 912 and a cylindrical surface segment of the outer metallic barrier liner 911 can be physically exposed around each annular cavity 85A.

Referring to FIG. 14F, an additional insulating spacer layer, which is herein referred to as an inner insulating spacer layer 82 can be formed by conformal deposition of an insulating material, which may comprise silicon oxide, silicon nitride, or another insulating material. The inner insulating spacer layer 82 can be deposited by a conformal deposition process, such as a chemical vapor deposition process. The thickness of the inner insulating spacer layer 82 can be greater than one half of the thickness of the at least one outer metallic material layer (911, 912). The entire volume of each annular cavity 85A can be filled within a respective portion of the inner insulating spacer layer 82. Generally, at least one insulating spacer layer (81, 82) is formed inside each vertically-extending tubular portion of the at least one outer metallic material layer (911, 912). The at least one insulating spacer layer (81, 82) comprises an inner insulating spacer layer 82 that is formed on an inner cylindrical sidewall of the outer insulating spacer layer 81, and the inner insulating spacer layer 82 fills a respective annular cavity 85A.

Referring to FIG. 14G, a second patterning film 832 may be optionally deposited over the horizontally-extending portion of the inner insulating spacer layer 82 that overlies the contact-level dielectric layer 80 by an anisotropic deposition process. For example, the second patterning film 832 may comprise a commercially available carbon-based etch mask material. Alternatively, the second patterning film 832 may be omitted, as will be described in more detail with respect to the third embodiment. An anisotropic etch process can be performed to etch through horizontally-extending portions of the inner insulating spacer layer 82 and underlying portions of the first insulating layers 321 underneath the void in each layer contact via cavity 85. Each horizontally-extending portion of the inner insulating spacer layer 82 that is not masked by the second patterning film 832 can be etched through, and an underlying portion of a respective first insulating layer 321 can be etched through. The anisotropic etch process can etch through an underlying portion of an outer blocking dielectric layer 44, and a horizontal surface segment of a respective underlying first-type electrically conductive layer 461 can be physically exposed. The second patterning film 832 can be subsequently removed, for example, by ashing. Alternatively, if the second patterning film 832 is omitted, the horizontal portion of the inner insulating spacer layer 82 is also removed during the etching process.

Referring to FIG. 14H, at least one inner metallic material layer (921, 922) can be deposited on the physically exposed surfaces of the first-type electrically conductive layers 461, the inner insulating spacer layer 82, and optionally the contact-level dielectric layer 80. The at least one inner metallic material layer (921, 922) may comprise an inner metallic barrier liner 921 and an inner metal layer 922.

The inner metallic barrier liner 921 may comprise a metallic barrier material such as TiN, TaN, WN, and/or MoN. The inner metallic barrier liner 921 may be deposited by physical vapor deposition or chemical vapor deposition. The thickness of the inner metallic barrier liner 921 may be in a range from 3 nm to 50 nm, although lesser and greater thicknesses may also be employed. The inner metallic barrier liner 921 can be formed directly on each physically exposed horizontal surface of the first-type electrically conductive layers 461, and on each inner cylindrical surface of the inner insulating spacer layer 82. The inner metallic barrier liner 921 may also be formed on physically exposed cylindrical surface segments of the outer blocking dielectric layers 44.

The inner metal layer 922 may comprise a metal, such a W, Mo, Ti, Ta, Co, Ru, Cu, etc. The inner metal layer 922 may be deposited by physical vapor deposition, chemical vapor deposition, electroplating, or a combination thereof. The thickness of the inner metal layer 922 is selected to fill remaining volumes of the voids in the layer contact via cavities 85.

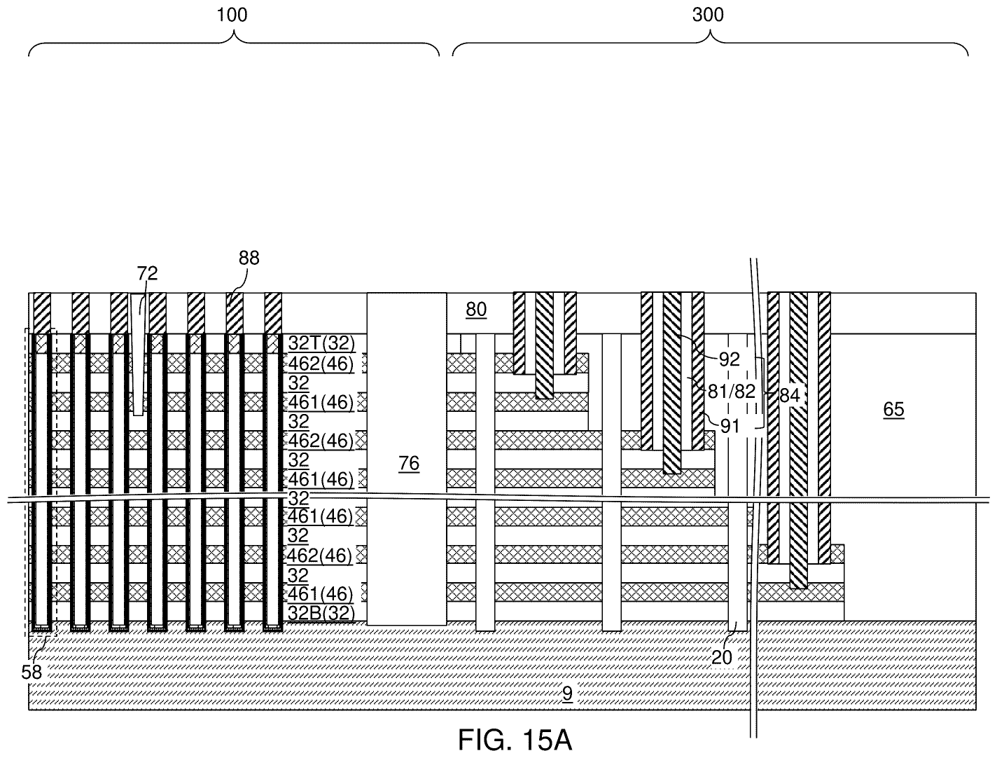

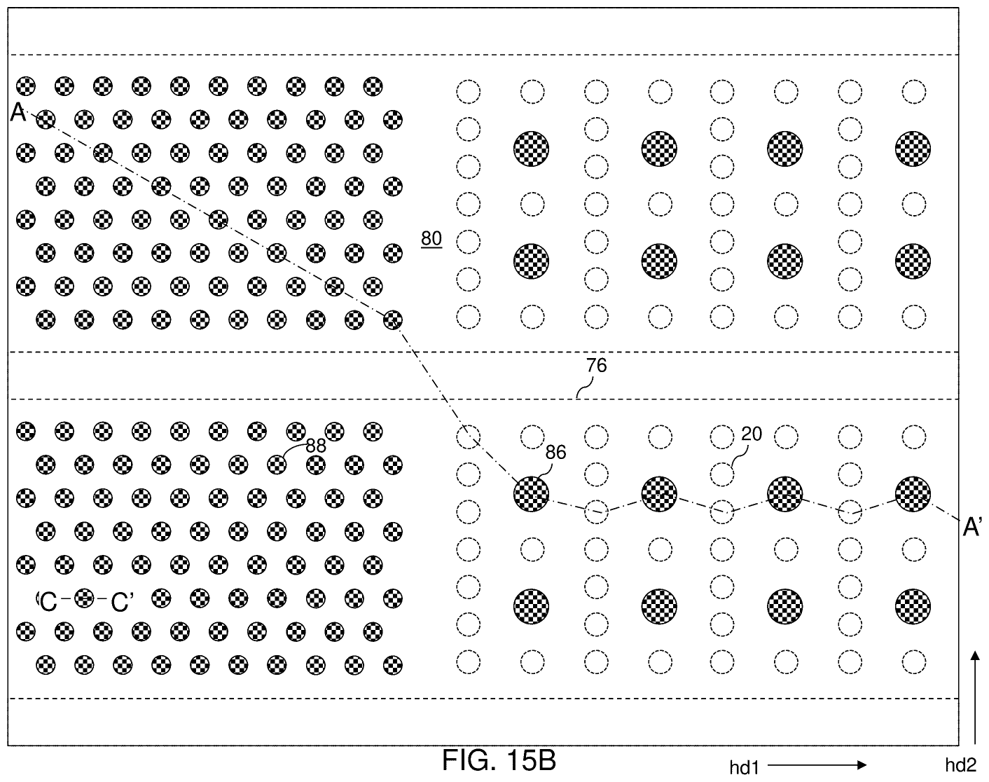

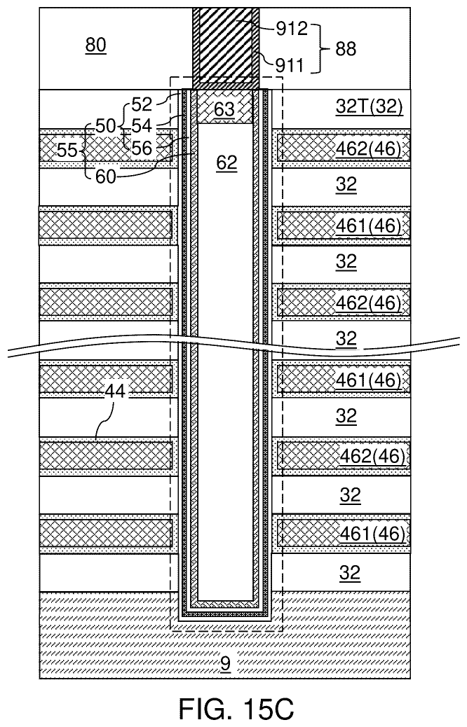

Referring to FIGS. 14I, 15A, 15B, and 15C, a chemical mechanical polishing process can be performed to remove material portions overlying the horizontal plane including the top surface of the contact-level dielectric layer 80. Specifically, portions of the at least one inner metallic material layer (921, 922), the at least one insulating spacer layer (81, 82) (if present), and the at least one outer metallic material layer (911, 912) (if present) that overlie the horizontal plane including the top surface of the contact-level dielectric layer 80 can be removed by the chemical mechanical polishing process. Each remaining portion of the at least one outer metallic material layer (911, 912) that fills a respective drain contact via cavity 87 constitutes a drain contact via structure 88, which contacts a top surface of a respective underlying drain region 63. Each continuous combination of remaining material portions that fills a respective layer contact via cavity 85 constitutes a coaxial contact via structure 84.

Each coaxial double contact via structure 84 includes a combination of an outer layer contact via structure 91, at least one insulating spacer layer (81, 82), and an inner layer contact via structure 92. The coaxial double contact via structure 84 vertically extends through the stepped dielectric material portion 65. Each coaxial double contact via structure 84 is formed on a respective first-type electrically conductive layer 461 and on a respective second-type electrically conductive layer 462 such that the inner layer contact via structure 92 contacts the respective first-type electrically conductive layer 461, the at least one insulating spacer layer (81, 82) laterally surrounds the inner layer contact via structure 92, and the outer layer contact via structure 91 laterally surrounds the at least one insulating spacer layer (81, 82) and contacts the respective second-type electrically conductive layer 462.

In summary, each coaxial double contact via structure 84 vertically extends through a dielectric material portion (such as the stepped dielectric material portion 65) and comprises: an inner layer contact via structure 92 contacting a first-type electrically conductive layer 461; at least one insulating spacer layer (81, 82) comprising a respective tubular insulating portion that laterally surrounds the inner layer contact via structure 92; and an outer layer contact via structure 91 comprising a tubular conductive portion that laterally surrounds the at least one insulating spacer layer (81, 82) and contacting a second-type electrically conductive layer 462. In one embodiment, a bottom surface of the inner layer contact via structure 92 contacts a horizontal surface segment of the first-type electrically conductive layer 461. In one embodiment, the horizontal surface segment of the first-type electrically conductive layer 461 is vertically recessed relative a top surface of the first-type electrically conductive layer 461. In one embodiment, a cylindrical surface segment of an outer sidewall of the outer layer contact via structure 91 contacts a cylindrical surface of the second-type electrically conductive layer 462.

In one embodiment, a first insulating layer 321 of the insulating layers 32 is located between the first-type electrically conductive layer 461 and the second-type electrically conductive layer 462; and a cylindrical surface segment of a sidewall of the inner layer contact via structure 92 contacts a cylindrical sidewall surface of the first insulating layer 321. In one embodiment shown in FIG. 14I, the at least one insulating spacer layer (81, 82) comprises a stepped annular bottom surface contacting the first insulating layer 321. In one embodiment, the stepped annular bottom surface comprises: an inner annular horizontal surface segment 180; an outer annular horizontal surface segment 181; and a vertical cylindrical surface segment 182 that connects an inner periphery of the outer annular horizontal surface segment 181 to an outer periphery of the inner annular horizontal surface segment 180.

In one embodiment, the at least one insulating spacer layer (81, 82) comprises: an inner insulating spacer layer 82; and an outer insulating spacer layer 81 laterally surrounding the inner insulating spacer layer 82. In one embodiment, the inner insulating spacer layer 82 comprises a laterally protruding, annular bottom portion 82A having a cylindrical outer sidewall surface 183 that contacts a lower cylindrical surface segment of an inner sidewall of the outer layer contact via structure 91. In one embodiment, a bottommost surface 184 of the outer insulating spacer layer 81 contacts an annular top surface of the annular bottom portion 82A of the inner insulating spacer layer 82.

In one embodiment, a first insulating layer 321 of the insulating layers 32 is located between the first-type electrically conductive layer 461 and the second-type electrically conductive layer 462; and the outer layer contact via structure 91 comprises an outer metallic barrier liner 911 and an outer metal layer 912, wherein the outer metallic barrier liner 911 contacts a cylindrical sidewall of the second-type electrically conductive layer 462 and an annular surface of the first insulating layer 321. In one embodiment, the outer metal layer 912 contacts a cylindrical surface of the at least one insulating spacer layer (81, 82).

In one embodiment, the inner layer contact via structure 92 comprises an inner metallic barrier liner 921 and an inner metal layer 922, wherein the inner metallic barrier liner 921 contacts a planar surface of the first-typer electrically conductive layer and a cylindrical surface of the at least one insulating spacer layer (81, 82). In one embodiment, a contact-level dielectric layer 80 overlies the alternating stack (32, 46) and the dielectric material portion (such as the stepped dielectric material portion 65). A topmost surface of the inner layer contact via structure 92, a topmost surface of the at least one insulating spacer layer (81, 82), and a topmost surface of the outer layer contact via structure 91 are located within a horizontal plane including a top surface of the contact-level dielectric layer 80.

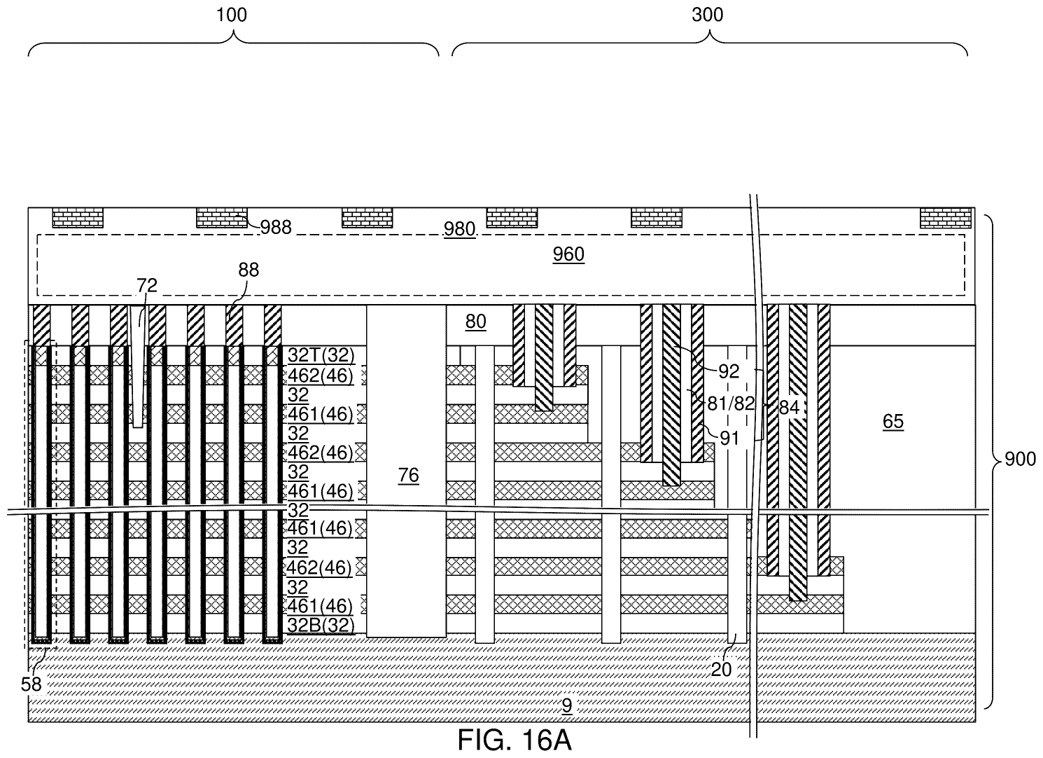

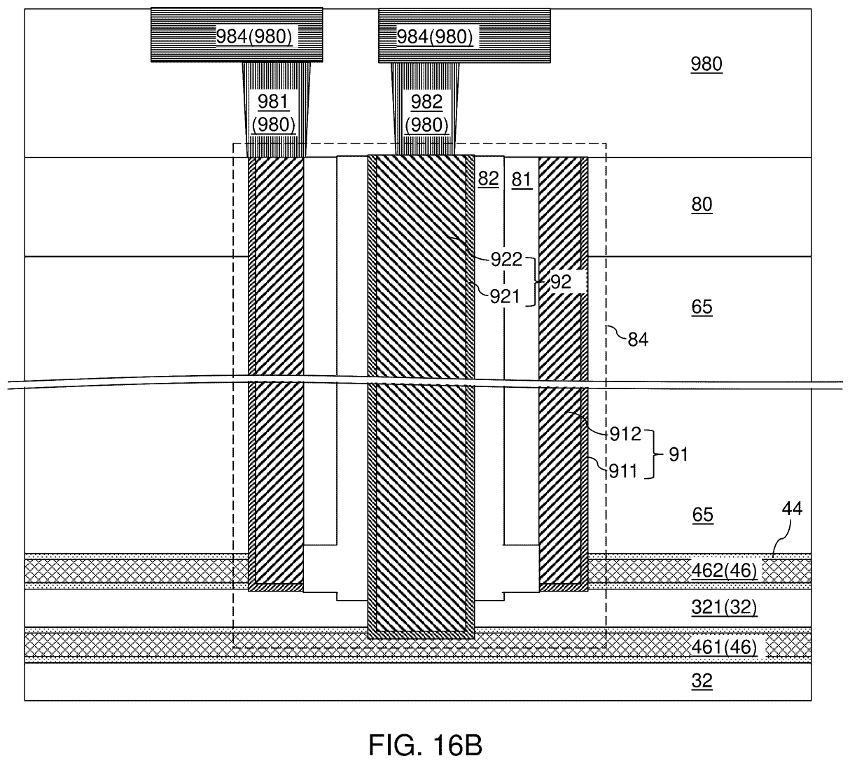

Referring to FIGS. 16A and 16B, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side metal interconnect structures 980. The memory-side dielectric material layers 960 comprise a bit-line-level dielectric material layer embedding bit lines, which are a subset of the memory-side metal interconnect structures 980. The memory-side metal interconnect structures 980 may comprise first connection via structures 981 contacting a top surface of a respective one of the outer layer contact via structure 91, and second contact via structures 982 contacting a top surface of a respective one of the inner layer contact via structures 92. The memory-side metal interconnect structures 980 may also comprise interconnection line structures 984 providing electrical connection to the electrically conductive layers 46.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer of the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

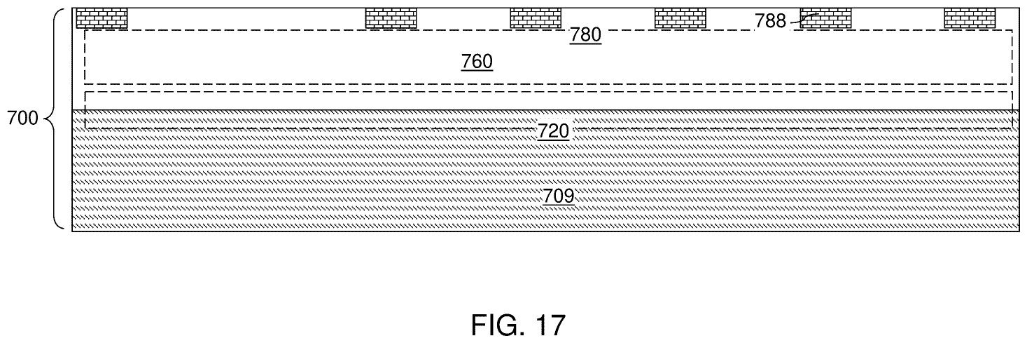

Referring to FIG. 17, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

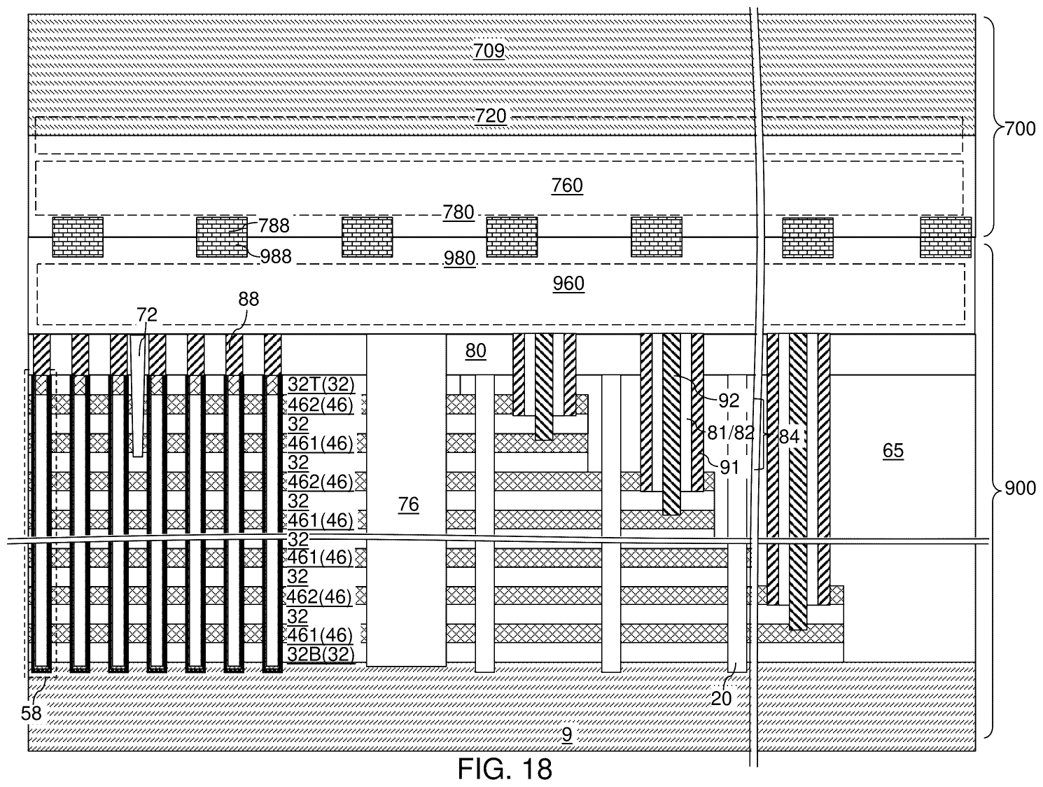

Referring to FIG. 18, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

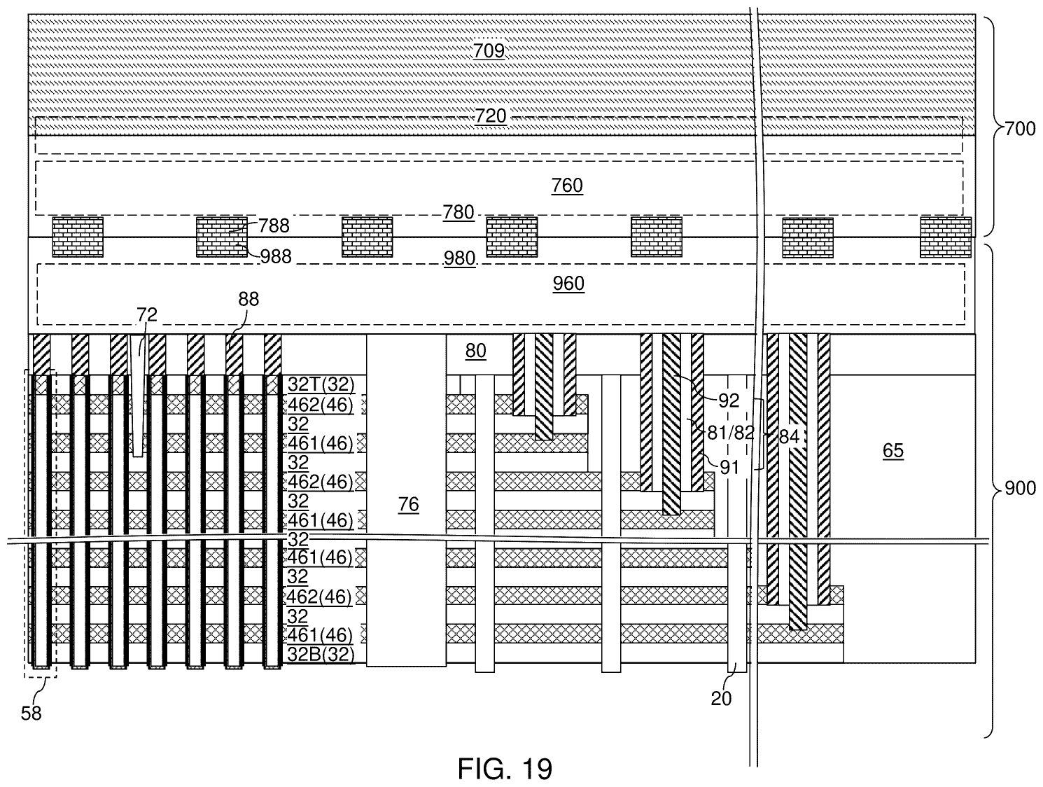

Referring to FIG. 19, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layer 32B may be employed as a polish stop or etch stop, respectively.

In one embodiment, at least a terminal step of at least one removal process that is employed to remove the carrier substrate 9 may comprise a selective wet etch process that etches the material of the carrier substrate 9 (such as a semiconductor material of the carrier substrate 9) selective to dielectric materials of the memory films 50. In an illustrative example, if the carrier substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the carrier substrate 9 can be removed by the selective wet etch process. Backside end surfaces of the support pillar structures 20 can be physically exposed upon removal of the carrier substrate 9.

A sequence of wet etch steps can be performed to sequentially remove portions of the memory film 50 that are exposed on the backside of the alternating stack (32, 46). For example, the blocking dielectric layer 52, the memory material layer 54, and the optional dielectric liner 56 (which may be, for example, a tunneling dielectric layer) of each memory film 50 can be removed from a region that is more distal from the bonding interface between the memory die 900 and the logic die 700 than a physically exposed planar surface of the bottommost insulating layer 32B is from the bonding interface.

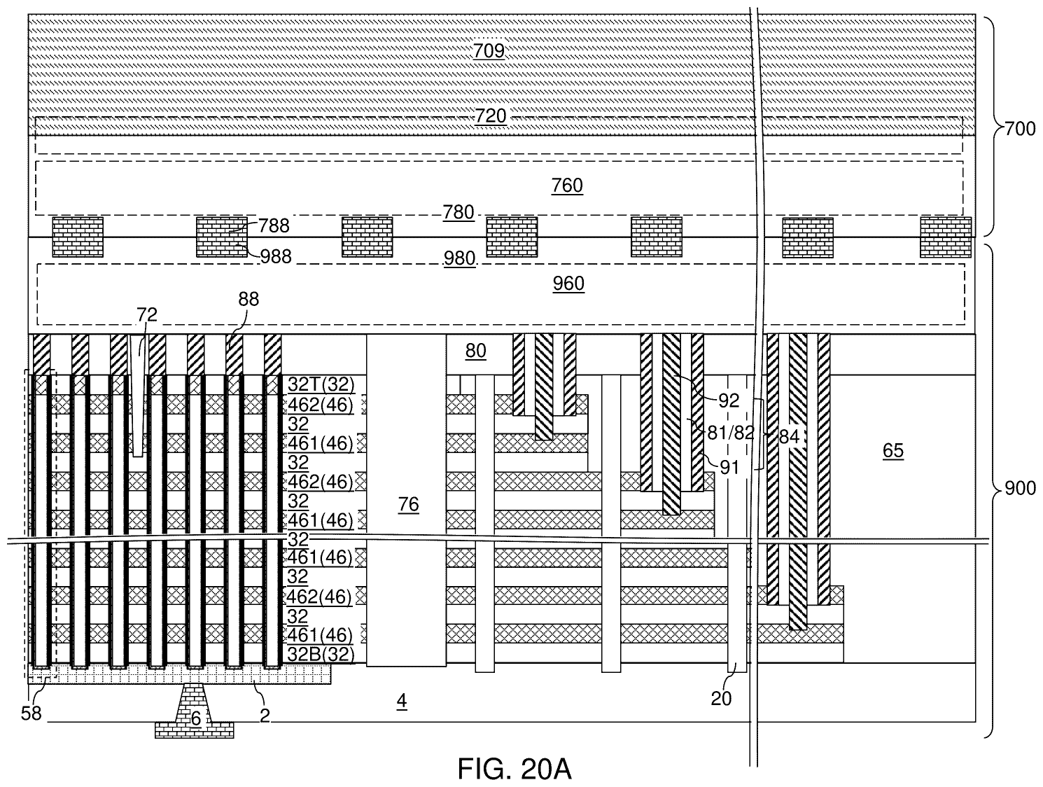

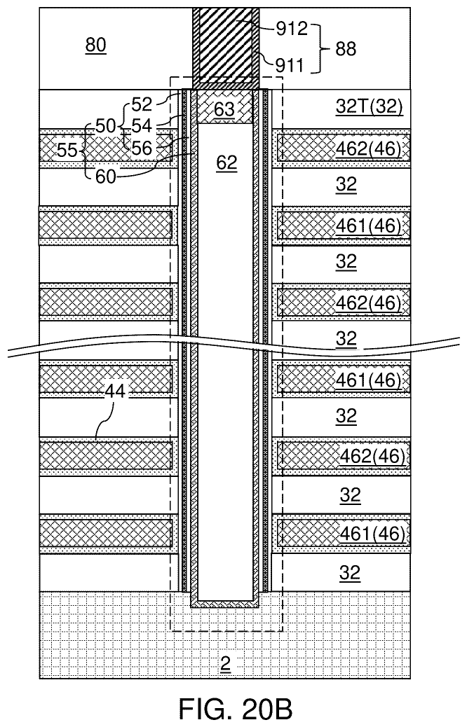

Referring to FIGS. 20A and 20B, at least one source structure 2 can be formed on the physically exposed bottom surfaces of the vertical semiconductor channels 60. The at least one source structure 2 may comprise a heavily doped semiconductor material having a doping of the second conductivity type, and/or may comprise at least one metallic material (such as a combination of a metallic barrier liner material and a backside metal). At least one backside dielectric layer 4 may be formed on the backside of the first exemplary structure, and at least one backside contact structure 6 can be formed through the at least one backside dielectric layer 4 on a backside surface of a respective electrical node (such as a source structure 2).

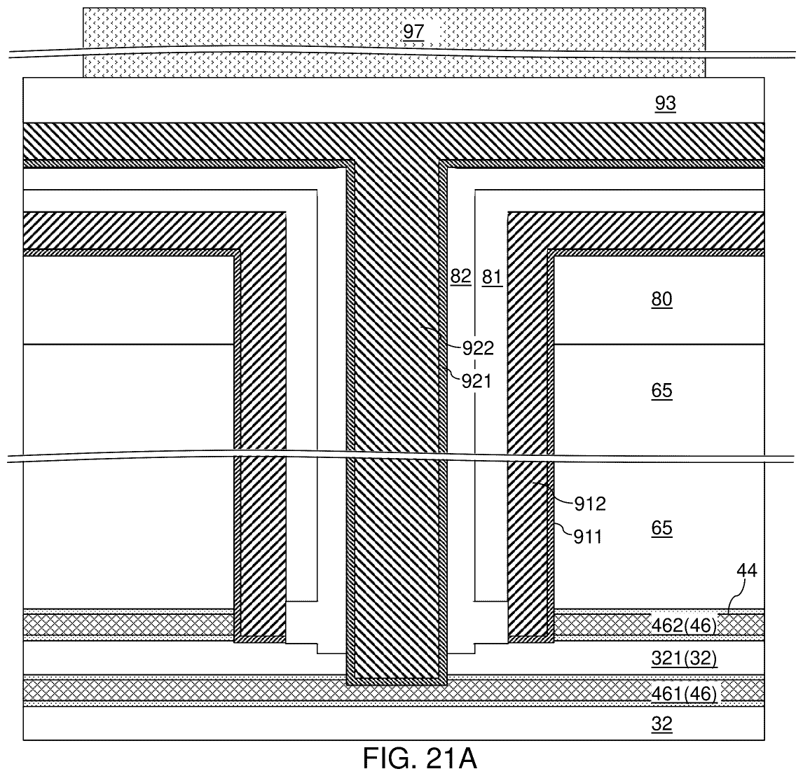

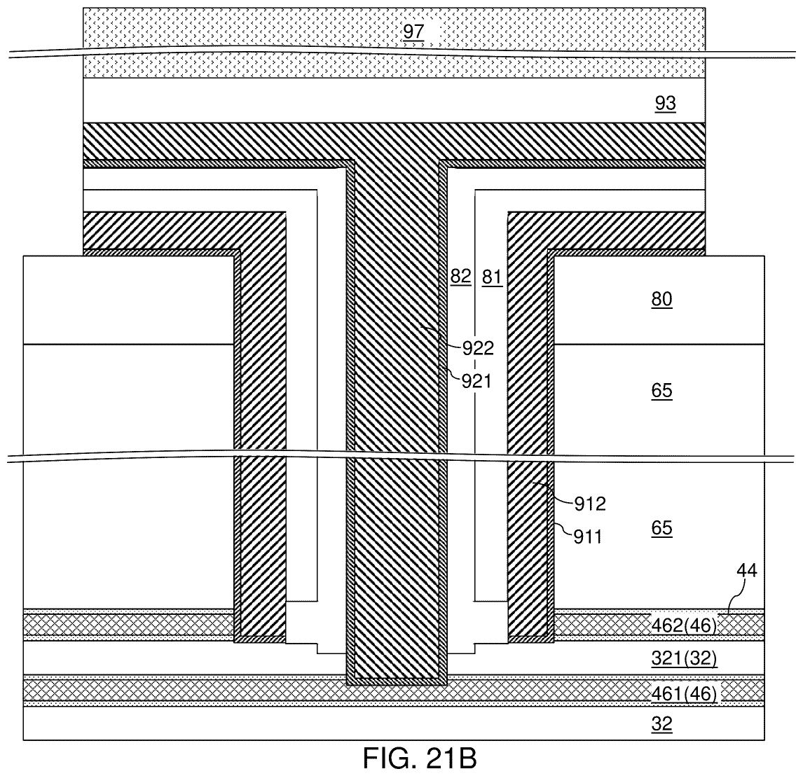

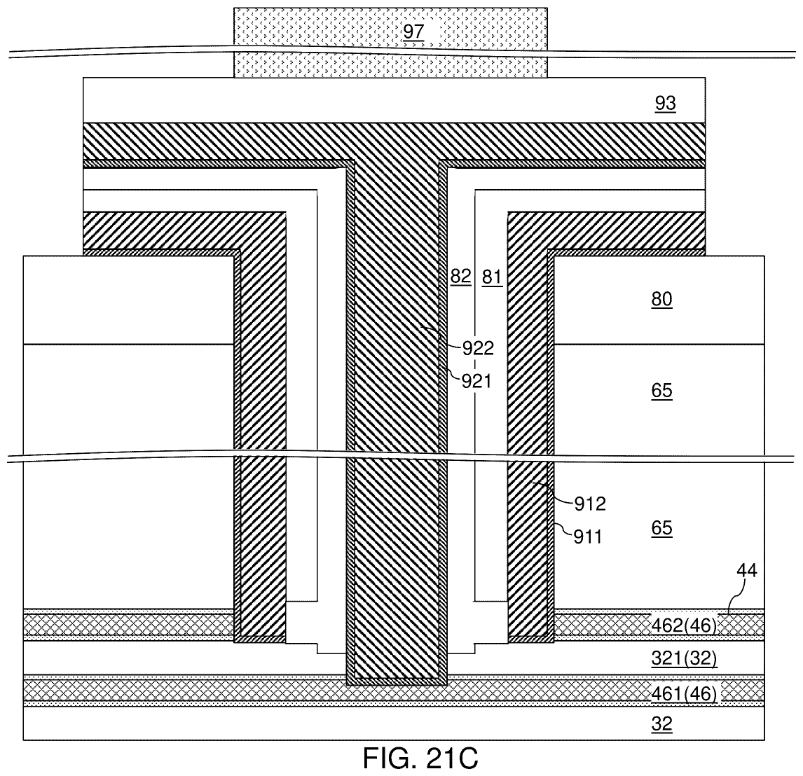

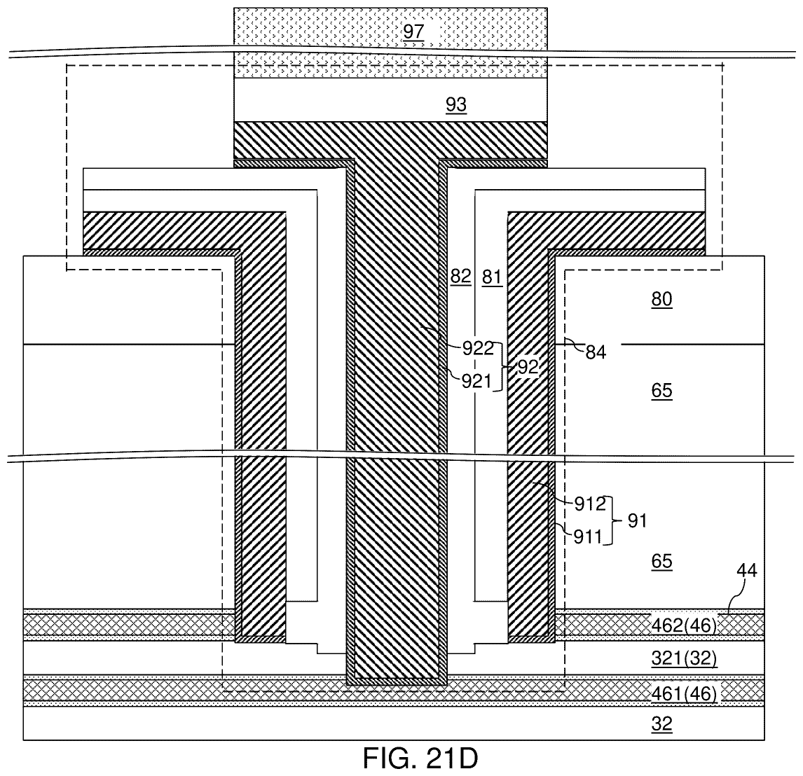

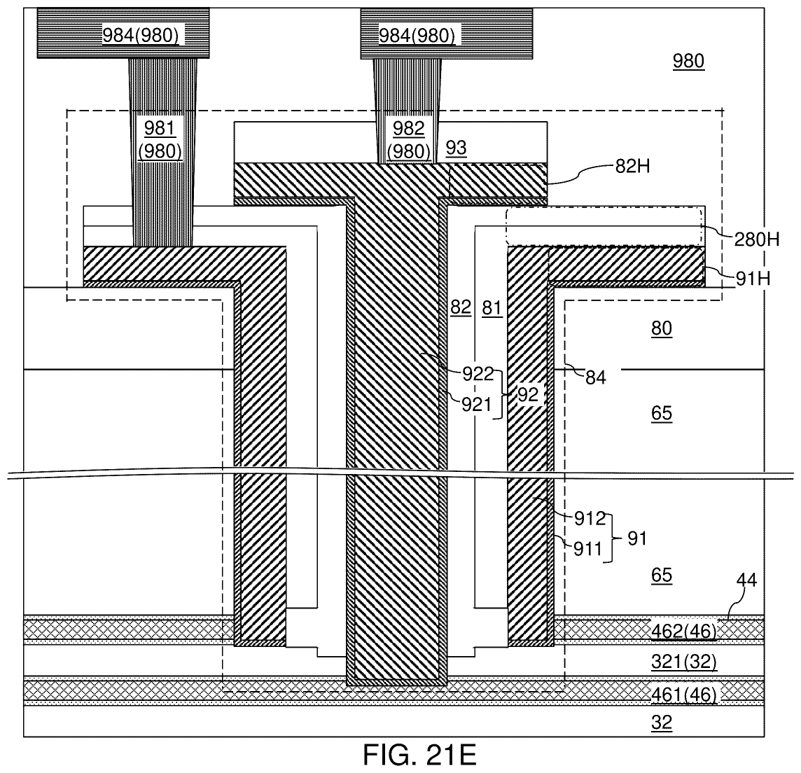

FIGS. 21A-21E are sequential vertical cross-sectional views of a region around a layer contact via cavity during formation of a coaxial double contact via structure 84 and overlying upper-level metal interconnect structures in a second embodiment of the first exemplary structure. The second embodiment of the first exemplary structure can be derived from the first embodiment of the first exemplary structure described with reference to FIGS. 1-20 by modifying a set of processing steps.

Referring to FIG. 21A, the second embodiment of the first exemplary structure can be derived from the first embodiment of the first exemplary structure illustrated in FIG. 14H by optionally forming a capping dielectric layer 93 over the horizontally-extending portion of the at least one inner metallic material layer (921, 922). The capping dielectric layer 93 may comprise a same material or a similar material as the at least one insulating spacer layer (81, 82), and may have about the same thickness as the total thickness of the at least one outer metallic material layer (911, 912).

A trimmable photoresist layer 97 can be formed over the capping dielectric layer 93 (or over the at least one inner metallic material layer (921, 922)), and can be lithographically patterned into discrete trimmable photoresist material portions. Each discrete photoresist material portion of the trimmable photoresist layer 97 can cover the area of a respective underlying vertically-extending tubular portion of the at least one outer metallic material layer (911, 912). In one embodiment, the entire sidewall of each discrete trimmable photoresist material portion of the trimmable photoresist layer 97 may be laterally offset outward from a cylindrical vertical plane including an outer cylindrical sidewall of a tubular portion of the at least one outer metallic material layer (911, 912).

Referring to FIG. 21B, an anisotropic etch process can be performed to etch unmasked portions of the optional capping dielectric layer 93, the at least one inner metallic material layer (921, 922), the at least one insulating spacer layer (81, 82) and the at least one outer metallic material layer (911, 912). The trimmable photoresist layer 97 can be employed as the etch mask layer for the anisotropic etch process. A sidewall of each patterned portion of the capping dielectric layer 93 can be vertically coincident with a sidewall of respective remaining horizontally-extending portions of the at least one inner metallic material layer (921, 922), the at least one insulating spacer layer (81, 82), and the at least one outer metallic material layer (911, 912).

Referring to FIG. 21C, the trimmable photoresist layer 97 can be isotropically trimmed by performing a trimming process, which may comprise a controlled ashing process that ashes surface portions of the discrete patterned portions of the trimmable photoresist layer 97. Thus, the area covered by the trimmable photoresist layer 97 is reduced.

Referring to FIG. 21D, an anisotropic etch process can be performed to etch portions of the capping dielectric layer 93 and the at least one inner metallic material layer (921, 922) that are not masked by the trimmable photoresist layer 97 as trimmed at the processing steps of FIG. 21C. The anisotropic etch process may comprise a first anisotropic etch step that etches the dielectric material of the capping dielectric layer 93 selective to the at least one inner metallic material layer (921, 922). The anisotropic etch process may further comprise a second anisotropic etch step that etches the metallic materials of the at least one inner metallic material layer (921, 922) selective to the dielectric material of the at least one insulating spacer layer (81, 82) and the contact-level dielectric layer 80. The trimmable photoresist layer 97 can be subsequently removed, for example, by ashing.

Referring to FIG. 21E, the processing steps described with reference to FIGS. 16A-20B can be performed. The memory-side metal interconnect structures 980 may comprise first connection via structures 981 contacting a top horizontal surface of a respective one of the outer layer contact via structure 91, and second contact via structures 982 contacting a top horizontal surface of a respective one of the inner layer contact via structures 92. The memory-side metal interconnect structures 980 may also comprise interconnection line structures 984 providing electrical connection to the electrically conductive layers 46.

In the second first exemplary structure, the contact-level dielectric layer 80 overlies the alternating stack (32, 46) and a dielectric material portion (such as the stepped dielectric material portion 65). Each insulating spacer layer (81, 82) comprises a laterally-extending portion (i.e., horizontal portion 280H) that overlies the contact-level dielectric layer 80. Each outer layer contact via structure 91 may comprise a respective annular flange portion (i.e., horizontal portion 91H underlying the respective laterally-extending annular portion (i.e., an annular flange portion) 280H of at least one insulating spacer layer (81, 82).

Each sidewall of an annular flange portion 280H of the at least one insulating spacer layer (81, 82) that overlies the contact-level dielectric layer 80 may be vertically coincident with a sidewall of an annular flange portion 91H of an underlying outer layer contact via structure 91. Each inner layer contact via structure 92 may comprise a respective annular flange portion 92H overlying a respective laterally-extending annular flange portion 280H of at least one insulating spacer layer (81, 82).

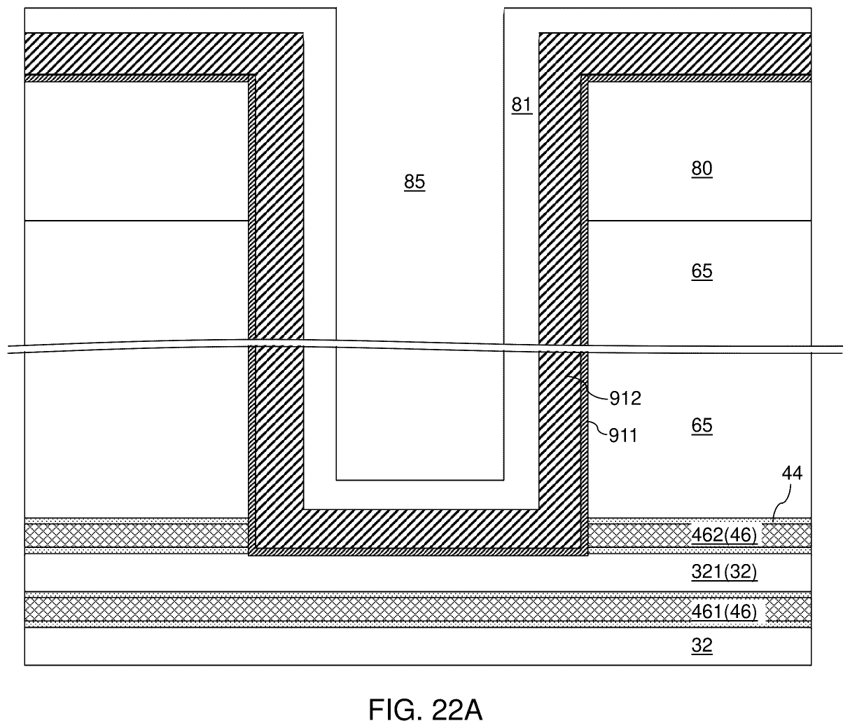

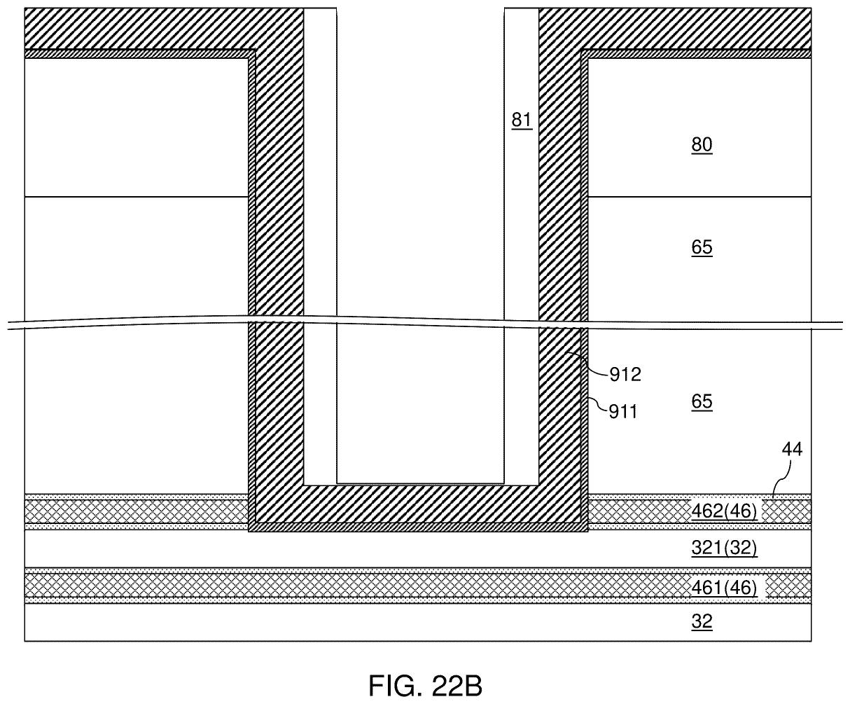

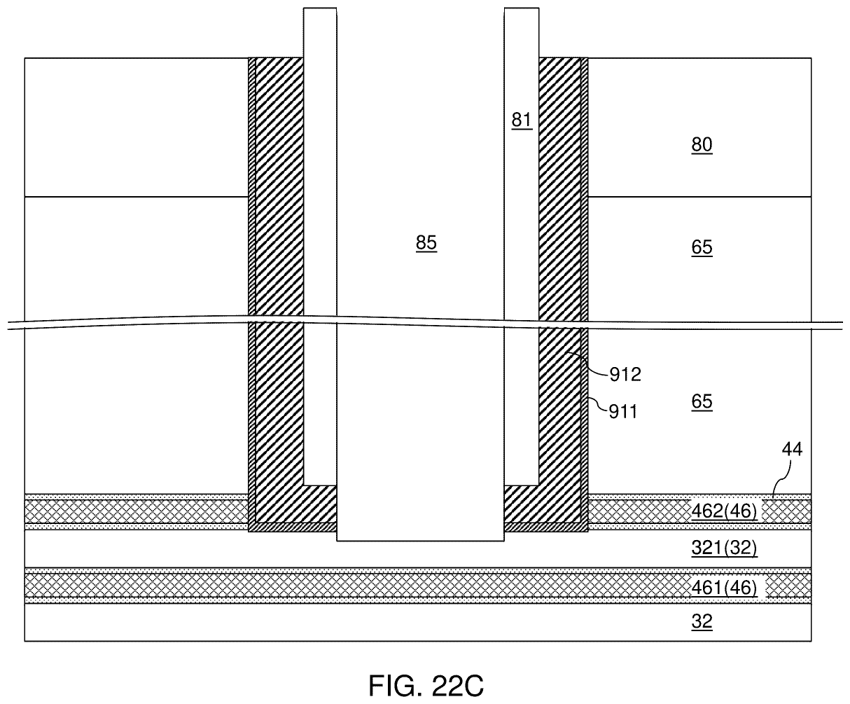

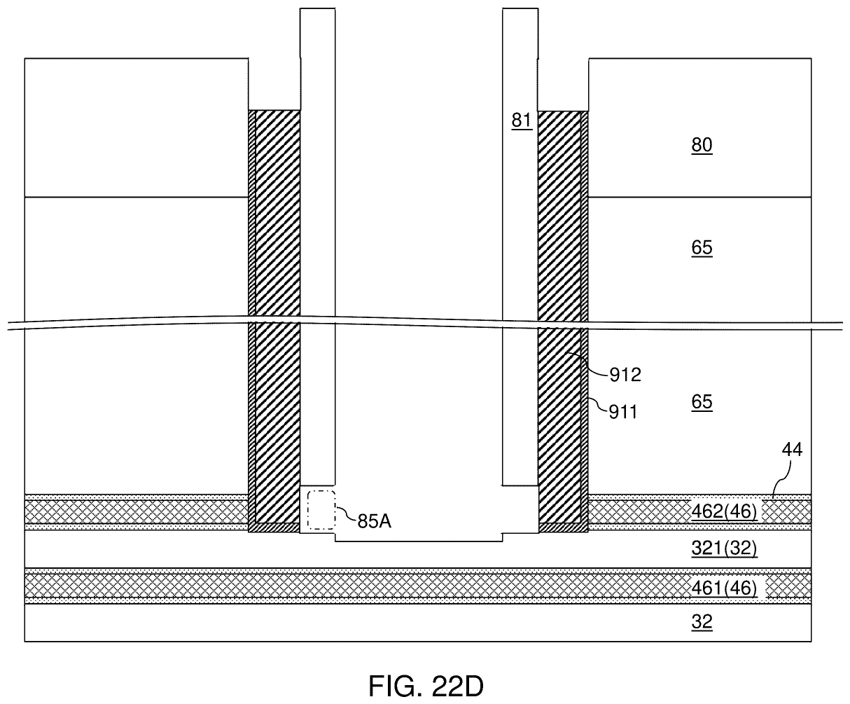

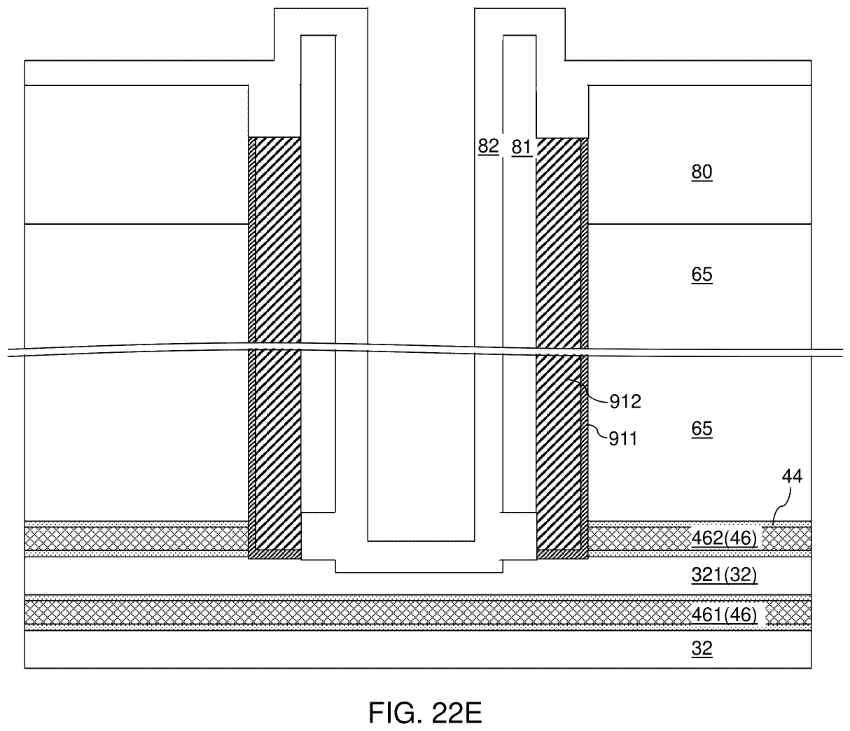

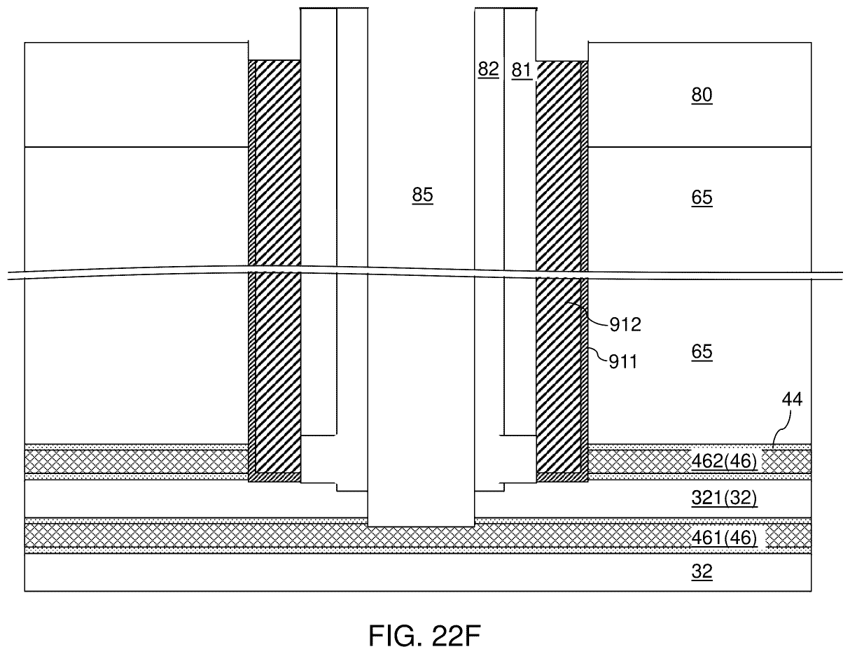

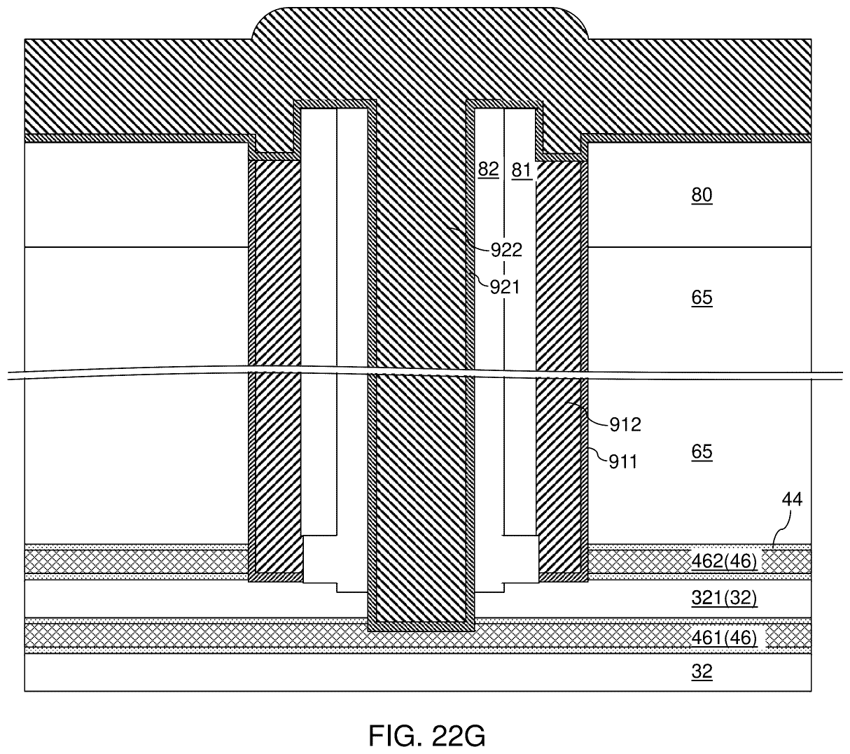

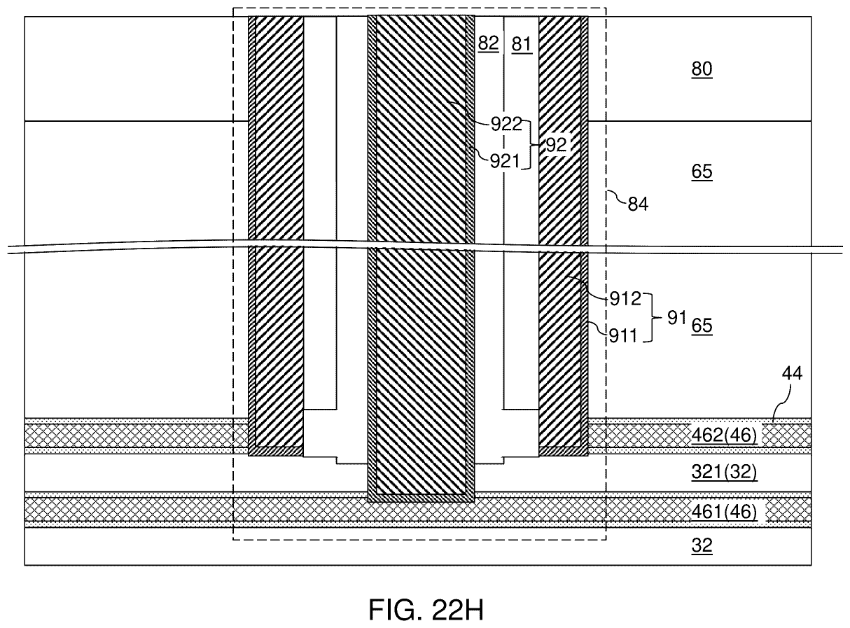

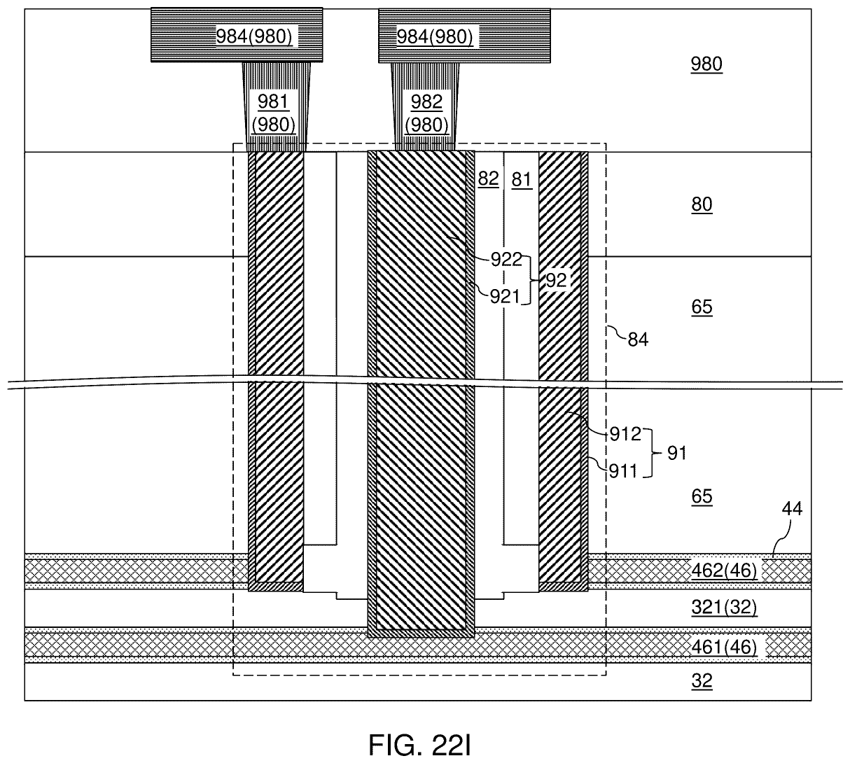

FIGS. 22A-22I are sequential vertical cross-sectional views of a region around a layer contact via cavity during formation of a coaxial double contact via structure 84 and overlying upper-level metal interconnect structures in a third embodiment of the first exemplary structure. In the third embodiment, the patterning films (831, 832) are omitted from the method of the first embodiment.

Referring to FIG. 22A, a third embodiment of the first exemplary structure is illustrated at the processing steps described with reference to FIG. 14C. The third embodiment of the first exemplary structure at this processing step may be the same as the first embodiment of the first exemplary structure at the processing step of FIG. 14C with an optional modification in the thickness of the contact-level dielectric layer 80. In one embodiment, the thickness of the contact-level dielectric layer 80 for the third embodiment of the first exemplary structure may be greater than the thickness of the contact-level dielectric layer 80 for the first embodiment of the first exemplary structure.

Referring to FIG. 22B, a first anisotropic etch process can be performed to etch horizontally-extending portions of the outer insulating spacer layer 81. The chemistry of the first anisotropic etch process may be selective to the metallic materials of the at least one outer metallic material layer (911, 912). Each remaining vertically-extending portion of the outer insulating spacer layer 81 may have a respective tubular configuration, and may be formed within a respective one of the layer contact via cavities 85.

Referring to FIG. 22C, a second anisotropic etch process can be performed to etch horizontally-extending portions of the at least one outer metallic material layer (911, 912). Each remaining portion of the at least one outer metallic material layer (911, 912) may have a tubular configuration, and may be formed within the volume of a respective one of the layer contact via cavities 85. In one embodiment, each remaining portion of the at least one outer metallic material layer (911, 912) may have a respective L-shaped vertical cross-sectional profile comprising a tubular portion and an inner rim portion that is adjoined to a bottom end of the tubular portion and laterally extending inward from the tubular portion.

Referring to FIG. 22D, at least one selective isotropic etch process can be performed to isotropically etch the metallic materials of the at least one outer metallic material layer (911, 912) selective to the insulating materials of the outer insulating spacer layers 81 and the insulating layers 32. For example, if the outer metallic barrier liner 911 comprises titanium nitride and if the outer metal layer 912 comprise tungsten, a first wet etch process employing a mixture of hydrogen peroxide and ammonium hydroxide may be employed to etch physically exposed portions of the outer metal layer 912, and a second wet etch process employing a mixture of hydrogen peroxide and sulfuric acid can be performed to etch physically exposed portions of the outer metallic barrier liner 911. The duration of each selective isotropic etch process can be selected such that the recessed surfaces of the at least one outer metallic material layer (911, 912) are approximately vertically coincident with an outer cylindrical sidewall of an overlying vertically-extending tubular portion of the outer insulating spacer layer 81.

Thus, physically exposed surfaces of the at least one outer metallic material layer (911, 912) can be laterally recessed selective to the insulating layers 32 and the outer insulating spacer layer 81 by performing a selective isotropic etch process. An annular cavity 85A is formed in each volume from which an annular portion of the at least one outer metallic material layer (911, 912) is removed. In summary, the annular cavity 85A can be formed underneath each vertically-extending tubular portion of the outer insulating spacer layer 81 in a volume from which materials of the at least one outer metallic material layer (911, 912) are etched. A cylindrical surface segment of the outer metal layer 912 and a cylindrical surface segment of the outer metallic barrier liner 911 can be physically exposed around each annular cavity 85A.

Referring to FIG. 22E, an additional insulating spacer layer, which is herein referred to as an inner insulating spacer layer 82 can be formed by conformal deposition of an insulating material, which may comprise silicon oxide, silicon nitride, or another insulating material. The inner insulating spacer layer 82 can be deposited by a conformal deposition process such as a chemical vapor deposition process. The thickness of the inner insulating spacer layer 82 can be greater than one half of the thickness of the at least one outer metallic material layer (911, 912). The entire volume of each annular cavity 85A can be filled within a respective portion of the inner insulating spacer layer 82. In summary, at least one insulating spacer layer (81, 82) is formed inside each vertically-extending tubular portion of the at least one outer metallic material layer (911, 912). The at least one insulating spacer layer (81, 82) comprises an inner insulating spacer layer 82 that is formed on an inner cylindrical sidewall of the outer insulating spacer layer 81 and fills the respective annular cavity 85A.

Referring to FIG. 22F, an anisotropic etch process can be performed to etch through horizontally-extending portions of the inner insulating spacer layer 82 and underlying portions of the first insulating layers 321 underneath the void in each layer contact via cavity 85 in a bottom portion of each layer contact via cavity 85. The horizontally-extending portion of the inner insulating spacer layer 82 overlying the contact-level dielectric layer 80 and a top portion of the contact-level dielectric layer 80 can be collaterally etched during the anisotropic etch process. The anisotropic etch process can etch through an underlying portion of an outer blocking dielectric layer 44, and a horizontal surface segment of a respective underlying first-type electrically conductive layer 461 can be physically exposed.

Referring to FIG. 22G, at least one inner metallic material layer (921, 922) can be deposited on the physically exposed surfaces of the first-type electrically conductive layers 461, the inner insulating spacer layer 82, and the contact-level dielectric layer 80. The at least one inner metallic material layer (921, 922) may comprise an inner metallic barrier liner 921 and an inner metal layer 922. The inner metallic barrier liner 921 may comprise a metallic barrier material such as TiN, TaN, WN, and/or MoN. The inner metallic barrier liner 921 may be deposited by physical vapor deposition or chemical vapor deposition. The thickness of the inner metallic barrier liner 921 may be in a range from 3 nm to 50 nm, although lesser and greater thicknesses may also be employed. The inner metallic barrier liner 921 can be formed directly on each physically exposed horizontal surface of the first-type electrically conductive layers 461, and on each inner cylindrical surface of the inner insulating spacer layer 82. The inner metallic barrier liner 921 may be formed on physically exposed cylindrical surface segments of the outer blocking dielectric layers 44.

The inner metal layer 922 may comprise a metal such a W, Mo, Ti, Ta, Co, Ru, Cu, etc. The inner metal layer 922 may be deposited by physical vapor deposition, chemical vapor deposition, electroplating, or a combination thereof. The thickness of the inner metal layer 922 is selected to fill remaining volumes of the voids in the layer contact via cavities 85.

Referring to FIG. 22H, a chemical mechanical polishing (CMP) process can be performed to remove material portions overlying the horizontal plane including annular top surfaces of the at least one outer metallic material layer (911, 912). Specifically, portions of the at least one inner metallic material layer (921, 922), the at least one insulating spacer layer (81, 82), that overlie the horizontal plane including the annular top surfaces of the at least one outer metallic material layer (911, 912) can be removed by the chemical mechanical polishing process. Optionally, the annular top surfaces the at least one outer metallic material layer (911, 912) may also be recessed during the CMP process. Each remaining portion of the at least one outer metallic material layer (911, 912) that fills a respective drain contact via cavity 87 constitutes a drain contact via structure 88, which contacts a top surface of a respective underlying drain region 63. Each continuous combination of remaining material portions that fills a respective layer contact via cavity 85 constitutes a coaxial contact via structure 84.

Each coaxial double contact via structure 84 includes a combination of an outer layer contact via structure 91, at least one insulating spacer layer (81, 82), and an inner layer contact via structure 92, and vertically extends through the stepped dielectric material portion 65. Each coaxial double contact via structure 84 is formed on a respective first-type electrically conductive layer 461 and on a respective second-type electrically conductive layer 462 such that the inner layer contact via structure 92 contacts the respective first-type electrically conductive layer 461, the at least one insulating spacer layer (81, 82) laterally surrounds the inner layer contact via structure 92, and the outer layer contact via structure 91 laterally surrounds the at least one insulating spacer layer (81, 82) and contacts the respective second-type electrically conductive layer 462.

Referring to FIG. 22I, the processing steps described with reference to FIGS. 16A-20B can be performed. The memory-side metal interconnect structures 980 may comprise first connection via structures 981 contacting a top surface of a respective one of the outer layer contact via structure 91 having a tubular configuration, and second contact via structures 982 contacting a top surface of a respective one of the inner layer contact via structures 92. The memory-side metal interconnect structures 980 may also comprise interconnection line structures 984 providing electrical connection to the electrically conductive layers 46.

Referring collectively to all drawings and according to various aspects of the present disclosure a device structure comprises: an alternating stack (32, 46) of insulating layers 32 and electrically conductive layers 46, wherein the electrically conductive layers 46 comprise a vertically neighboring pair of a first-type electrically conductive layer 461 and a second-type electrically conductive layer 462 that overlies the first-type electrically conductive layer 461; a dielectric material portion (such as the stepped dielectric material portion 65) overlying the alternating stack (32, 46); memory openings 49 vertically extending through the alternating stack (32, 46); memory opening fill structures 58 located in the memory openings 49, wherein each of the memory opening fill structures 58 comprises a respective vertical stack of memory elements (e.g., portions of the memory film 50) and a vertical semiconductor channel 60; and a coaxial double contact via structure 84 vertically extending through the dielectric material portion (such as the stepped dielectric material portion 65) and comprising: an inner layer contact via structure 92 contacting the first-type electrically conductive layer 461; at least one insulating spacer layer (81, 82) comprising a respective tubular insulating portion that laterally surrounds the inner layer contact via structure 92; and an outer layer contact via structure 91 comprising a tubular conductive portion that laterally surrounds the at least one insulating spacer layer (81, 82) and contacting the second-type electrically conductive layer 462.

In one embodiment, a bottom surface of the inner layer contact via structure 92 contacts a horizontal surface segment of the first-type electrically conductive layer 461. In one embodiment, the horizontal surface segment of the first-type electrically conductive layer 461 is vertically recessed relative a top surface of the first-type electrically conductive layer 461. In one embodiment, a cylindrical surface segment of an outer sidewall of the outer layer contact via structure 91 contacts a cylindrical surface of the second-type electrically conductive layer 462.

In one embodiment, a first insulating layer 321 of the insulating layers 32 is located between the first-type electrically conductive layer 461 and the second-type electrically conductive layer 462; and a cylindrical surface segment of a sidewall of the inner layer contact via structure 92 contacts a cylindrical sidewall surface of the first insulating layer 321.

In one embodiment, the at least one insulating spacer layer (81, 82) comprises a stepped annular bottom surface contacting the first insulating layer 321. In one embodiment, the stepped annular bottom surface comprises: an inner annular horizontal surface segment 180; an outer annular horizontal surface segment 181; and a cylindrical vertical surface segment 182 that connects an inner periphery of the outer annular horizontal surface segment 181 to an outer periphery of the inner annular horizontal surface segment 180.

In one embodiment, the at least one insulating spacer layer (81, 82) comprises: an inner insulating spacer layer 82; and an outer insulating spacer layer 81 laterally surrounding the inner insulating spacer layer 82. In one embodiment, the inner insulating spacer layer 82 comprises a laterally protruding annular bottom portion 82A having a cylindrical sidewall surface 183 that contacts a lower cylindrical surface segment of an inner sidewall of the outer layer contact via structure 91. In one embodiment, a bottommost surface 184 of the outer insulating spacer layer 81 contacts an annular top surface of the laterally protruding annular bottom portion 82A of the inner insulating spacer layer 82.

In one embodiment, a first insulating layer 321 of the insulating layers 32 is located between the first-type electrically conductive layer 461 and the second-type electrically conductive layer 462; and the outer layer contact via structure 91 comprises an outer metallic barrier liner 911 and an outer metal layer 912, wherein the outer metallic barrier liner 911 contacts a cylindrical sidewall of the second-type electrically conductive layer 462 and an annular surface of the first insulating layer 321. In one embodiment, the outer metal layer 912 contacts a cylindrical surface of the at least one insulating spacer layer (81, 82).

In one embodiment, the inner layer contact via structure 92 comprises an inner metallic barrier liner 921 and an inner metal layer 922, wherein the inner metallic barrier liner 921 contacts a planar surface of the first-typer electrically conductive layer and a cylindrical surface of the at least one insulating spacer layer (81, 82). In one embodiment, a contact-level dielectric layer 80 overlies the alternating stack (32, 46) and the dielectric material portion (such as the stepped dielectric material portion 65).

In the first and third embodiments, a topmost surface of the inner layer contact via structure 92, a topmost surface of the at least one insulating spacer layer (81, 82), and a topmost surface of the outer layer contact via structure 91 are located within a horizontal plane including a top surface of the contact-level dielectric layer 80.

In the second embodiment, the at least one insulating spacer layer (81, 82) comprises a laterally-extending portion 280 that overlies the contact-level dielectric layer 80.

The coaxial double contact via structure 84 is more laterally compact compared to separate contact via structures which are located side by side. The coaxial double contact via structure 84 provides a reduced contact area, which can lead to a reduced memory device area, which increases the number of memory strings which may be formed over the same substrate.

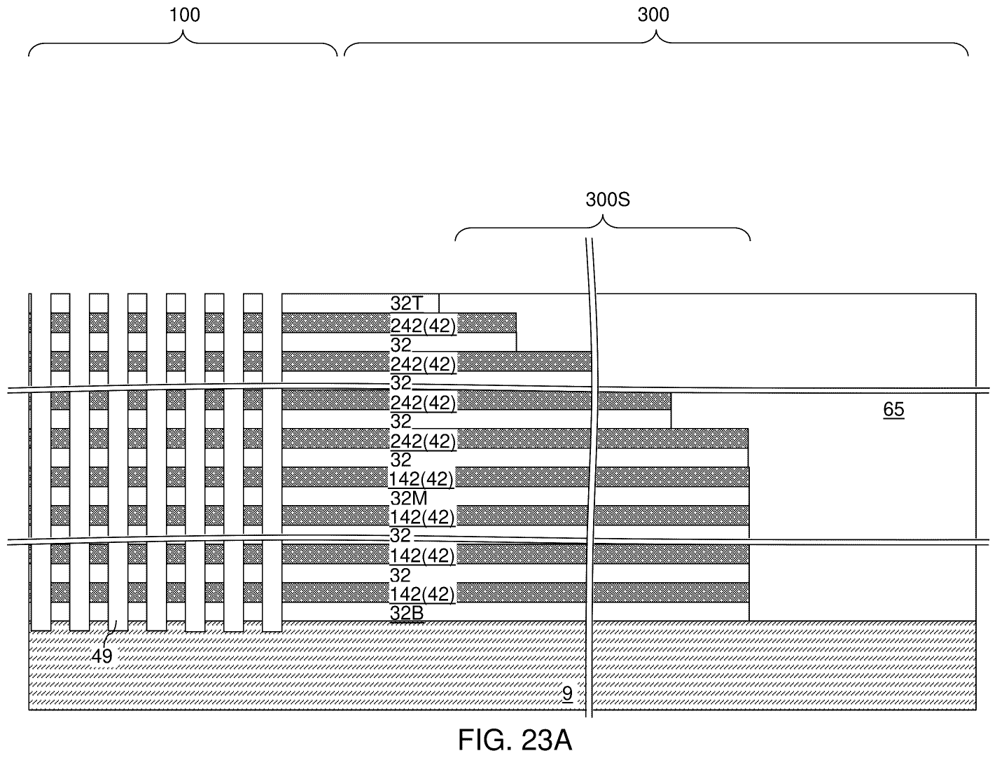

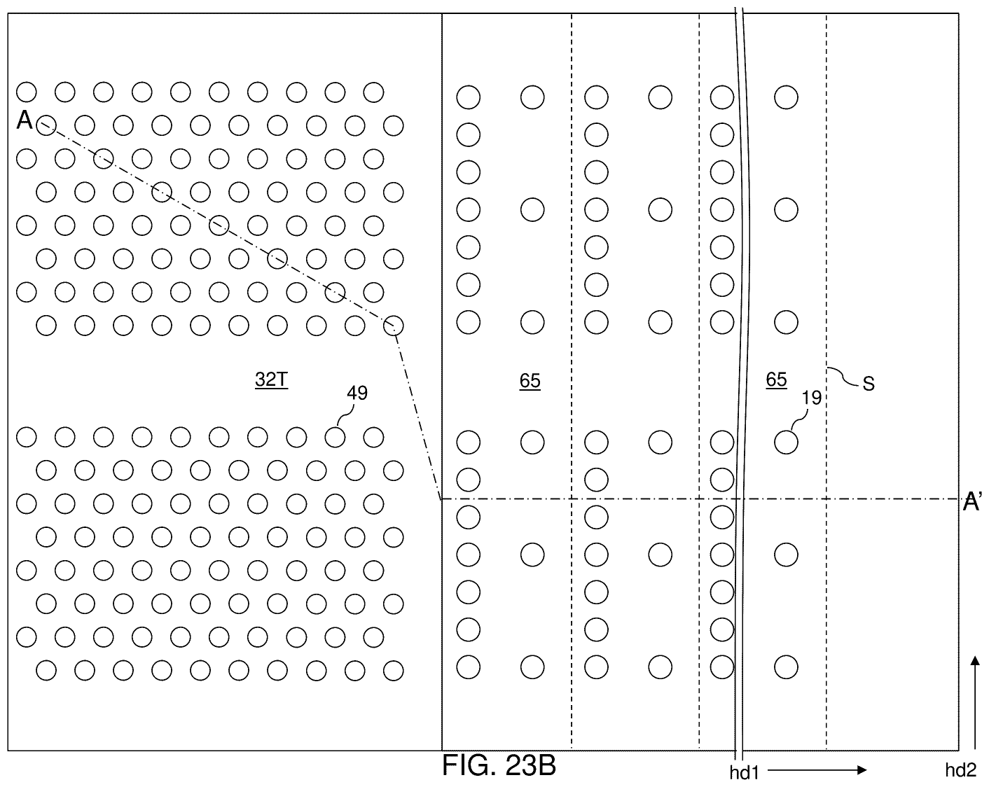

Referring to FIGS. 23A and 23B, a second exemplary structure according to a second embodiment of the present disclosure is illustrated. The second exemplary structure can be derived from the first exemplary structure illustrated in FIG. 1 by modifying the pattern for forming stepped surfaces in the staircase region within the contact region 300. In the second exemplary structure, the sacrificial material layers 42 can be grouped into two sets of mutually exclusive sacrificial material layers 42. The two sets of mutually exclusive sacrificial material layers 42 comprise a set of first sacrificial material layers 142 and a set of second sacrificial material layers 242. The set of second sacrificial material layers 242 overlies the set of first sacrificial material layers 142. In one embodiment, the number of the second sacrificial material layers 242 may be the same as the number of first sacrificial material layers 142.

The sacrificial material layers 42 can be patterned to form stepped surfaces in a staircase region 300S within the contact region 300. In one embodiment, the lateral extent of each sacrificial material layer 42 is not less than the lateral extent of any underlying sacrificial material layer 42 in the staircase region. A plurality of masking steps and a plurality of anisotropic etch processes can be employed to form stepped surfaces in the staircase region within the contact region 300. In some embodiments, at least one trimmable masking layer may be employed to form the stepped surfaces.

According to an aspect of the present disclosure, each of the first sacrificial material layers 142 can be patterned to have a same area in a plan view such as a top-down view. The area of each first sacrificial material layer 142 is herein referred to as a first area. Each of the first sacrificial material layers 142 and each of the insulating layers 32 located below the topmost first sacrificial material layer 142 can have a first lateral extent along a first horizontal direction hd1, which can be the direction along which lateral isolation trenches to be subsequently formed laterally extend.

Each of the second sacrificial material layers 242 can be patterned so that the lateral extents of the second sacrificial material layers 242 in the staircase region decrease with a vertical distance from the horizontal plane including the bottom surface of the bottommost insulating layer 32B. Thus, the second sacrificial material layers 242 have areas in the plan view that decrease with the vertical distance from the horizontal plane including the bottom surface of the bottommost insulating layer 32B. The area of the bottommost second sacrificial material 242 may coincide with or may be less than the area of each of the first sacrificial material layers 142. In one embodiment, the lateral extent of the second sacrificial material layers 242 along the first horizontal direction may decrease stepwise with the vertical distance from the horizontal plane including the bottom surface of the bottommost insulating layer 32B.

In one embodiment, the stepped surfaces of the alternating stack (32, 42) may comprise horizontal surface segments of the second sacrificial material layers 42 and vertical steps each including a combination of a sidewall of a second sacrificial material layer 242 and an insulating layer 32. Further, a straight sidewall of the alternating stack (32, 42) may vertically extend from the top surface of the carrier substrate 9 at least to the horizontal plane including a top surface of the topmost first sacrificial material layer 142. A stepped cavity is formed over the stepped surfaces of the alternating stack (32, 42).

A stepped dielectric material portion 65 (i.e., an insulating fill material portion) can be formed in the stepped cavity by deposition of a dielectric material over the stepped surfaces and by subsequent planarization of the dielectric material.

The insulating layers 32 may comprise a first subset of the insulating layers 32 that underlie the topmost first sacrificial material layer 142 and a second subset of the insulating layers 32 that overlie the topmost first sacrificial material layer 142. In one embodiment, the first subset of the insulating layers 32 comprises N+m insulating layers 32, in which N is an integer in a range from 4 to 512, and the second subset of the insulating layers 32 comprises N+k+1 insulating layers 32 including the topmost insulating layer 32T. The integers m and k may be independently selected from a number in range from 1 to 13, such as from 1 to 5, although a greater number may also be employed.

A straight sidewall of the stepped dielectric material portion 65 vertically extends from a bottom surface of a bottommost insulating layer 32B within the first subset at least to a top surface of a topmost insulating layer 32M within the first subset, and contacts each of the insulating layers 32 within the first subset. In one embodiment, each of the insulating layers 32 may have a same first thickness, and each of the sacrificial material layers 42 may have a same second thickness. In one embodiment, the straight sidewall of the stepped dielectric material portion 65 may vertically extend from a top surface of the carrier substrate 9 to a top surface of the bottommost second sacrificial material layer 242. In one embodiment, the vertical extent of the straight sidewall may be at least one half of the vertical extent of the alternating stack (32, 42).

The processing steps described with reference to FIGS. 3A and 3B can be performed to form memory openings 49 and support openings 19.

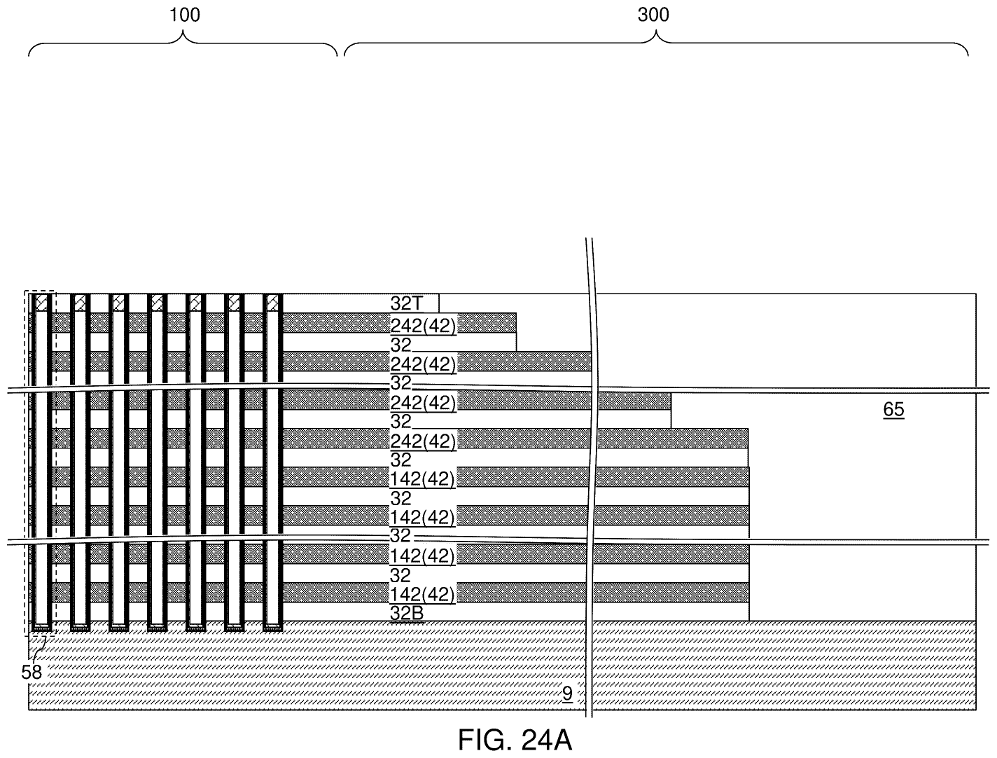

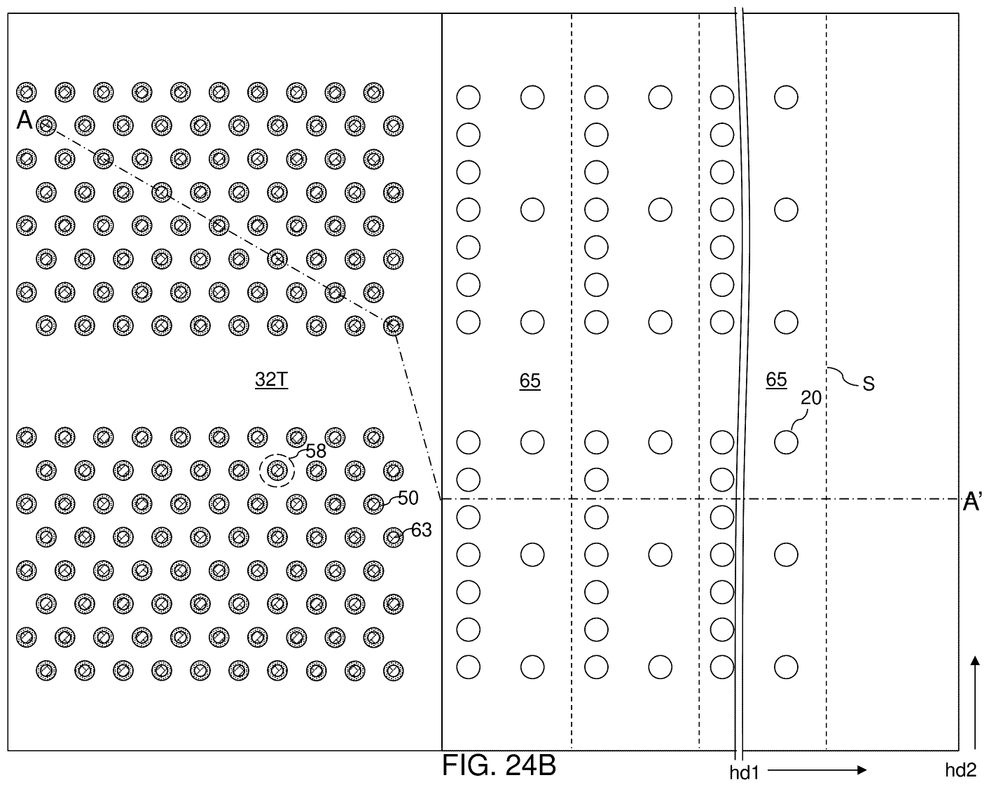

Referring to FIGS. 24A and 24B, the processing steps described with reference to FIGS. 4-8B can be performed to form support pillar structures 20 in the support openings 19 and to form memory opening fill structures 58 in the memory openings 49. Each of the memory opening fill structures comprises a memory stack structure 55, which can include a combination of a vertical stack of memory elements (such as portions of a memory material layer 54 located at levels of the sacrificial material layers 42) and a vertical semiconductor channel 60.

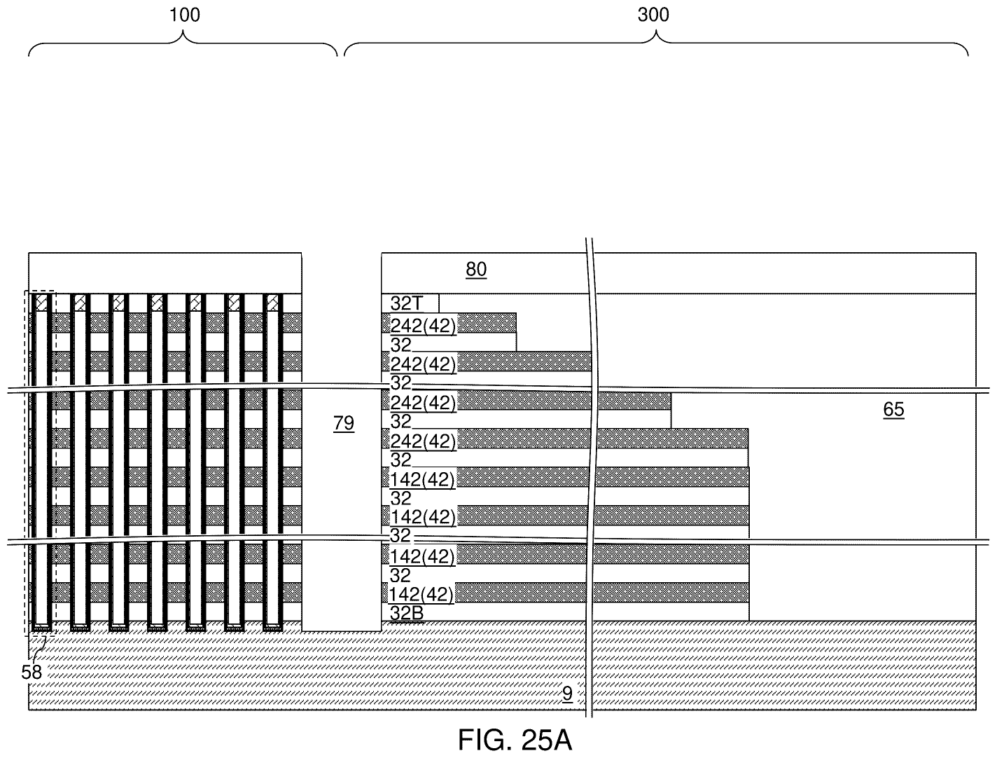

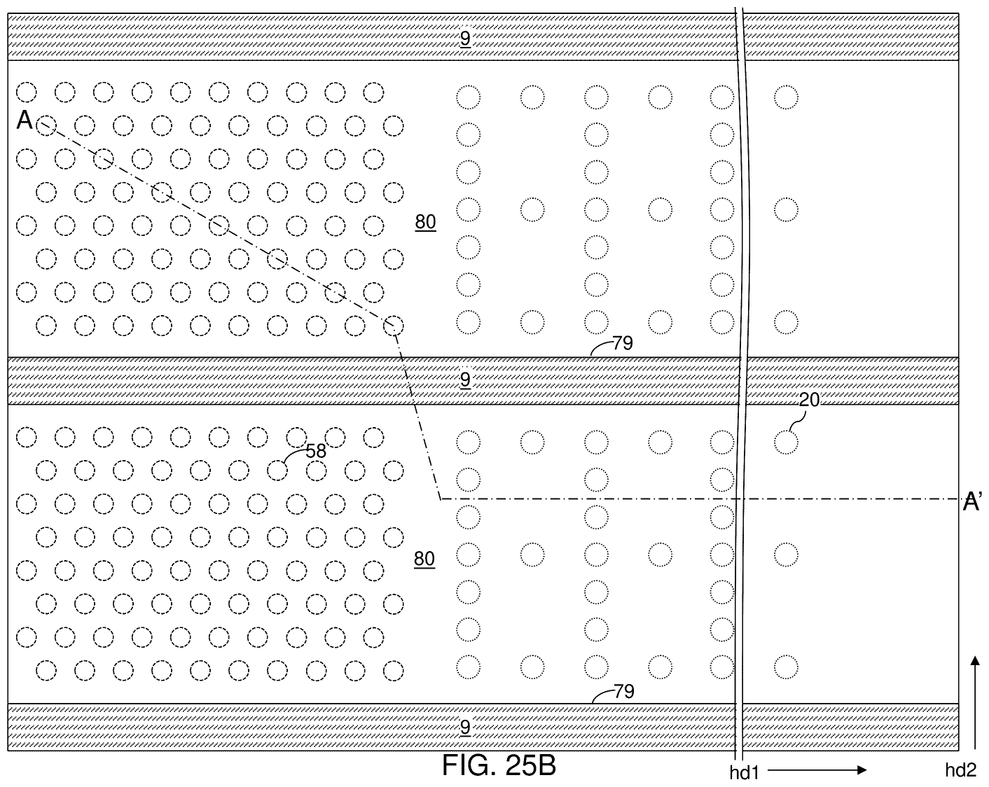

Referring to FIGS. 25A and 25B, the processing steps described with reference to FIGS. 9A and 9B can be performed to form lateral isolation trenches 79.

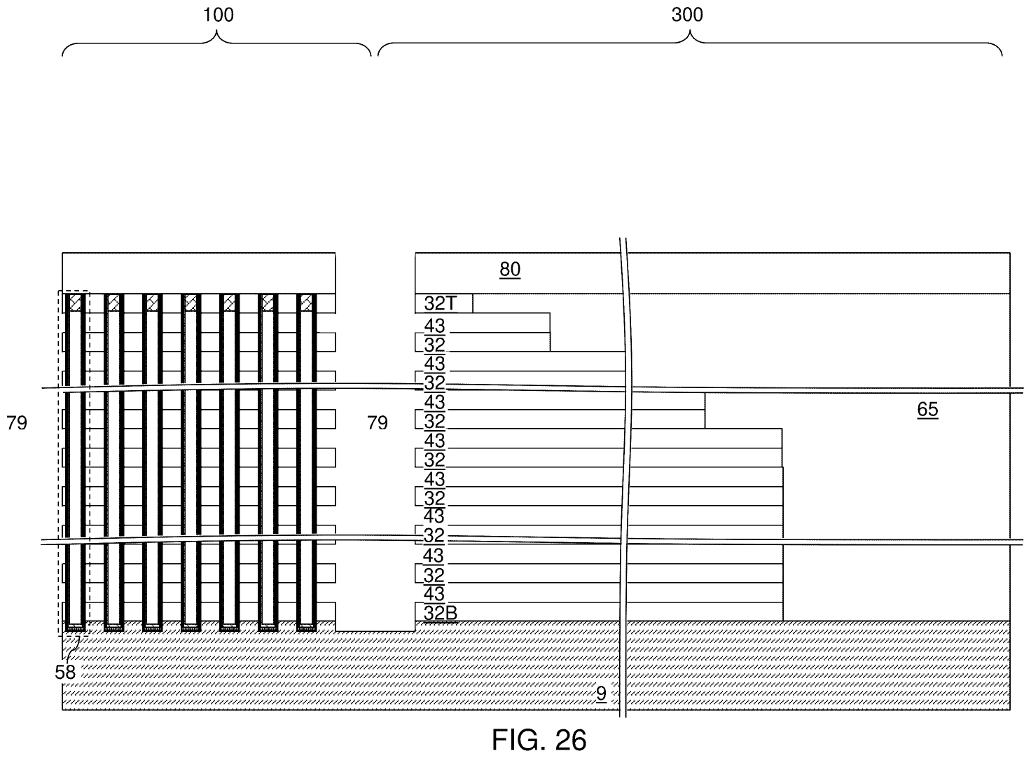

Referring to FIG. 26, the processing steps described with reference to FIG. 10 can be performed to form lateral recesses 43.

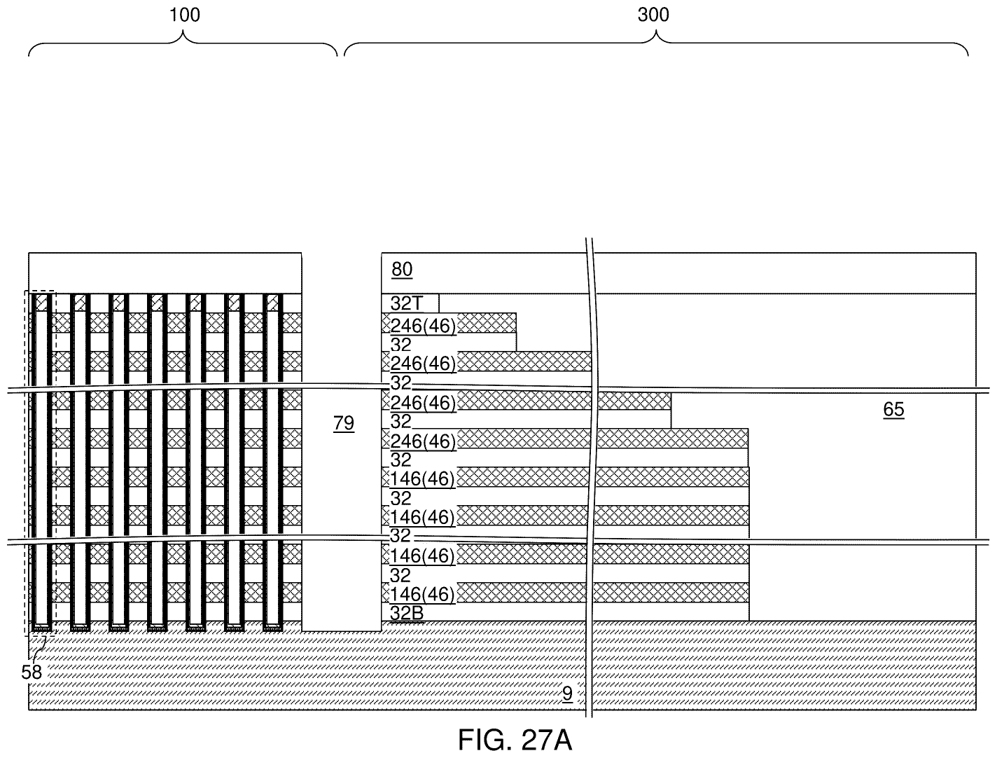

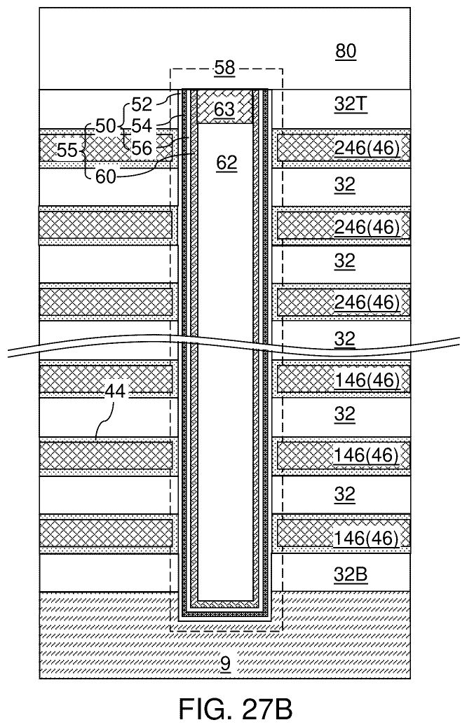

Referring to FIGS. 27A and 27B, the processing steps described with reference to FIGS. 11A and 11B can be performed to form outer blocking dielectric layers 44 and electrically conductive layers 46. The electrically conductive layers 46 comprise first electrically conductive layers 146 that replace the first sacrificial material layers 142 and second electrically conductive layers 246 that replace the second electrically conductive layers 242.

In summary, a combination of an alternating stack (32, 46) of insulating layers 32 and electrically conductive layers 46, a stepped dielectric material portion 65 overlying stepped surfaces of the alternating stack (32, 46), and memory opening fill structures 58 (which include memory stack structures 55) vertically extending through the alternating stack (32, 46) are formed. The electrically conductive layers 46 comprise first electrically conductive layers 146 and second electrically conductive layers 246 that overlie the first electrically conductive layers 146. Each of the memory opening fill structures 58 comprises a respective memory stack structure 55 that includes a vertical stack of memory elements (which may be comprise portions of a memory material layer 54) and a vertical semiconductor channel 60. Each of the first electrically conductive layers 146 is formed with a first lateral extent, i.e., occupies a same area in a plan view. Lateral extents of the second electrically conductive layers 246 differ from each other, and in one embodiment decrease with a vertical distance from a horizontal plane including a bottommost surface of the alternating stack (32, 46). In one embodiment, a maximum lateral extent of the bottommost second electrically conductive layer 246 of the second electrically conductive layers 246 is not greater than the first lateral extent of each of the first electrically conductive layers 146.

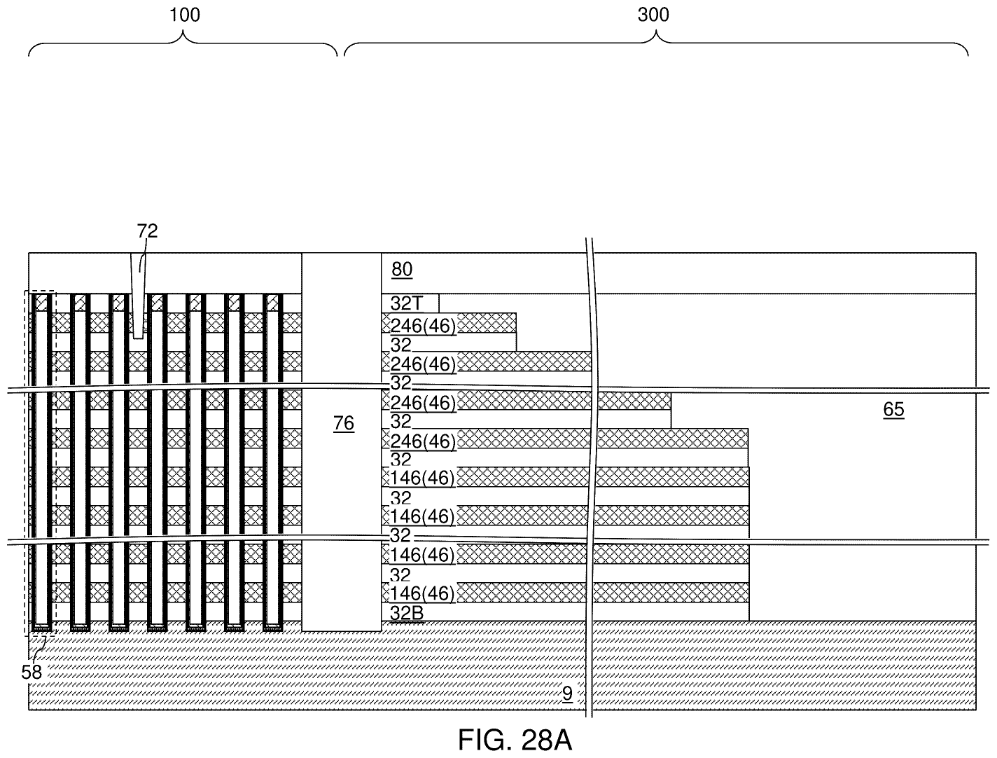

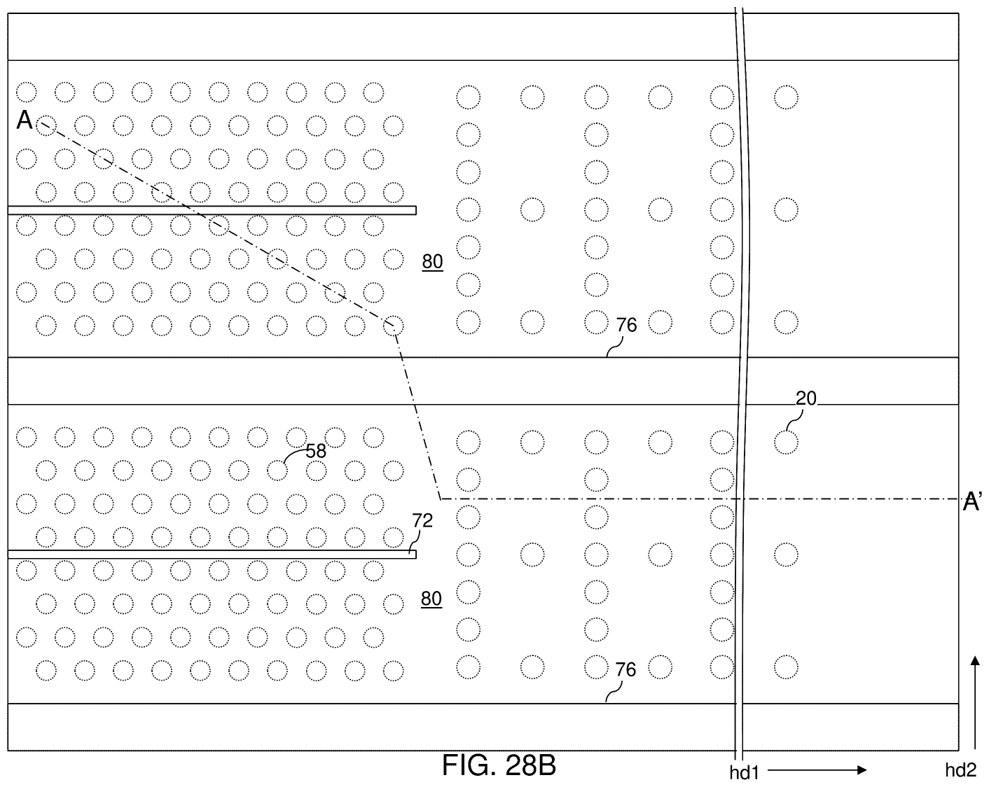

Referring to FIGS. 28A and 28B, a photoresist layer (not shown) can be applied over the contact-level dielectric layer 80, and can be lithographically patterned to form slit-shaped openings that extend along the first horizontal position between neighboring pairs of rows of memory opening fill structures 58. An anisotropic etch process can be performed to form drain-select-level isolation trenches at least through the topmost electrically conductive layer 46. In one embodiment, the electrically conductive layers 46 may comprise (N+m) first electrically conductive layers 146 and (N+k) second electrically conductive layers 246 that overlie the (N+m) first electrically conductive layers 146. N is an integer in a range from 4 to 512, and m and k are integers that are independently selected from a number in a range from 1 to 13, such as from 1 to 5. In this case, the electrically conductive layers 46 within each alternating stack (32, 46) may comprise N lower word lines comprising N first electrically conductive layers 146, N upper word lines comprising N second electrically conductive layers 246, m source side select gate electrodes that comprise m bottommost first electrically conductive layers 146, and k drain side select gate electrodes that comprise patterned portions of k topmost second electrically conductive layers 246. The photoresist layer can be subsequently removed, for example, by ashing.

A dielectric fill material, such as silicon oxide, can be deposited in the lateral isolation trenches 79 and in the drain-select-level isolation trenches. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. Each remaining portion of the dielectric fill material that fills a respective one of the drain-select-level isolation trenches constitutes a drain-select-level isolation structure 72. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

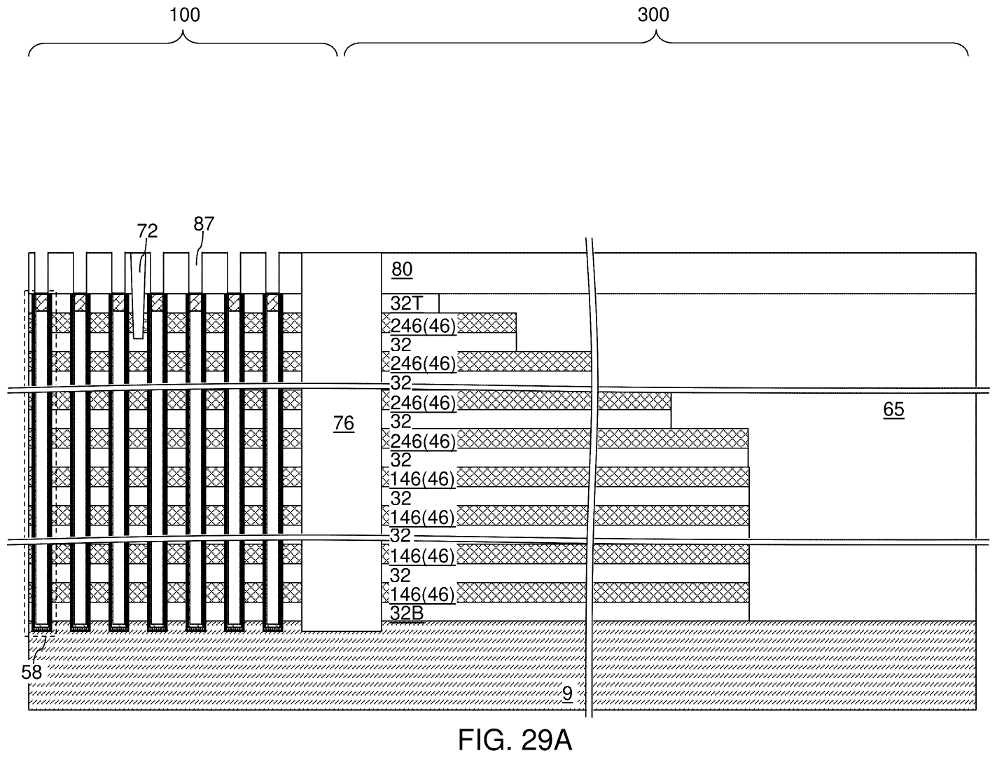

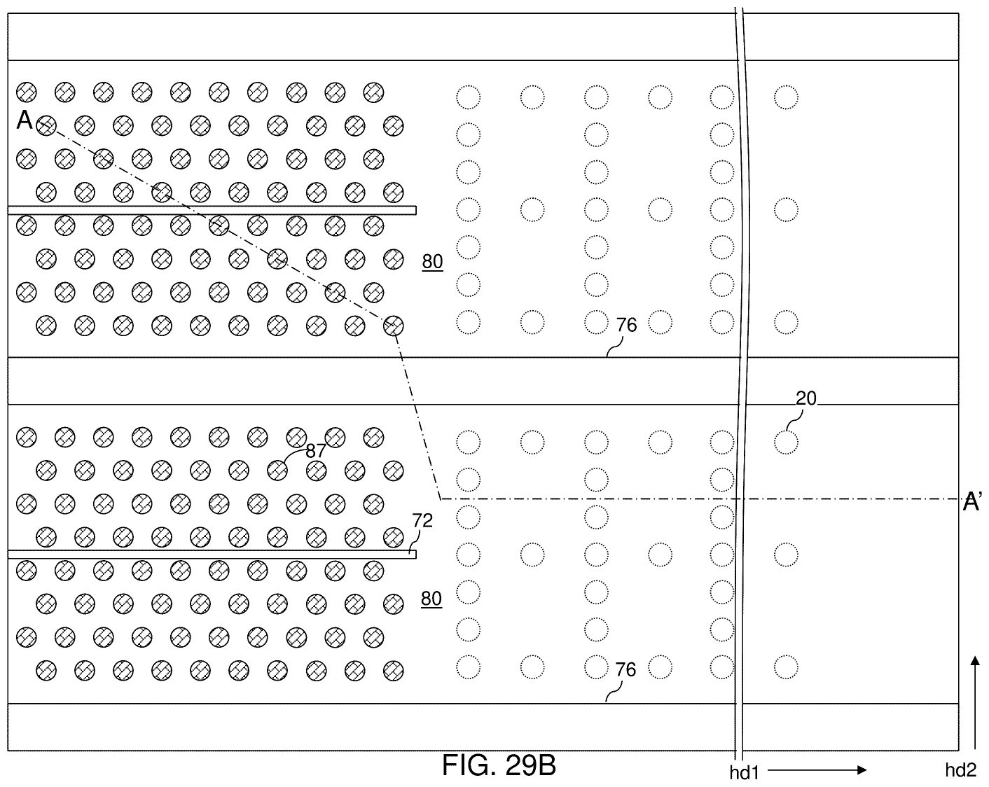

Referring to FIGS. 29A and 29B, a photoresist layer (not shown) can be applied over the contact-level dielectric layer 80, and can be lithographically patterned to form openings over the areas of the memory opening fill structures 58. A first anisotropic etch process can be performed to etch portions of the contact-level dielectric layer 80 that are not masked by the photoresist layer. Drain contact via cavities 87 can be formed over the memory opening fill structures 58 such that top surfaces of the drain regions 63 are physically exposed at the bottom of the drain contact via cavities 87.

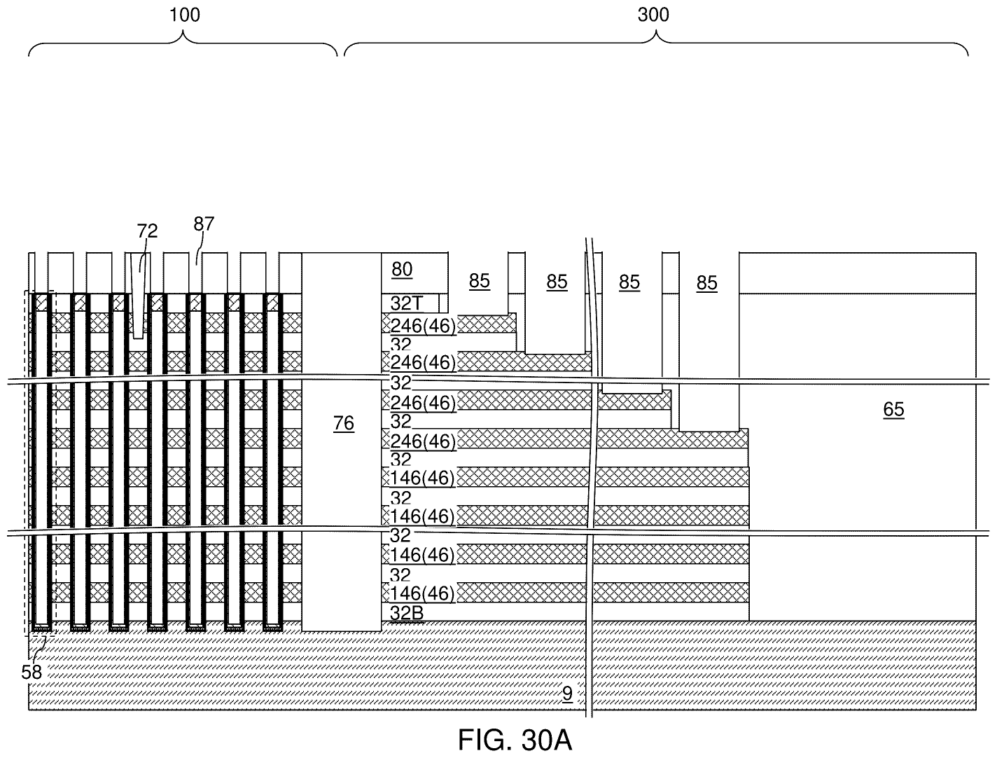

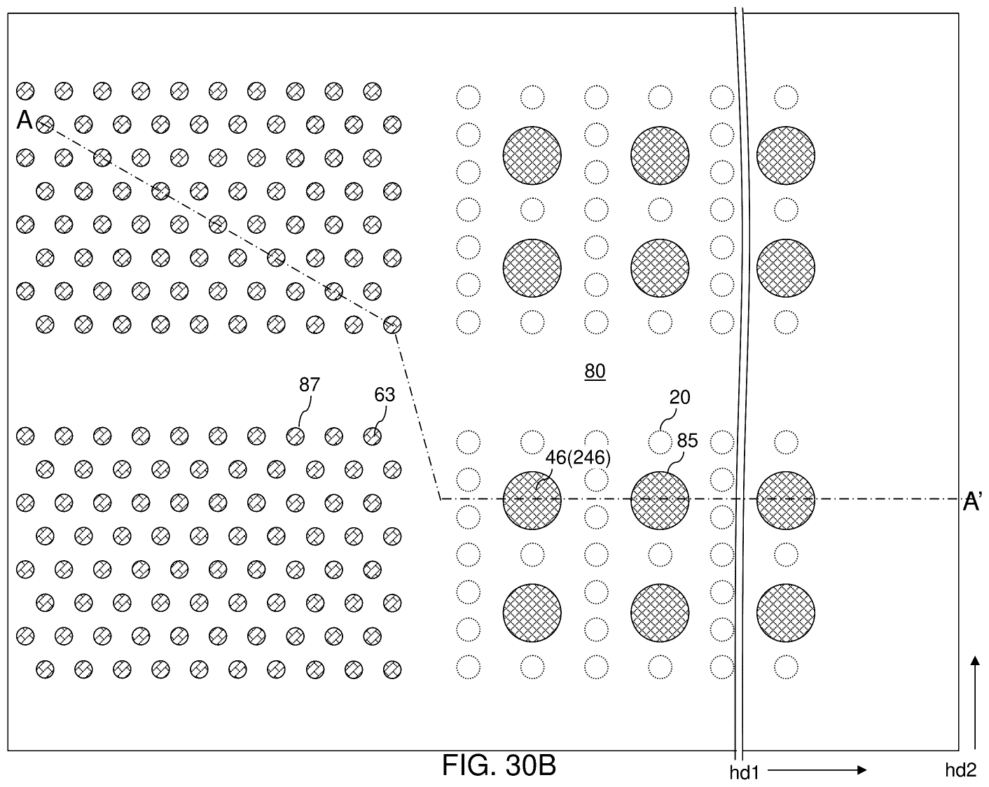

Referring to FIGS. 30A and 30B, a photoresist layer (not shown) can be applied over the contact-level dielectric layer 80, and can be lithographically patterned to form openings over horizontally-extending surface segments of the stepped bottom surface of the stepped dielectric material portion 65. A second anisotropic etch process can be performed to etch unmasked portions of the contact-level dielectric layer 80 and the stepped dielectric material portion 65. The second anisotropic etch process may have an etch chemistry that etches the materials of the contact-level dielectric layer 80 and the stepped dielectric material portion 65 selective to the material of the electrically conductive layers 46. A layer contact via cavity 85 is formed in each volume from which the materials of the contact-level dielectric layer 80, the stepped dielectric material portion 65, and outer blocking dielectric layers 44 are removed. A top surface segment of a second electrically conductive layer 246 can be physically exposed at the bottom of each layer contact via cavity 85. In one embodiment, each of the second electrically conductive layers 246 that are employed as upper word lines and drain side select gate electrodes may have a respective physically exposed top surface segment that underlies a respective one of the layer contact via cavities 85. The photoresist layer may be subsequently removed, for example, by ashing. Thus, the layer contact via cavities 85 can be formed through the stepped dielectric material portion 65 so that top surface segments of the second electrically conductive layers 246 are physically exposed upon formation of the layer contact via cavities 85.

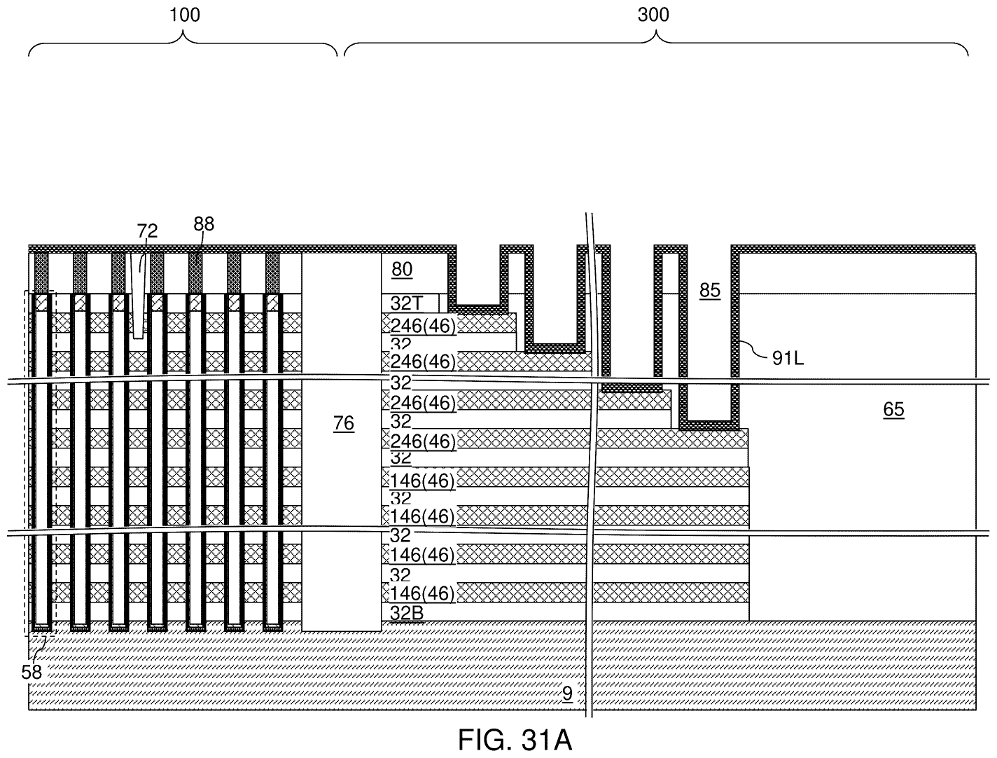

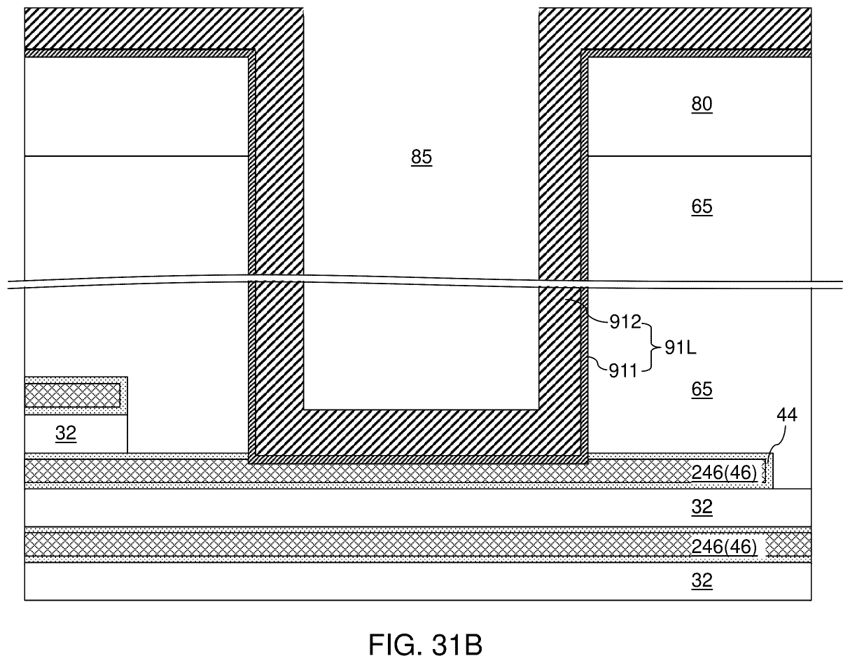

Referring to FIGS. 31A and 31B, at least one outer metallic material layer 91L can be deposited on the physically exposed surfaces around the layer contact via cavities 85 and over the contact-level dielectric layer 80. The at least one outer metallic material layer 91L may comprise an optional outer metallic barrier liner 911 and an outer metal layer 912. The outer metallic barrier liner 911 may comprise a metallic barrier material such as TiN, TaN, WN, and/or MoN. The outer metallic barrier liner 911 may be deposited by physical vapor deposition or chemical vapor deposition. The thickness of the outer metallic barrier liner 911 may be in a range from 3 nm to 50 nm, although lesser and greater thicknesses may also be employed. The outer metallic barrier liner 911 can be formed directly on each physically exposed planar surface of the second electrically conductive layers 246. The outer metallic barrier liner 911 may also be formed on physically exposed cylindrical surface segments of the outer blocking dielectric layers 44.

The outer metal layer 912 may comprise a metal, such as W, Mo, Ti, Ta, Co, Ru, Cu, etc. The outer metal layer 912 may be deposited by physical vapor deposition, chemical vapor deposition, electroplating, or a combination thereof. The thickness of the outer metal layer 912 may be in a range from 5% to 25%, such as from 10% to 20%, of the lateral dimension of each layer contact via cavity 85 as formed at the processing steps of FIGS. 30A and 30B. For example, the thickness of the outer metal layer 912 may be in a range from 10 nm to 200 nm, although lesser and greater thicknesses may also be employed.

In one embodiment, the thickness of the at least one outer metallic material layer 91L may be greater than one half of the lateral dimension (such as the diameter) of each drain contact via cavity 85. In this case, the entire volume of each drain contact via cavity 87 can be filled with the at least one outer metallic material layer 91L.

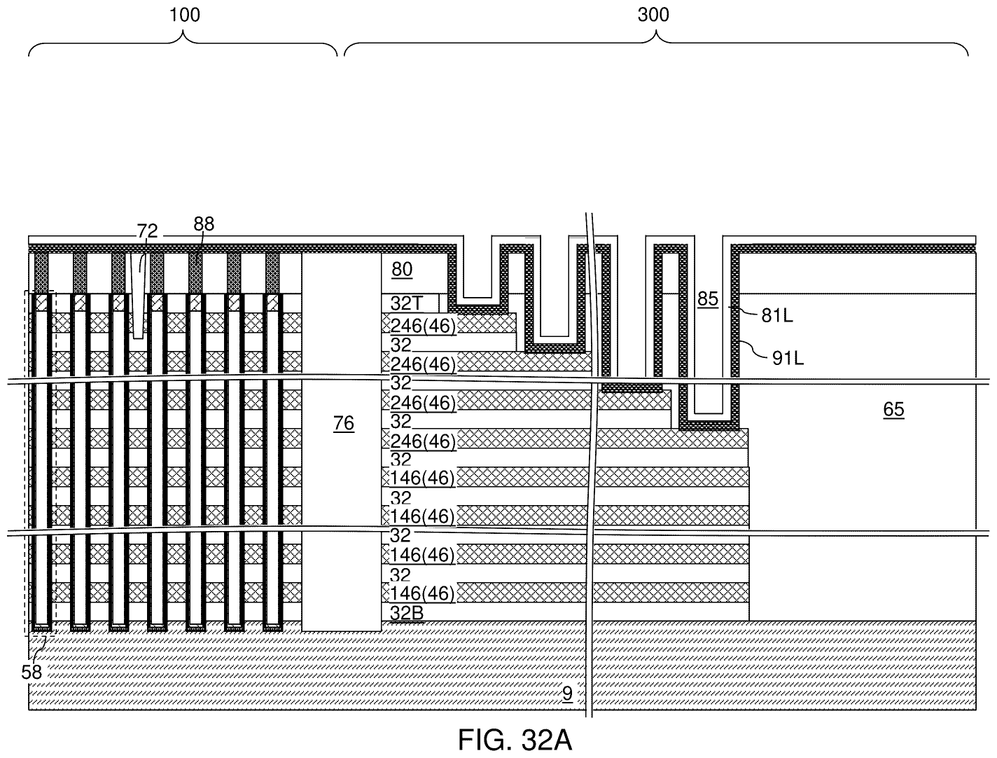

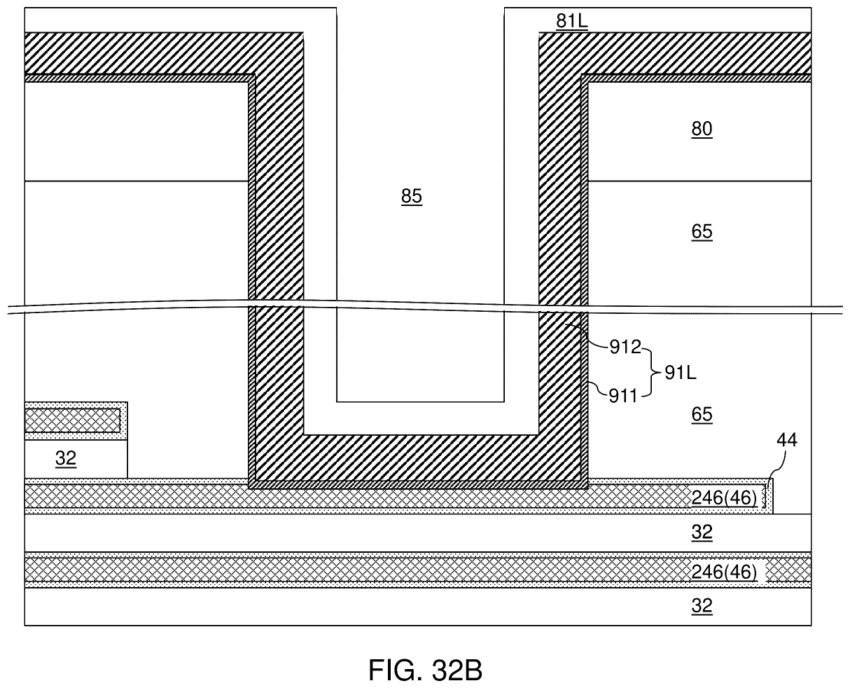

Referring to FIGS. 32A and 32B, an outer insulating spacer material layer 81L can be formed by conformal deposition of an insulating material, which may comprise silicon oxide, silicon nitride, or another insulating material. The outer insulating spacer material layer 81L is formed on the at least one outer metallic material layer 91L. The outer insulating spacer material layer 81L can be deposited by a conformal deposition process, such as a chemical vapor deposition process, and may have a thickness in a range from 2% to 10%, such as from 3% to 7%, of the lateral dimension of each layer contact via cavity 85 as formed at the processing steps of FIGS. 30A and 30B.

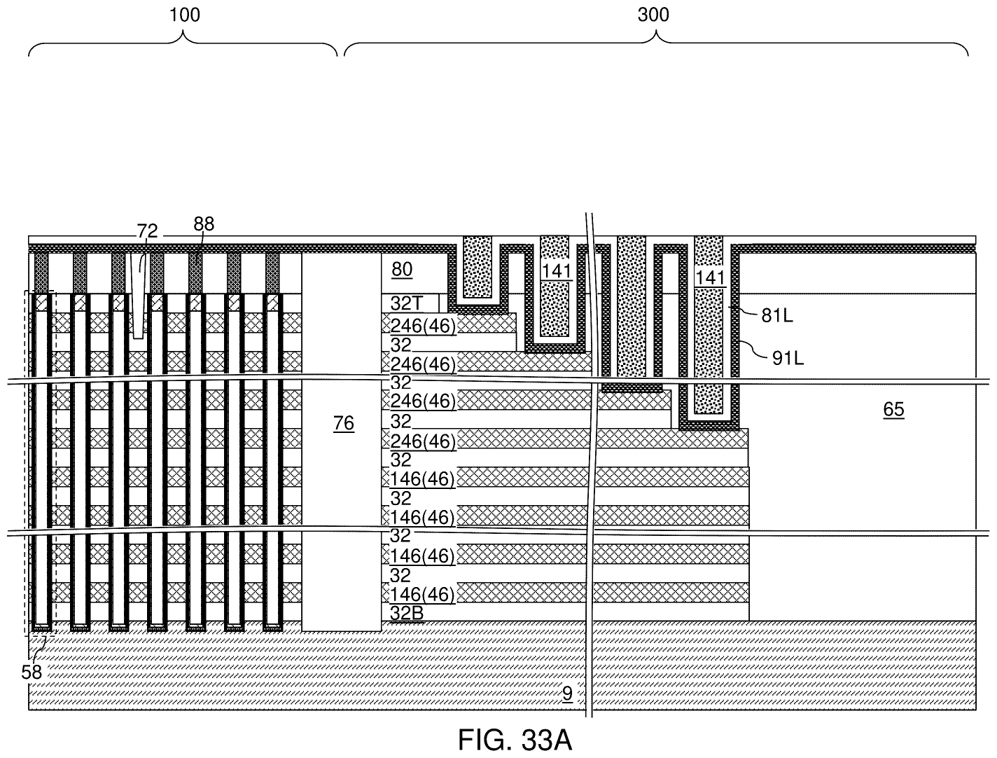

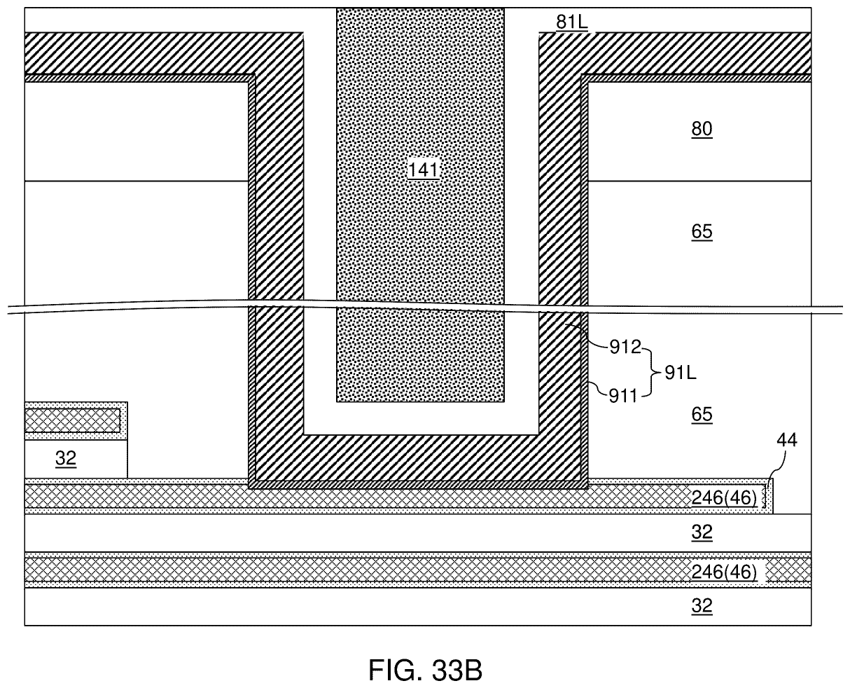

Referring to FIGS. 33A and 33B, a sacrificial via fill material may be optionally deposited in the voids within the layer contact via cavities 85. The sacrificial via fill material comprises a material that may be subsequently removed selective to the material of the outer insulating spacer material layer 81L. For example, the sacrificial via fill material may comprise amorphous carbon, a semiconductor material (such as silicon or a silicon-germanium alloy), a polymer material, or a silicate glass material having a high etch rate (such as organosilicate glass or borosilicate glass). Excess portions of the sacrificial via fill material can be removed from above the horizontal plane including the top surface of a horizontally-extending portion of the outer insulating spacer material layer 81L by a planarization process, which may comprise a chemical mechanical polishing process and/or a recess etch process. Each remaining portion of the sacrificial via fill material that fills a respective void within the layer contact via cavities 85 comprise a sacrificial via fill structure 141.

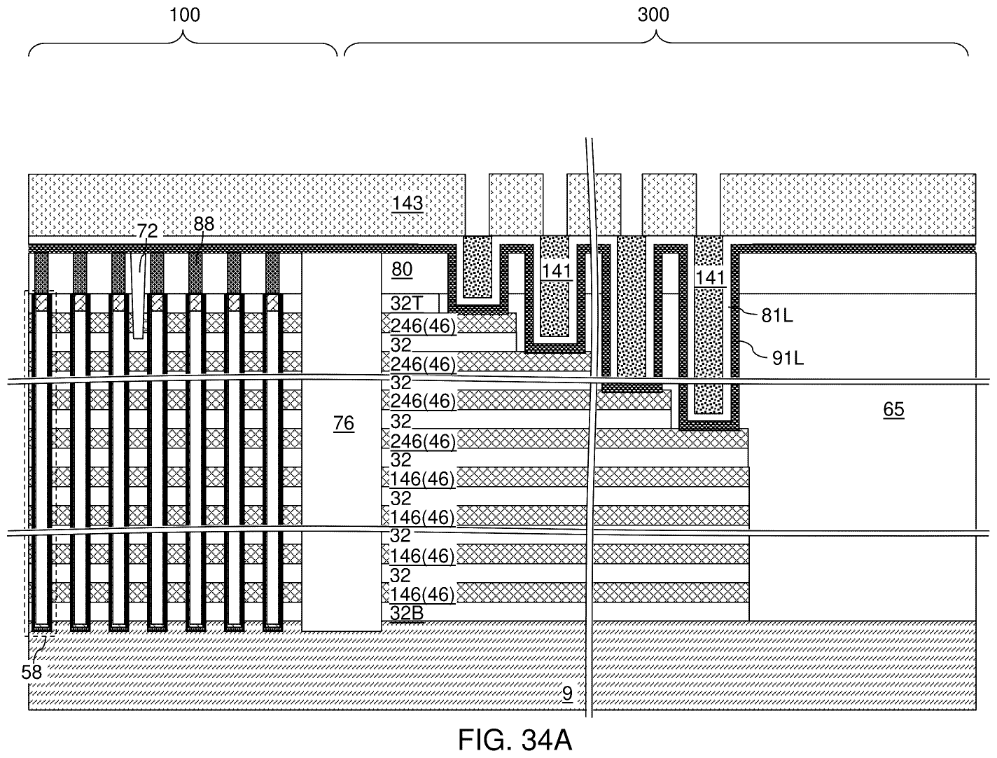

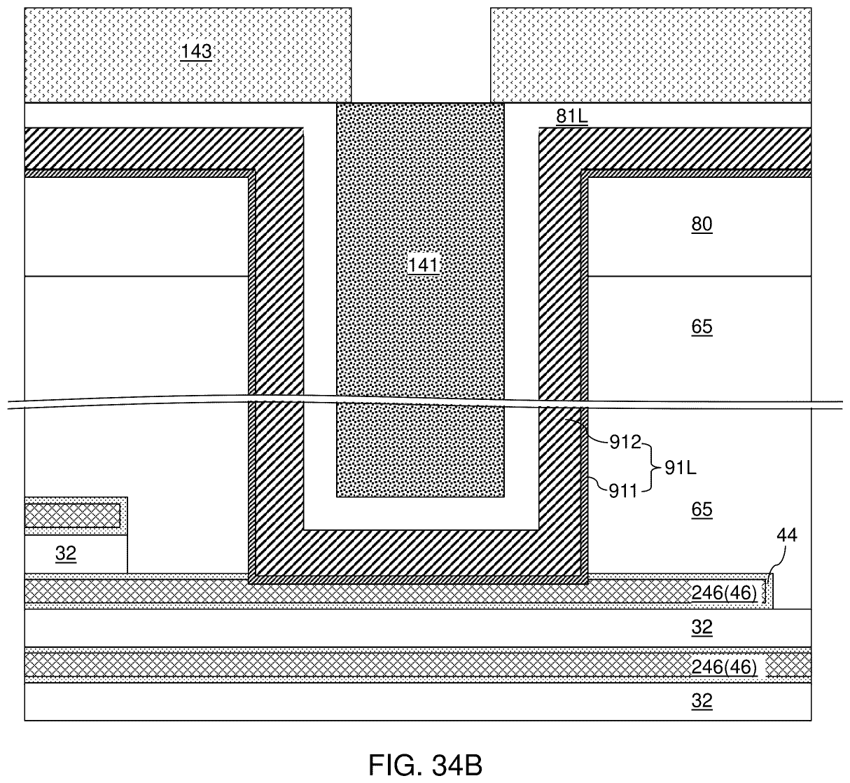

Referring to FIGS. 34A and 34B, a patterned etch mask layer 143 can be formed over the horizontally-extending portion of the outer insulating spacer material layer 81L. The patterned etch mask layer 143 may comprise an optional hard mask layer, at least one patterning assist layer (such as a dielectric antireflective coating layer), and a photoresist layer. The patterned etch mask layer 143 comprises openings that are located over the sacrificial via fill structures 141. The patterned etch mask layer 143 covers a horizontally-extending portion of the outer insulating spacer material layer 81L that overlies the layer contact via cavities 85.

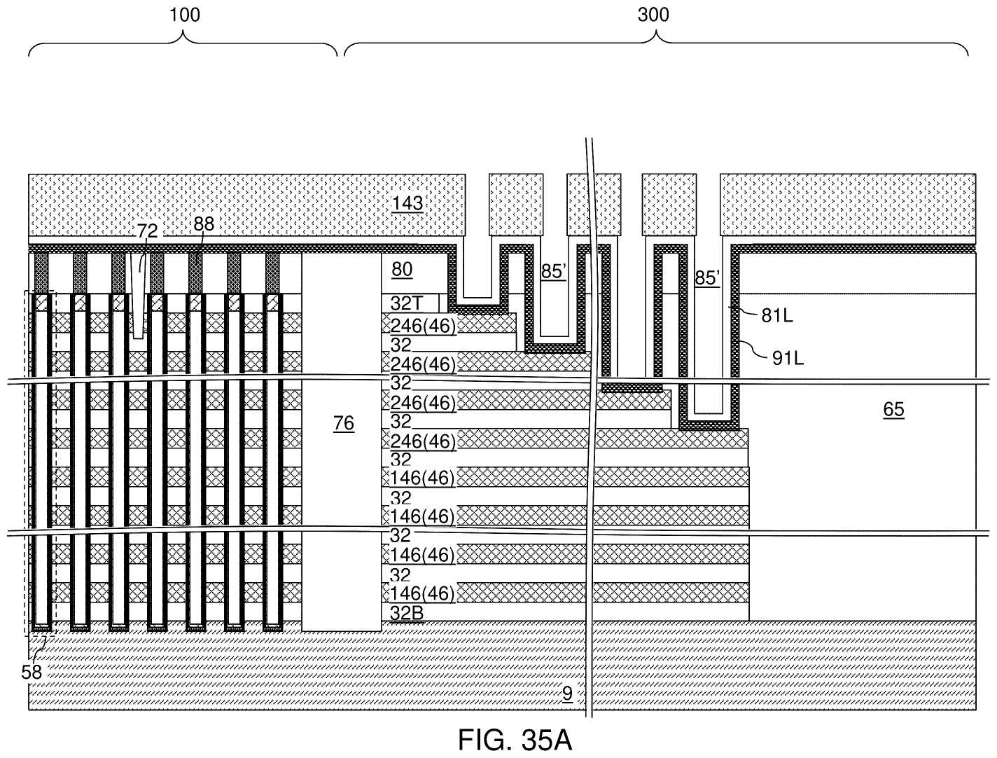

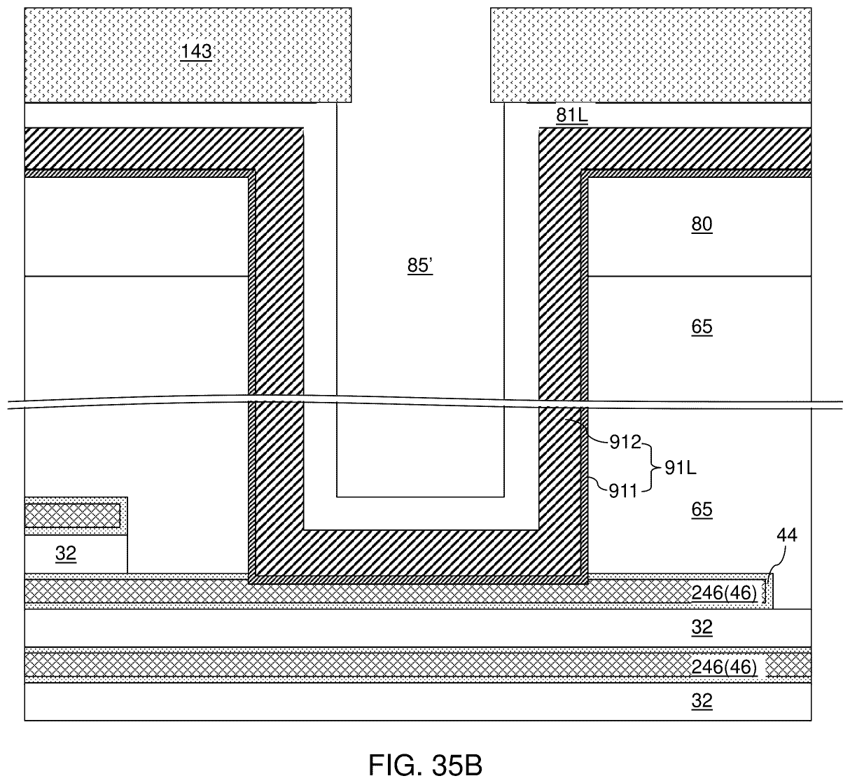

Referring to FIGS. 35A and 35B, the sacrificial via fill structures 141 can be removed selective to the material of the outer insulating spacer material layer 81L. An anisotropic etch process (such as a reactive ion etch process), an isotropic etch process (such as a wet etch process), or an ashing process may be employed to remove the sacrificial via fill structures 141. Voids 85′ are formed in volumes from which the material of the sacrificial via fill structures 141 are removed.

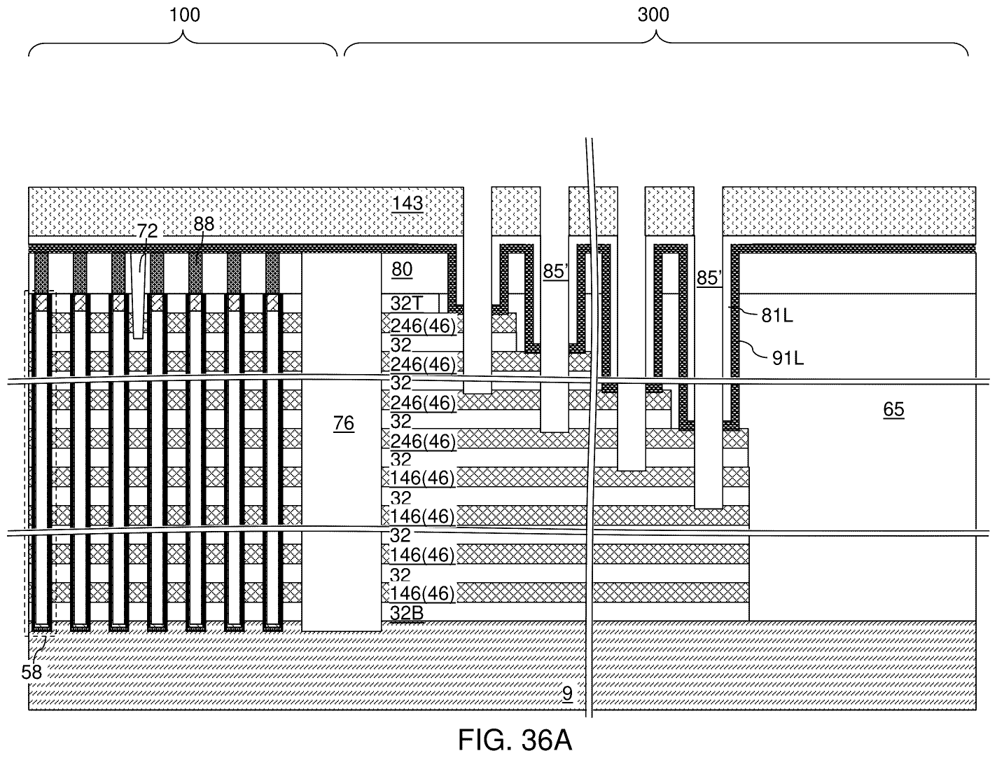

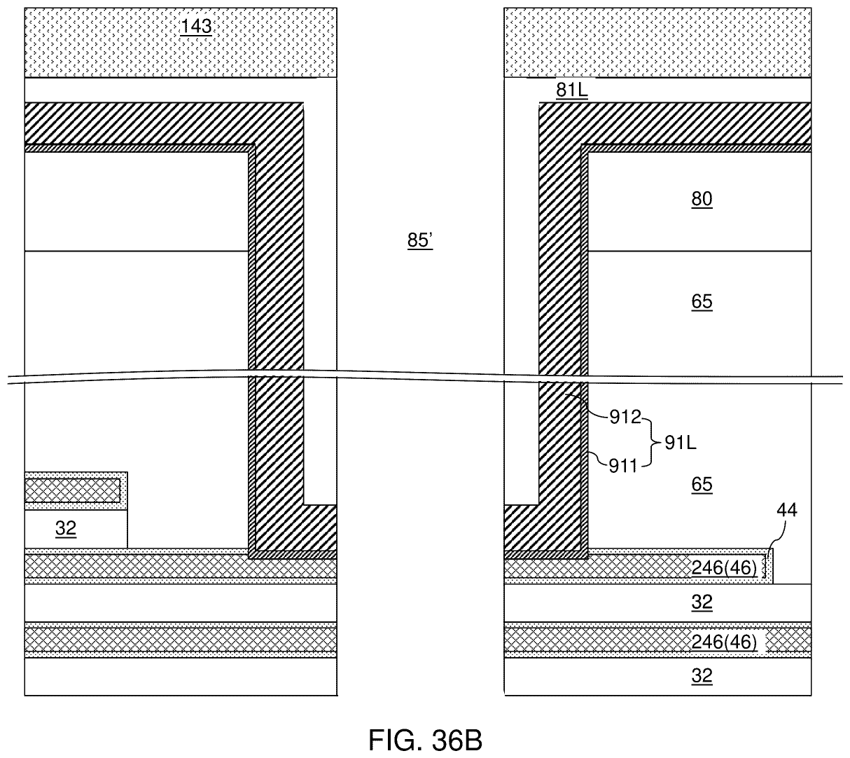

Referring to FIGS. 36A and 36B, an anisotropic etch process can be performed to etch unmasked portions of the outer insulating spacer material layer 81L, the at least one outer metallic material layer 91L, the electrically conductive layers 46, the outer blocking dielectric layers 44, and the insulating layers 32. The duration of the anisotropic etch process can be selected such that not more than N pairs of an electrically conductive layer 46 and an insulating layer 32 are etched through. In one embodiment, the duration of the anisotropic etch process can be selected such that less than N pairs of an electrically conductive layer 46 and an insulating layer 32 are etched through. In one embodiment, the duration of the anisotropic etch process can be selected such that N pairs of an electrically conductive layer 46 and an insulating layer 32 are etched through.

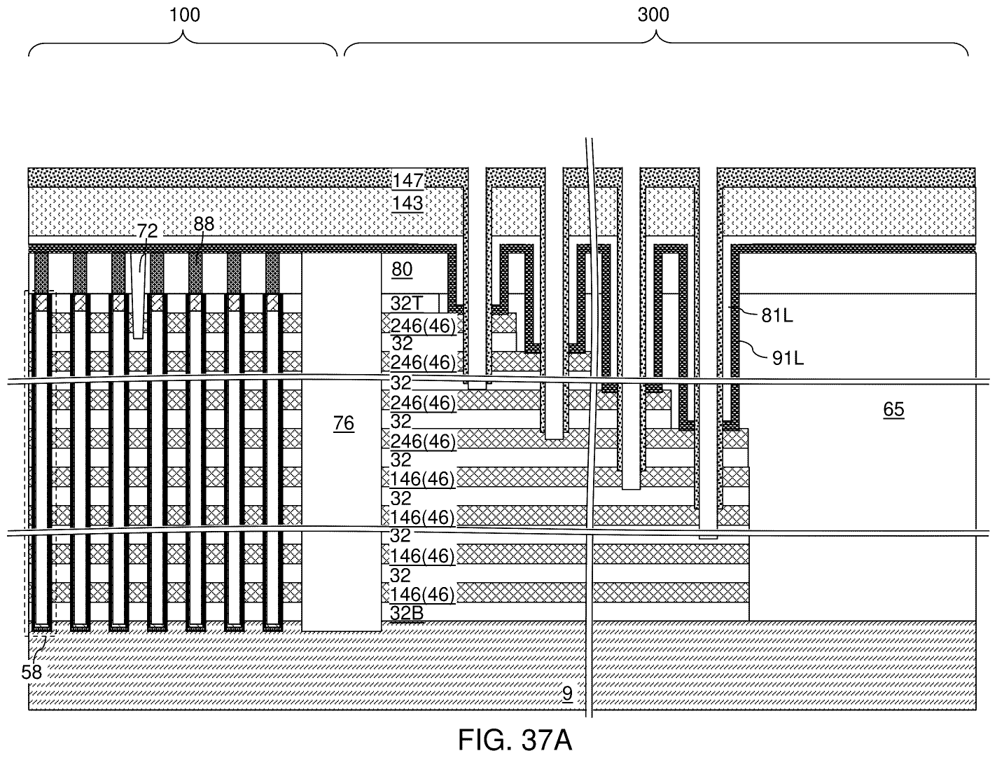

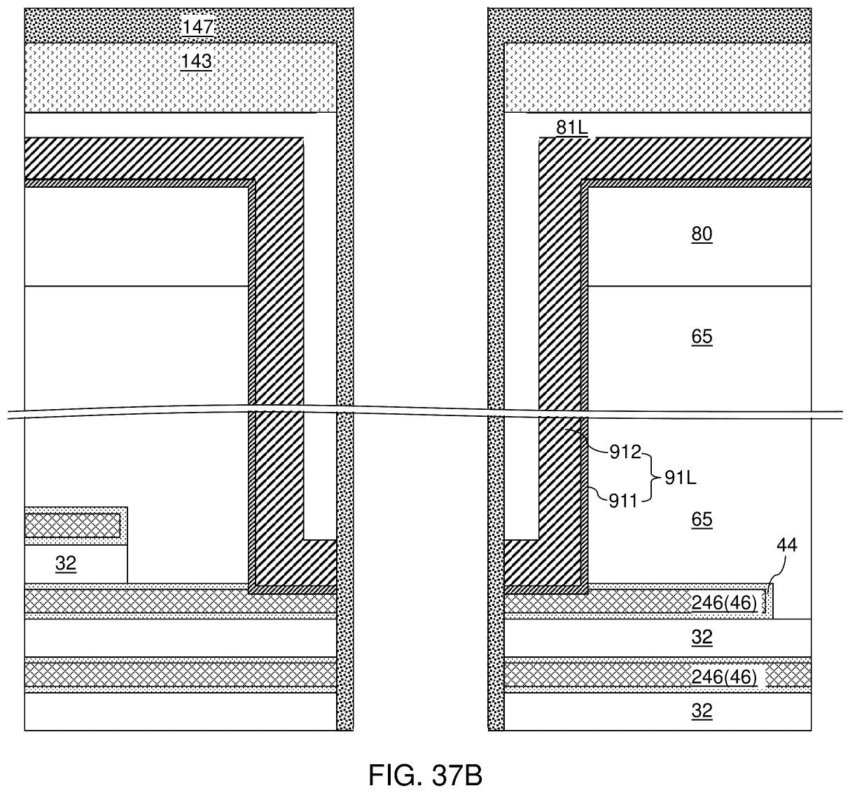

If the duration of the anisotropic etch process is selected such that less than N pairs of an electrically conductive layer 46 and an insulating layer 32 are etched through at the processing steps of FIGS. 36A and 36B, a patterning film 147 may be anisotropically deposited over the patterned etch mask layer 143 as illustrated in FIGS. 37A and 37B. The patterning film 147 may comprise an amorphous carbon-based material such as Advanced Patterning Film™ which is commercially available from Applied Materials, Inc®.

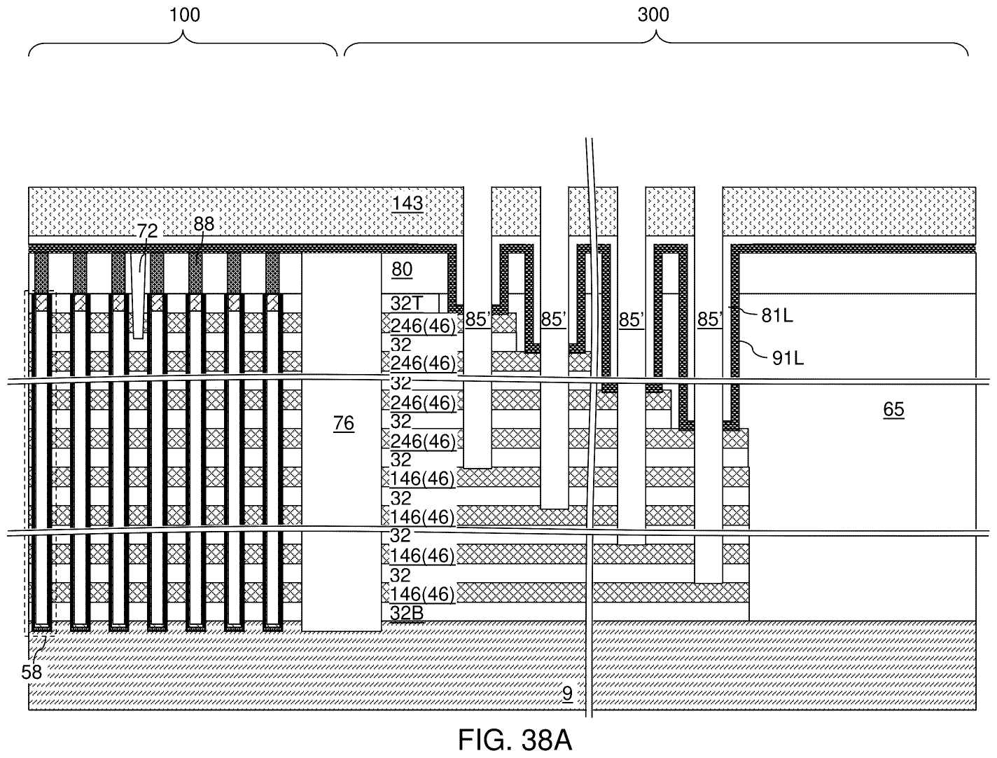

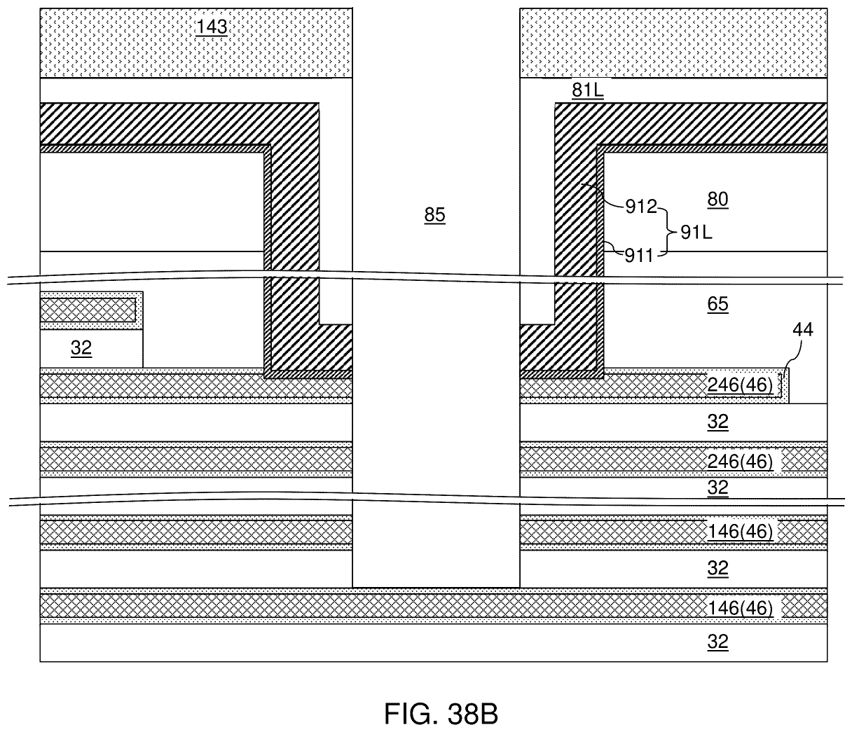

Referring to FIGS. 38A-38B, if the duration of the anisotropic etch process is selected such that less than N pairs of an electrically conductive layer 46 and an insulating layer 32 are etched through at the processing steps of FIGS. 36A and 36B, then an additional anisotropic etch process may be performed to vertically extend the voids 85′ that are laterally surrounded by vertically-extending portions of the outer insulating spacer material layer 81L. If the patterning film 147 is present then horizontal portions of the patterning film 147 are removed either by the additional anisotropic etch process or by a separate anisotropic sidewall spacer etch process that precedes the additional anisotropic etch process.

In one embodiment, the duration of the additional anisotropic etch process can be selected such that each of the voids 85′ vertically extends through N pairs of an electrically conductive layer 46 and an insulating layer 32. Surface segments of the first electrically conductive layers 146 are physically exposed underneath voids 85′ that are formed by the additional anisotropic etch process.

In summary, a single anisotropic etch process or a plurality of anisotropic etch processes in combination with at least one deposition of a patterning film 147 can be employed to vertically extend the voids 85′ such that each of the voids 85′ is laterally surrounded by, and is laterally bounded by, N pairs of an electrically conductive layer 46 and an insulating layer 32. Thus, each void 85′ is laterally bounded by cylindrical sidewalls of a respective set of N insulating layers 32, and is laterally bounded by cylindrical sidewalls of a respective set of N electrically conductive layers 46. The respective set of N electrically conductive layers comprise at least one second electrically conductive layer 246, such as the bottommost second electrically conductive layer 246. A top surface segment of a respective one of the second electrically conductive layers 246 can be physically exposed underneath each void 85′.

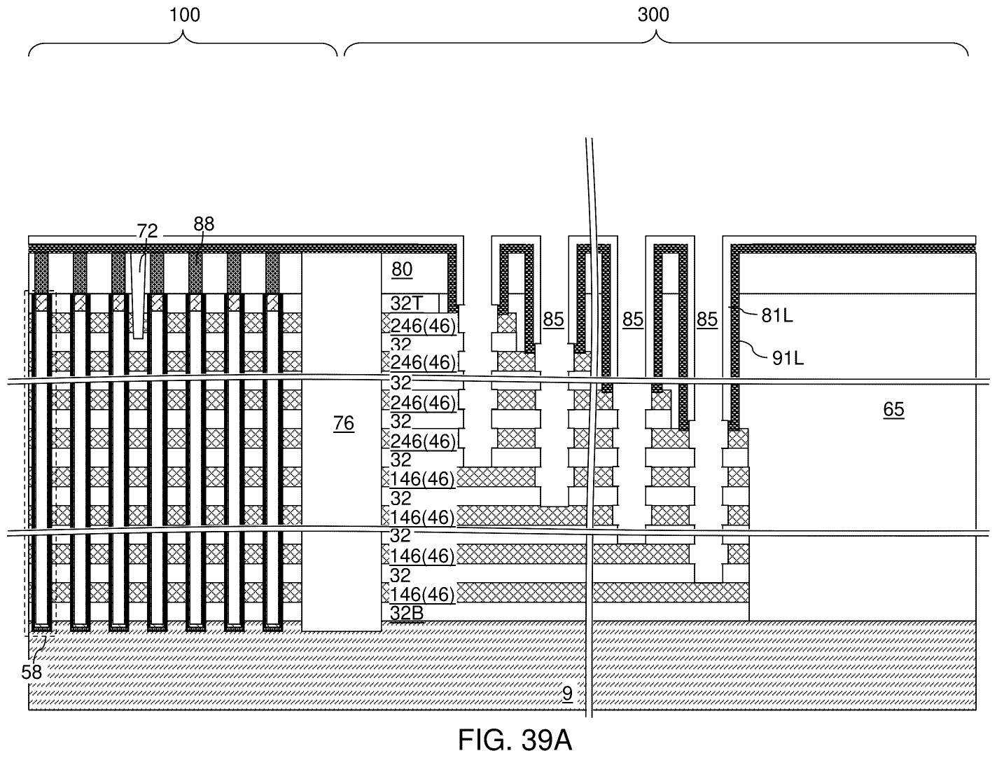

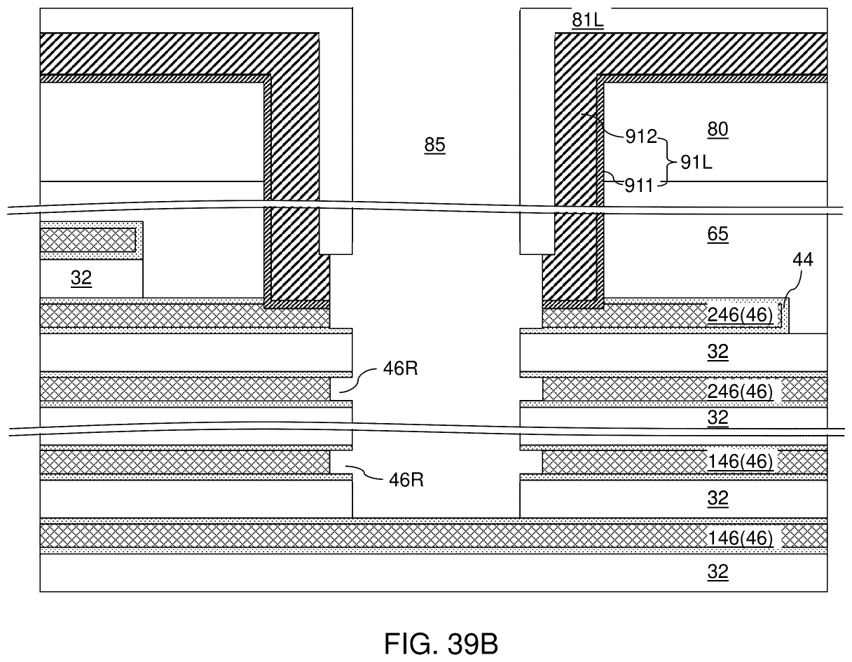

Referring to FIGS. 39A and 39B, an optional isotropic etch process can be performed to isotropically etch the metallic materials of the electrically conductive layers 46 and the outer metallic material layer 91L selective to the dielectric materials of the outer insulating spacer material layer 81L, the insulating layers 32, and the backside blocking dielectric layers 44. The isotropic etch process may comprise a wet etch process that etches metallic materials selectively to dielectric materials. Surface portions of the first electrically conductive layers 146 and the second electrically conductive layers 246 and surface portions of the outer metallic material layer 91L that are exposed to the voids 85′ can be isotropically laterally recessed to leave lateral annular recesses 46R. The lateral recess etch distance of the isotropic etch process may be less than the sum of the thickness of the outer metallic material layer 91L and the thickness of the outer insulating spacer material layer 81L. In one embodiment, the lateral recess etch distance of the isotropic etch process may be less than the thickness of the outer insulating spacer material layer 81L.

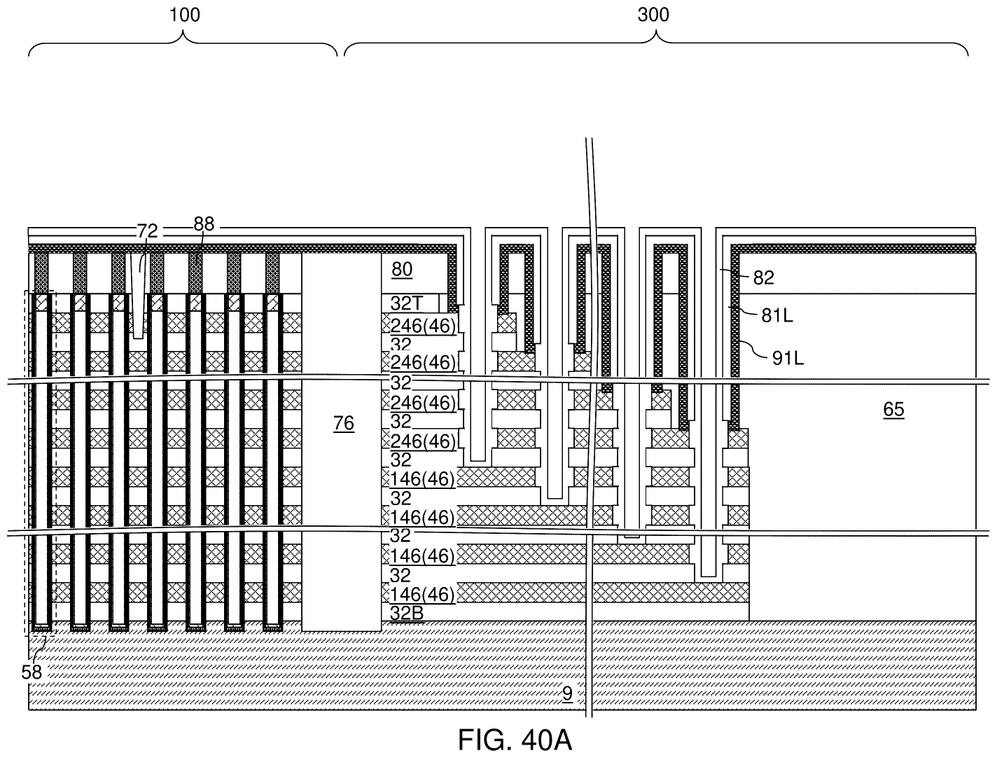

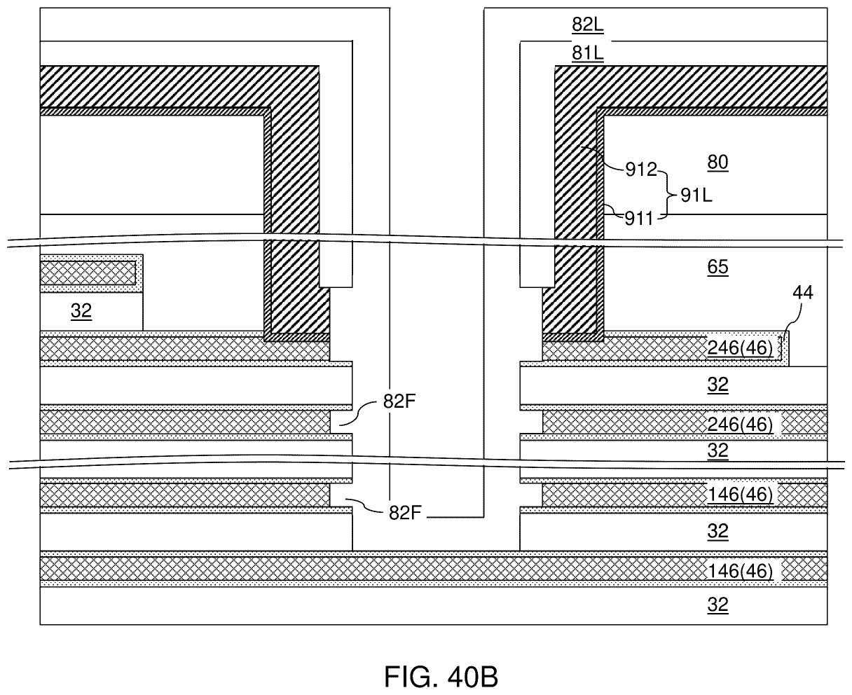

Referring to FIGS. 40A and 40B, an additional insulating spacer material layer, which is herein referred to as an inner insulating spacer material layer 82L, can be formed by conformal deposition of an insulating material, which may comprise silicon oxide, silicon nitride, or another insulating material. The inner insulating spacer material layer 82L can be deposited by a conformal deposition process, such as a chemical vapor deposition process. The thickness of the inner insulating spacer material layer 82L can be greater than one half of the sum of the thickness of the at least one outer metallic material layer 91L and the thickness of an electrically conductive layer 46. Generally, at least one insulating spacer material layer (81L, 82L) is formed inside each vertically-extending tubular portion of the at least one outer metallic material layer 91L. In one embodiment, the at least one insulating spacer material layer (81L, 82L) comprises an inner insulating spacer material layer 82L that is formed on an inner cylindrical sidewall of the outer insulating spacer material layer 81L. The inner insulating spacer material layer 82L includes lateral insulating fins 82F that fill the respective annular recesses 46R that are formed by laterally recessing the electrically conductive layers 46 at the processing steps of FIGS. 39A and 39B.

In one embodiment, each vertically-extending portion of the outer insulating spacer material layer 81L contacts a respective plurality of electrically conductive layers 46 of the electrically conductive layers 46 of the alternating stack (32, 46). In one embodiment, each vertically-extending portion of the outer insulating spacer material layer 81L contacts sidewalls of N electrically conductive layers 46 which include at least a cylindrical sidewall of the bottommost second electrically conductive layer 246. In one embodiment, each vertically-extending portion of the inner insulating spacer material layer 82L may comprise a respective straight inner cylindrical sidewall, and a respective ribbed outer cylindrical sidewall having lateral fins (i.e., protrusions) 82F at each level of the respective plurality of electrically conductive layers 46 (i.e., a respective set of N electrically conductive layers 46). In one embodiment, each of the electrically conductive layers 46 is embedded within a respective outer blocking dielectric layer 44, and the respective ribbed outer cylindrical sidewall contacts annular horizontal surface segments of a subset of the outer blocking dielectric layers 44.

In one embodiment, each tubular portion of the at least one outer metallic material layer 91L contacts an annular top surface of a respective one of the second electrically conductive layers 246, and contacts a respective tubular portion of the outer insulating spacer material layer 81L. The respective tubular portion of the outer insulating spacer material layer 81L is vertically spaced from and is located entirely above the respective one of the second electrically conductive layers 246.

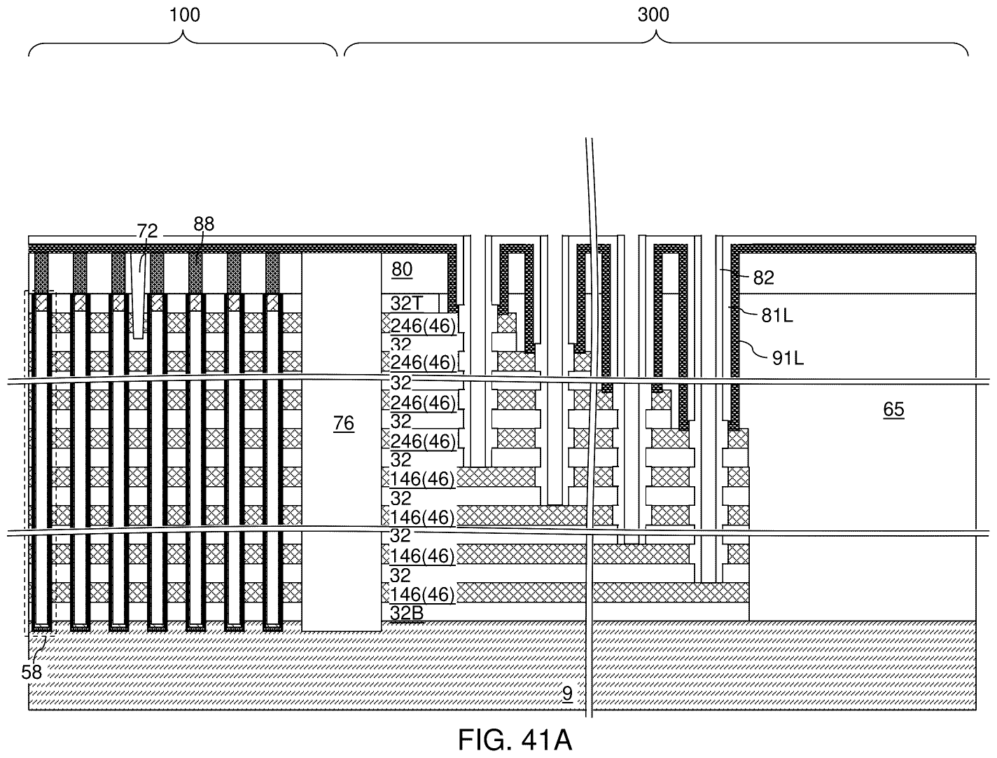

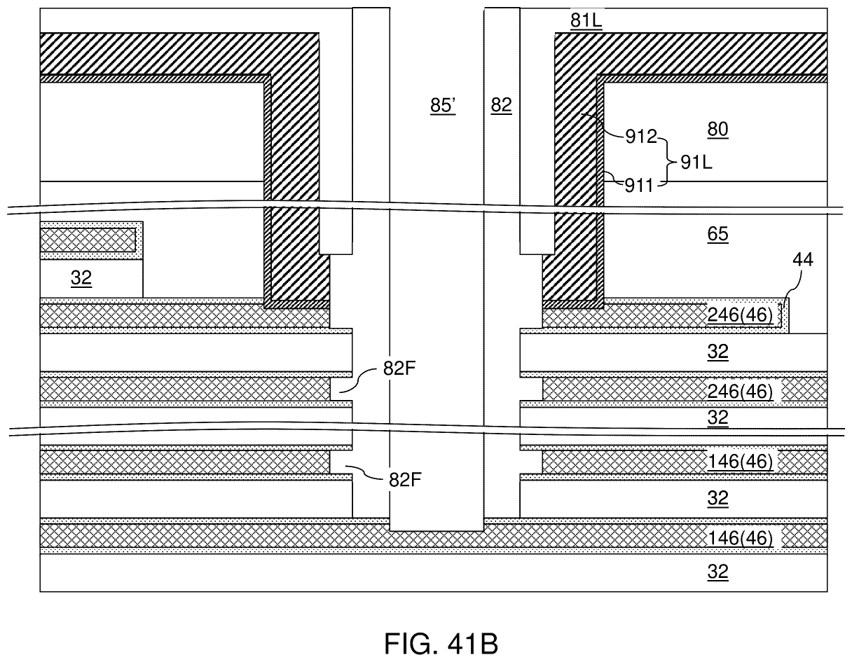

Referring to FIGS. 41A and 41B, an anisotropic etch process can be performed to etch horizontally-extending portions of the inner insulating spacer material layer 82L. Each remaining tubular portion of the inner insulating spacer material layer 82L constitutes an inner insulating spacer layer 82 which includes lateral fins (i.e., protrusions) 82F at the levels of some of the electrically conductive layers 46. The inner insulating spacer layers 82 are formed in peripheral portions of the voids 85′. An outer blocking dielectric layer 44 that underlies each remaining portion of the void 85′ can be removed during a terminal portion of the anisotropic etch process, and a top surface of an underlying first electrically conductive layer 146 can be physically exposed. Each of the first electrically conductive layers 146 may comprise a respective physically exposed top surface segment that is exposed to an overlying void 85′.

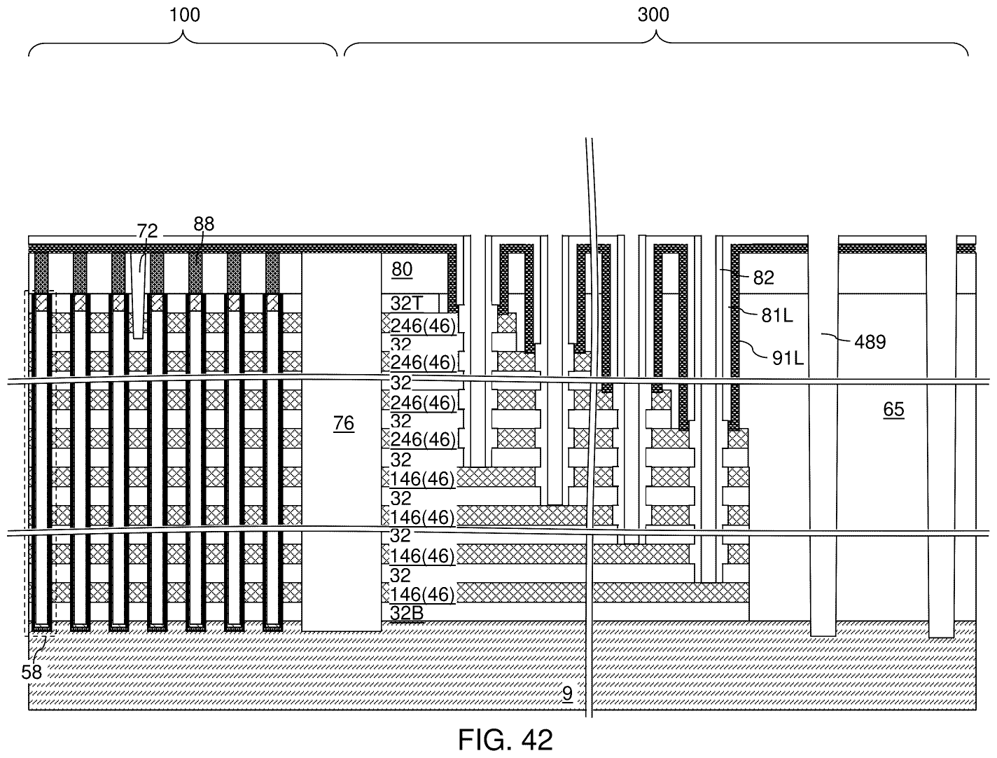

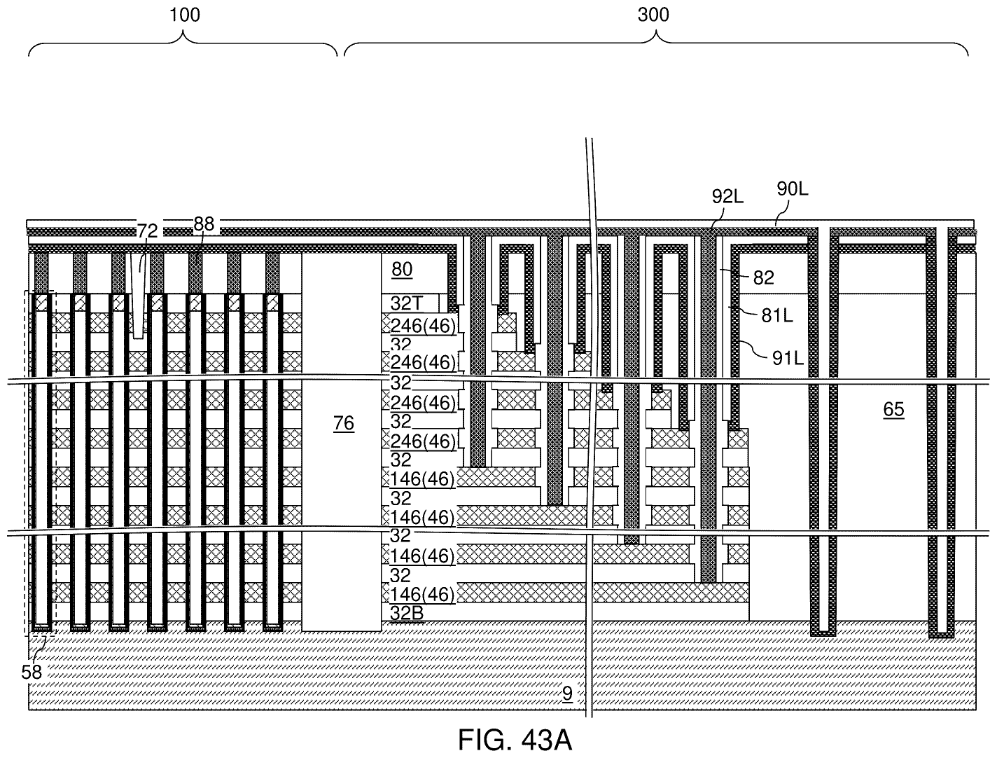

Referring to FIG. 42, a photoresist layer (not shown) may be applied over the horizontally-extending portion of the outer insulating spacer material layer 81L, and can be lithographically patterned to form openings in areas in which the stepped dielectric material portion 65 has a height that equals the height of the alternating stacks (32, 46). An optional anisotropic etch process can be performed to form optional connection via cavities 489 through the stepped dielectric material portion 65 underneath the openings in the photoresist layer. Surface segments of the carrier substrate 9 can be physically exposed at the bottom of each of the connection via cavities 489. The photoresist layer can be subsequently removed, for example, by ashing.

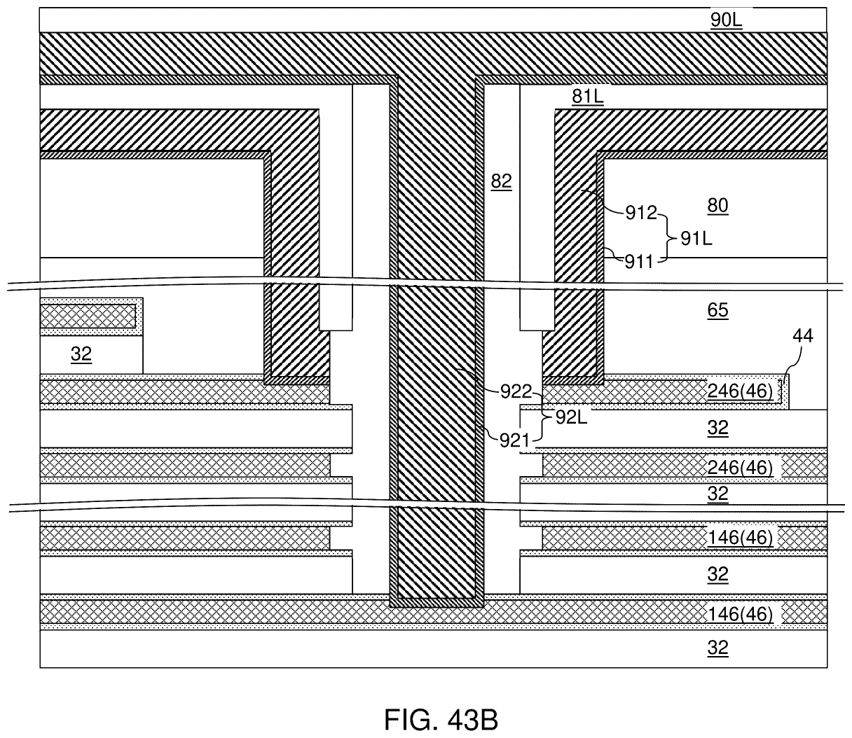

Referring to FIGS. 43A and 43B, at least one inner metallic material layer 92L can be deposited in the voids 85′ (which are laterally surrounded by the inner insulating spacer layers 82) and in the connection via cavities 489 (if present). In one embodiment, the at least one inner metallic material layer 92L may comprise an inner metallic barrier liner 921 and an inner metal layer 922. The inner metallic barrier liner 921 may comprise a metallic barrier material such as TIN, TaN, WN, and/or MoN. The inner metallic barrier liner 921 may be deposited by physical vapor deposition or chemical vapor deposition. The thickness of the inner metallic barrier liner 921 may be in a range from 3 nm to 50 nm, although lesser and greater thicknesses may also be employed. The inner metallic barrier liner 921 can be formed directly on each physically exposed horizontal surface of the first electrically conductive layers 146, and on each inner cylindrical surface of the inner insulating spacer layer 82. The inner metallic barrier liner 921 may also be formed on physically exposed cylindrical surface segments of the outer blocking dielectric layers 44. The inner metal layer 922 may comprise a metal, such as W, Mo, Ti, Ta, Co, Ru, Cu, etc. The inner metal layer 922 may be deposited by physical vapor deposition, chemical vapor deposition, electroplating, or a combination thereof. The thickness of the inner metal layer 922 is selected to fill remaining volumes of the voids in the layer contact via cavities 85.

A dielectric material layer 90L can be deposited over the horizontally-extending portion of the at least one inner metallic material layer 92L. The dielectric material layer 90L comprises a dielectric material such as silicon oxide, silicon nitride, or a dielectric metal oxide material. The thickness of the dielectric material layer 90L may be about the same as the thickness of the outer insulating spacer material layer 81L.

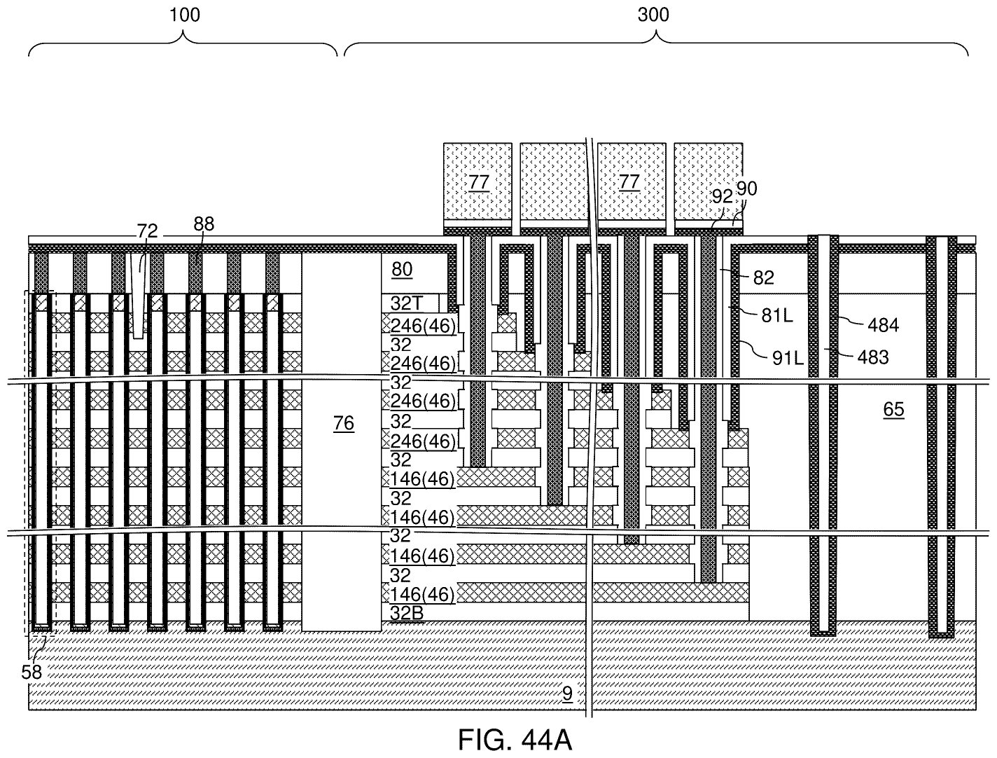

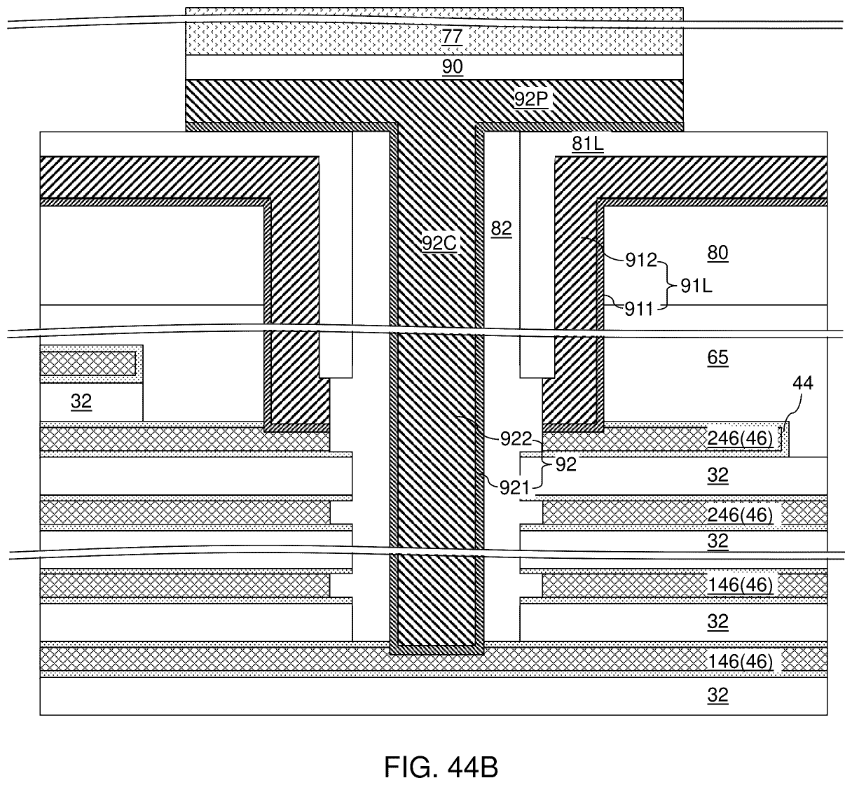

Referring to FIGS. 44A and 44B, a photoresist layer can be applied over the dielectric material layer 90L, and can be lithographically patterned into discrete photoresist material portions 77 each overlying a respective one of the vertically-extending portions of the at least one outer metallic material layer 91L. In one embodiment, the photoresist layer may comprise a trimmable photoresist material, i.e., a photoresist material that can be controllably trimmed by performing a slow ashing process. In one embodiment, each discrete photoresist material portion 77 may have a respective sidewall that is laterally offset outward from an outer sidewall of a respective underlying tubular portion of the at least one outer metallic material layer 91L.

An anisotropic etch process can be performed to transfer the pattern of the discrete photoresist material portions through the dielectric material layer 90L and through the horizontally-extending portion of the at least one inner metallic material layer 92L. The anisotropic etch process can etch portions of the dielectric material layer 90L and the at least one inner metallic material layer 92L that are not masked by the photoresist layer 77. Each remaining patterned portion of the dielectric material layer 90L comprises a dielectric material plate 90. Each remaining portion of the at least one inner metallic material layer 92L comprises an inner layer contact via structure 92 including a cylindrical portion 92C that is laterally surrounded by an inner insulating spacer layer 82 and a plate portion 92P that overlies the horizontal plane including the annular top surfaces of the inner insulating spacer layers 82.

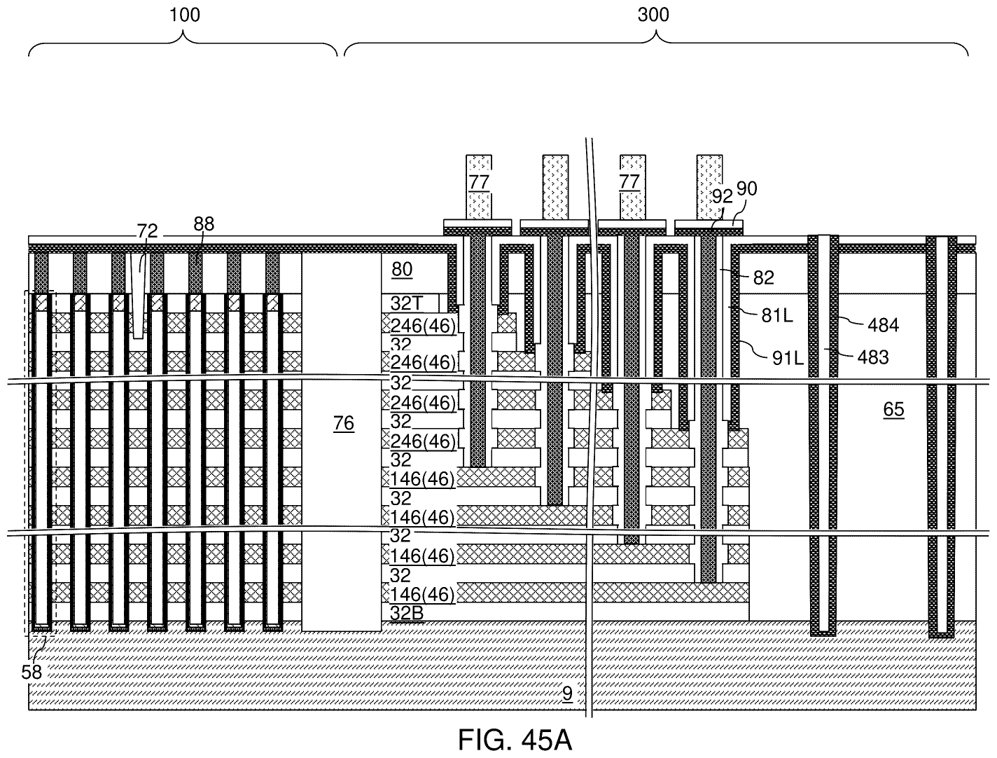

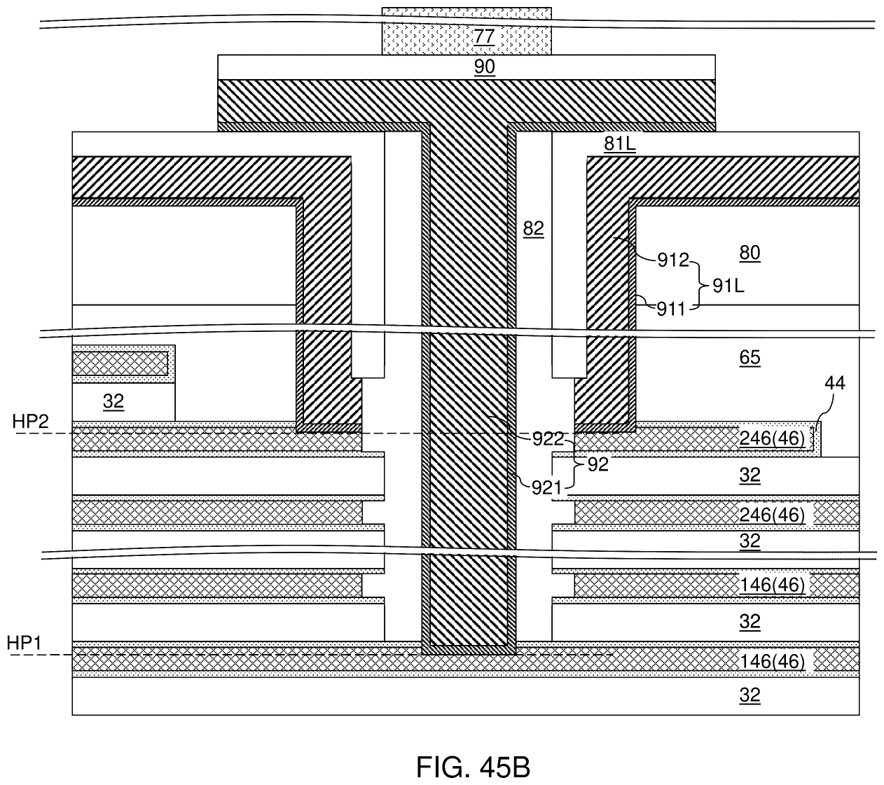

Referring to FIGS. 45A and 45B, a photoresist trimming process can be performed to isotropically trim the discrete photoresist material portions 77. The duration of the photoresist trimming process may be selected such that each sidewall of the discrete photoresist material portions 77 after the trimming process are laterally offset inward from an inner sidewall of a respective underlying tubular portion of the at least one outer metallic material layer 91L.

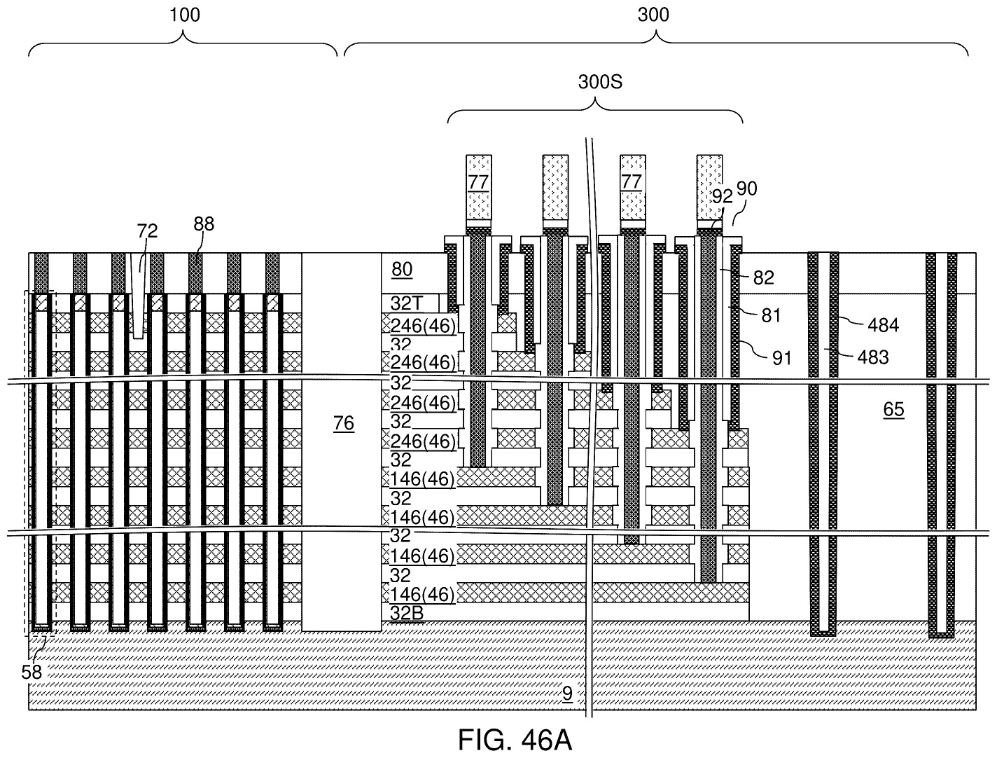

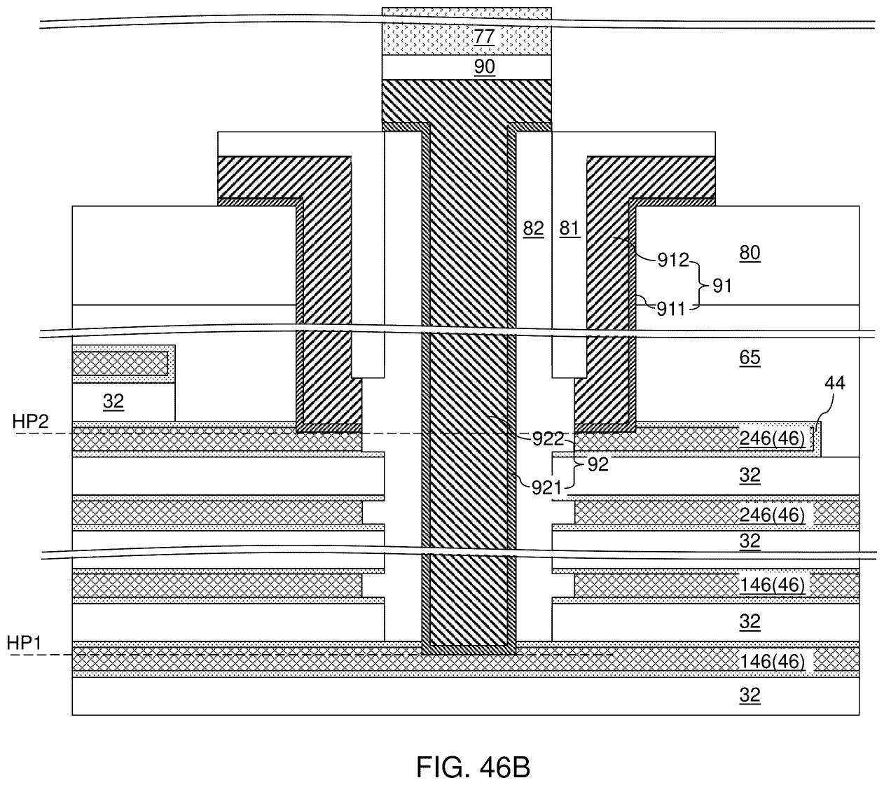

Referring to FIGS. 46A and 46B, an anisotropic etch process can be performed to etch horizontally-extending portions of the outer insulating spacer material layer 81L and the at least one outer metallic material layer 91L that are not masked by the dielectric material plates 90 and the plate portions of the inner layer contact via structures 92 as formed at the processing steps of FIGS. 44A and 44B. Thus, the pattern in the dielectric material plates 90 and the inner layer contact via structures 92 as formed at the processing steps of FIGS. 44A and 44B is transferred through the outer insulating spacer material layer 81L and the at least one outer metallic material layer 91L. Each patterned remaining portion of the outer insulating spacer material layer 81L comprises an outer insulating spacer layer 81 that includes a tubular portion and an annular portion. The top end of the tubular portion of each outer insulating spacer layer 81 can be adjoined to an inner region of the annular portion of the outer insulating spacer layer 81, and the inner cylindrical sidewall of the tubular portion can extend continuously to an inner periphery of a top surface of the annular portion. Each patterned portion of the at least one outer metallic material layer 91L comprises an outer layer contact via structure 91. Each outer layer contact via structure 91 comprises a tubular portion and an annular portion. The top end of the tubular portion of each outer layer contact via structure 91 can be adjoined to an inner region of the annular portion of the outer layer contact via structure 91, and the inner cylindrical sidewall of the tubular portion can extend continuously to an inner periphery of a top surface of the annular portion.

Further, the anisotropic etch process can etch portions of the dielectric material plates 90 and peripheral regions of the plate portions of the inner layer contact via structures 92 that are not masked by the discrete photoresist material portions 77. A peripheral portion of each dielectric material plate 90 can be trimmed by the anisotropic etch process, and a peripheral portion of each plate portion of the inner layer contact via structures 92 can be trimmed by the anisotropic etch process. The discrete photoresist material portions 77 can be subsequently removed, for example, by ashing.

In an alternative embodiment, the etch step shown in FIGS. 44A and 44B can be continued to etch through the at least one outer metallic material layer 91L and the outer insulating spacer material layer 81L to form the outer insulating spacer layer 81 and an outer layer contact via structure 91. The discrete photoresist material portion 77 slimming step shown in FIGS. 45A and 45B is then performed. The etch step shown in FIGS. 46A and 46B comprises a timed etch step that etches portions of the dielectric material plates 90 and peripheral regions of the plate portions of the inner layer contact via structures 92 that are not masked by the discrete photoresist material portions 77. In this alternative embodiment, the horizontal portions of the outer insulating spacer layer 81 function as etch stop structures.

Each contiguous combination of an inner layer contact via structures 92, an inner insulating spacer layer 82, an outer insulating spacer layer 81, and an outer layer contact via structure 91 constitutes a coaxial double contact via structure (92, 82, 81, 91). Thus, coaxial double contact via structures (92, 82, 81, 91) are formed through the stepped dielectric material portion 65 and a respective subset of the electrically conductive layers 46. Each of the coaxial double contact via structures (92, 82, 81, 91) comprises a respective inner layer contact via structure 92 contacting a respective one of the first electrically conductive layers 146 and a respective outer layer contact via structure 91 that laterally surrounds the respective inner layer contact via structure 92 and contacts a respective one of the second electrically conductive layers 246.

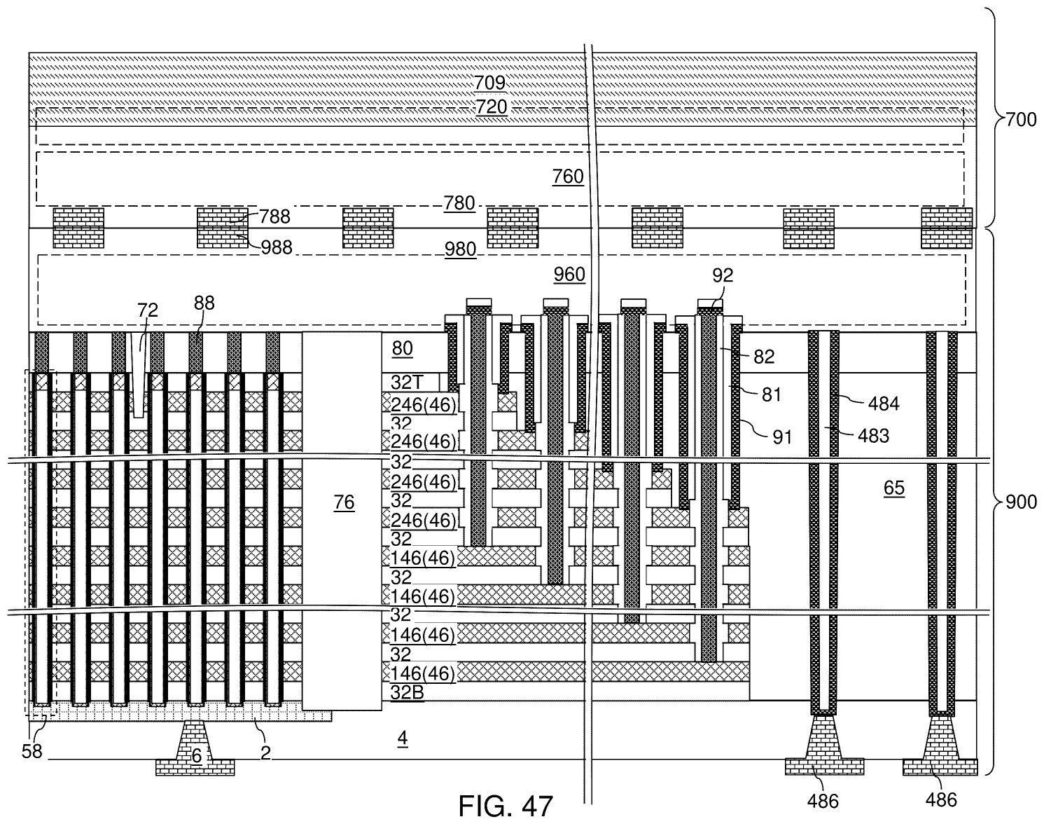

Referring to FIG. 47, the processing steps described with reference to FIGS. 16A and 16B can be performed to form memory-side dielectric material layers 960, memory-side metal interconnect structures 980, and memory-side bonding pads 988. The memory-side metal interconnect structures 980 comprise metal via structures (not expressly shown) that contact top surfaces of a respective one of the inner layer contact via structures 92 and outer layer contact via structures 91.

The processing steps described with reference to FIGS. 17-20B can be subsequently performed to form a bonded assembly of a memory die 900 and a logic die 700.

Referring collectively to FIGS. 23A-47 and related drawings and according to various embodiments of the present disclosure, a device structure is provided, which comprises: an alternating stack (32, 46) of insulating layers 32 and electrically conductive layers 46, wherein the electrically conductive layers 46 comprise first electrically conductive layers 146 and second electrically conductive layers 246 that overlie the first electrically conductive layers 146, wherein lateral extents of the second electrically conductive layers 246 vary (e.g., decrease) along a vertical direction in a staircase region; a stepped dielectric material portion 65 overlying and laterally contacting the alternating stack (32, 46) in the staircase region; memory openings 49 vertically extending through the alternating stack (32, 46); memory opening fill structures 58 located in the memory openings 49, wherein each of the memory opening fill structures 58 comprises a respective vertical stack of memory elements (which may comprise portions of the memory material layer 54) and vertical semiconductor channel 60; and coaxial double contact via structures (92, 82, 81, 91) vertically extending through the stepped dielectric material portion 65, wherein each of the coaxial double contact via structures (92, 82, 81, 91) comprises: a respective inner layer contact via structure 92 contacting a respective one of the first electrically conductive layers 146; and a respective outer layer contact via structure 91 that laterally surrounds the respective inner layer contact via structure 92 and contacts a respective one of the second electrically conductive layers 246.

In one embodiment, each of the coaxial double contact via structures (92, 82, 81, 91) comprises a respective set of at least one insulating spacer layer (81, 82) that laterally surrounds the respective inner layer contact via structure 92 and is laterally surrounded by the respective outer layer contact via structure 91. In one embodiment, for each of the coaxial double contact via structures (92, 82, 81, 91), a respective plurality of insulating layers 32 of the insulating layers 32 is located between a respective first horizontal plane HP1 including a bottom surface of the respective inner layer contact via structure 92 and a respective second horizontal plane HP2 including a bottom surface of the respective outer layer contact via structure 91.

In one embodiment, a bottommost one of the second electrically conductive layers 246 overlies a topmost one of the first electrically conductive layers 146. In one embodiment, for one of the coaxial double contact via structures (92, 82, 81, 91), a plurality of second electrically conductive layers 246 of the second electrically conductive layers 246 and a plurality of first electrically conductive layers 146 of the first electrically conductive layers 146 are located between a first horizontal plane HP1 including a bottom surface of the respective inner layer contact via structure 92 and a second horizontal plane HP2 including a bottom surface of the respective outer layer contact via structure 91.

In one embodiment, each of the first electrically conductive layers 146 has a same first areal extent in a plan view along a vertical direction. In one embodiment, each insulating layer 32 that underlies a topmost first electrically conductive layer 146 of the first electrically conductive layers 146 has the same first areal extent in the plan view. In one embodiment, the variable lateral extents of the second electrically conductive layers 246 differ from each other, and are not greater than the first lateral extent of the first electrically conductive layers 146.

In one embodiment, a first subset of the insulating layers 32 underlie the topmost first electrically conductive layer 146; and a straight sidewall of the stepped dielectric material portion 65 vertically extends from a bottom surface of a bottommost insulating layer 32 within the first subset at least to a top surface of a topmost insulating layer 32 within the first subset, and contacts each of the insulating layers 32 within the first subset.

In one embodiment, the first subset of the insulating layers 32 comprises N insulating layers 32, wherein N is an integer in a range from 4 to 512; and for each of the coaxial double contact via structures (92, 82, 81, 91), a respective set of N insulating layers 32 of the insulating layers 32 of the alternating stack (32, 46) is located between a respective first horizontal plane HP1 including a bottom surface of the respective inner layer contact via structure 92 and a respective second horizontal plane HP2 including a bottom surface of the respective outer layer contact via structure 91.

In one embodiment, each of the coaxial double contact via structures (92, 82, 81, 91) comprises a respective inner insulating spacer layer 82 that laterally surrounds the respective inner layer contact via structure 92 and is contacted by a respective plurality of electrically conductive layers 46 of the electrically conductive layers 46 of the alternating stack (32, 46). In one embodiment, the respective inner insulating spacer layer 82 comprises a respective straight inner cylindrical sidewall that contacts the inner layer contact via structure 92, and a respective ribbed outer cylindrical sidewall having laterally protruding fins 82F at each level of the respective plurality of electrically conductive layers 46.

In one embodiment, each of the electrically conductive layers 46 is embedded within a respective outer blocking dielectric layer 44; and the respective ribbed outer cylindrical sidewall contacts annular horizontal surface segments of a subset of the outer blocking dielectric layers 44. In one embodiment, each of the coaxial double contact via structures (92, 82, 81, 91) comprises a respective outer insulating spacer layer 81 that laterally surrounds the respective inner insulating spacer layer 82 and is vertically spaced from, and is located entirely above, the respective one of the second electrically conductive layers 246.

In one embodiment, the respective outer layer contact via structure 91 comprises a tubular portion and an annular portion that is adjoined to a top end of the tubular portion. In one embodiment, the respective inner layer contact via structure 92 comprises a cylindrical portion and a plate portion that is adjoined to a top end of the cylindrical portion and having a greater area than the cylindrical portion in a plan view along a vertical direction.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
an alternating stack of insulating layers and electrically conductive layers, wherein the electrically conductive layers comprise first electrically conductive layers and second electrically conductive layers that overlie the first electrically conductive layers, wherein lateral extents of the second electrically conductive layers vary along a vertical direction in a staircase region;
a stepped dielectric material portion overlying and laterally contacting the alternating stack in the staircase region;
memory openings vertically extending through the alternating stack;
memory opening fill structures located in the memory openings, wherein each of the memory opening fill structures comprises a respective vertical stack of memory elements and vertical semiconductor channel; and
coaxial double contact via structures vertically extending through the stepped dielectric material portion, wherein each of the coaxial double contact via structures comprises:
a respective inner layer contact via structure contacting a respective one of the first electrically conductive layers; and
a respective outer layer contact via structure that laterally surrounds the respective inner layer contact via structure and contacts a respective one of the second electrically conductive layers.

2. The device structure of claim 1, wherein each of the coaxial double contact via structures comprises a respective set of at least one insulating spacer layer that laterally surrounds the respective inner layer contact via structure and is laterally surrounded by the respective outer layer contact via structure.

3. The device structure of claim 1, wherein, for each of the coaxial double contact via structures, a respective plurality of insulating layers of the insulating layers is located between a respective first horizontal plane including a bottom surface of the respective inner layer contact via structure and a respective second horizontal plane including a bottom surface of the respective outer layer contact via structure.

4. The device structure of claim 1, wherein a bottommost one of the second electrically conductive layers overlies a topmost one of the first electrically conductive layers.

5. The device structure of claim 1, wherein, for one of the coaxial double contact via structures, a plurality of second electrically conductive layers of the second electrically conductive layers and a plurality of first electrically conductive layers of the first electrically conductive layers are located between a first horizontal plane including a bottom surface of the respective inner layer contact via structure and a second horizontal plane including a bottom surface of the respective outer layer contact via structure.

6. The device structure of claim 1, wherein each of the first electrically conductive layers has a same first areal extent in a plan view along a vertical direction.

7. The device structure of claim 6, wherein the variable lateral extents of the second electrically conductive layers differ from each other, and are not greater than the first lateral extent of the first electrically conductive layers.

8. The device structure of claim 7, wherein:
a first subset of the insulating layers underlie the topmost first electrically conductive layer; and
a straight sidewall of the stepped dielectric material portion vertically extends from a bottom surface of a bottommost insulating layer within the first subset at least to a top surface of a topmost insulating layer within the first subset, and contacts each of the insulating layers within the first subset.

9. The device structure of claim 8, wherein:
the first subset of the insulating layers comprises N insulating layers, wherein N is an integer in a range from 4 to 512; and
for each of the coaxial double contact via structures, a respective set of N insulating layers of the insulating layers of the alternating stack is located between a respective first horizontal plane including a bottom surface of the respective inner layer contact via structure and a respective second horizontal plane including a bottom surface of the respective outer layer contact via structure.

10. The device structure of claim 1, wherein each of the coaxial double contact via structures further comprises a respective inner insulating spacer layer that laterally surrounds the respective inner layer contact via structure and is contacted by a respective plurality of electrically conductive layers of the electrically conductive layers of the alternating stack.

11. The device structure of claim 10, wherein the respective inner insulating spacer layer comprises a respective straight inner cylindrical sidewall that contacts the inner layer contact via structure, and a respective ribbed outer cylindrical sidewall having laterally protruding fins at each level of the respective plurality of electrically conductive layers.

12. The device structure of claim 10, wherein:
each of the electrically conductive layers is embedded within a respective outer blocking dielectric layer; and
the respective ribbed outer cylindrical sidewall contacts annular horizontal surface segments of a subset of the outer blocking dielectric layers.

13. The device structure of claim 10, wherein each of the coaxial double contact via structures further comprises a respective outer insulating spacer layer that laterally surrounds the respective inner insulating spacer layer and is vertically spaced from, and is located entirely above, the respective one of the second electrically conductive layers.

14. The device structure of claim 1, wherein the respective outer layer contact via structure comprises a tubular portion and an annular portion that is adjoined to a top end of the tubular portion.

15. The device structure of claim 1, wherein the respective inner layer contact via structure comprises a cylindrical portion and a plate portion that is adjoined to a top end of the cylindrical portion and having a greater area than the cylindrical portion in a plan view along a vertical direction.

16. A method of forming a device structure comprising:
forming a combination of an alternating stack of insulating layers and electrically conductive layers, a stepped dielectric material portion overlying stepped surfaces of the alternating stack, and a memory stack structure vertically extending through the alternating stack, wherein the electrically conductive layers comprise first electrically conductive layers and second electrically conductive layers that overlie the first electrically conductive layers, and wherein the memory stack structure comprises a vertical stack of memory elements and a vertical semiconductor channel; and
forming coaxial double contact via structures through the stepped dielectric material portion and a respective subset of the electrically conductive layers, wherein each of the coaxial double contact via structures comprises:
a respective inner layer contact via structure contacting a respective one of the first electrically conductive layers; and
a respective outer layer contact via structure that laterally surrounds the respective inner layer contact via structure and contacts a respective one of the second electrically conductive layers.

17. The method of claim 16, wherein:
each of the first electrically conductive layers is formed with a first lateral extent;
lateral extents of the second electrically conductive layers vary with a vertical distance from a horizontal plane including a bottommost surface of the alternating stack; and
a maximum lateral extent of a bottommost second electrically conductive layer of the second electrically conductive layers is not greater than the first lateral extent.

18. The method of claim 16, further comprising:
forming layer contact via cavities through the stepped dielectric material portion, wherein top surface segments of the second electrically conductive layers are physically exposed upon formation of the layer contact via cavities;
depositing at least one outer metallic material layer; and
anisotropically etching the at least one outer metallic material layer, wherein remaining portions of the at least one outer metallic material layer comprise the outer layer contact via structures.

19. The method of claim 18, further comprising:
depositing an outer insulating spacer material layer over the at least one outer metallic material layer;
forming a patterned etch mask layer that covers a horizontally-extending portion of the outer insulating spacer material layer that overlies the layer contact via cavities; and
anisotropically etching portions of the outer insulating spacer material layer and portions of the alternating stack that are not masked by the patterned etch mask layer by performing an anisotropic etch process such that surface segments of the first electrically conductive layers are physically exposed underneath voids that are formed by the anisotropic etch process.

20. The method of claim 19, further comprising:
isotropically etching surface portions of the first electrically conductive layers and the second electrically conductive layers that are exposed to the voids;
forming inner insulating spacer layers in peripheral portions of the voids; and
forming the inner layer contact via structures in remaining unfilled volumes of the voids after formation of the inner insulating spacer layers.
